(19) United States
(12) Patent Application Publication
(10) Pub. No.: US 2025/0088075 A1
(43) Pub. Date: Mar. 13, 2025

(54) SUBSTRATE TRANSPORT APPARATUS

(71) Applicant: Brooks Automation US, LLC, Chelmsford, MA (US)

(72) Inventors: Robert T. Caveney, Windham, NH (US); Robert C. May, San Antonio, TX (US); Jairo T. Moura, Marlborough, MA (US); Matthew J. McLellan, Chelmsford, MA (US); Ulysses Gilchrist, Reading, MA (US); Alexander G. Krupyshev, Chelmsford, MA (US)

(21) Appl. No.: 18/826,945

(22) Filed: Sep. 6, 2024

Related U.S. Application Data
(60) Provisional application No. 63/581,512, filed on Sep. 8, 2023.
(60) Provisional application No. 63/685,401, filed on Aug. 21, 2024.

(51) Int. Cl. H02K 7/14; B25J 9/12; H02K 5/10; H02K 15/00; H02K 16/00

(52) U.S. Cl. CPC H02K 7/14; B25J 9/126; H02K 5/10; H02K 15/00; H02K 16/00

(57) ABSTRACT

A brushless electrical machine includes: a frame; an electric machine stator connected to the frame and having a phase coil disposed in an atmospheric volume holding an atmospheric environment; an electric machine rotor cooperatively coupled to the electric machine stator so as to generate an output under stimulation from the electric machine stator, the electric machine rotor being disposed in a sealed environment sealed from and different than the atmospheric volume; and a seal that seals the electric machine rotor from the electric machine stator. The electric machine rotor and electric machine stator are disposed in an axial gap arrangement with an axial gap between the electric machine rotor and electric machine stator disposed astride the electric machine stator, and the seal is arranged in the axial gap so as to seal each electric machine stator from each electric machine rotor stimulated by the electric machine stator across the seal.

### CROSS-REFERENCE TO RELATED APPLICATIONS

This application is a non-provisional of and claims the benefit of U.S. provisional patent application No. 63/581,512 filed on Sep. 8, 2023 and U.S. provisional patent application No. 63/685,401 filed on Aug. 21, 2024, the disclosures of which are incorporated herein by reference in their entireties.

### BACKGROUND

### 1. Field

The present disclosure generally relates to robotic systems, and more particularly, to robotic transport systems.

### 2. Brief Description of Related Developments

In, for example, semiconductor processing, there is a trend towards narrow or elongated vacuum systems. These narrow vacuum systems have increasing footprints, particularly in length. Generally, vacuum robots that move in Cartesian coordinates (referred to as a yaw robot) are employed in these elongated vacuum systems. However, as the length or footprint of the elongated vacuum system grows, so does the reach required by the vacuum robots. To accommodate the increase in reach, the links of the vacuum robot arms increase in length/size resulting in heavier arm structure with increased inertia, which places increases demands on the motors driving each axis of the robot arm. In some applications, to increase semiconductor production throughput the robot arms are operated at higher accelerations which further increases the demands on the motors (e.g., such as a demand for torque output by the motors). In some aspects, the motors for driving the robot arm are located in a common motor housing (such as in a coaxial or side-by-side arrangement where the motor output is output through a coaxial drive shaft arrangement); while in other aspects, some of the motors are distributed within the robot arm itself. Placement of the motors within the arm serves to increase the weight and inertia of the arm structure.

Accordingly, the present disclosure addresses a number of those issues.

### BRIEF DESCRIPTION OF THE DRAWINGS

The foregoing aspects and other features of the present disclosure are explained in the following description, taken in connection with the accompanying drawings, wherein:

FIGS. 1A-1I are schematic illustrations of substrate processing apparatus in accordance with the present disclosure;

FIGS. 2A-2H are schematic illustrations of exemplary substrate transfer apparatus in accordance with the present disclosure, and which may be employed in any of the substrate processing apparatus of FIGS. 1A-1I;

FIGS. 3A-3C are schematic illustrations of an exemplary substrate transfer apparatus including one or more brushless electrical machines in accordance the present disclosure;

FIGS. 3D-3F are schematic illustrations of portions of the exemplary substrate transfer apparatus of FIGS. 3A-3C in accordance the present disclosure;

FIGS. 4A and 4B are schematic illustrations of an exemplary substrate transfer apparatus including one or more brushless electrical machines in accordance the present disclosure;

FIGS. 5A-5C are schematic illustrations of an exemplary brushless electrical machine in accordance with the present disclosure, and that may be incorporated at one or more joints of any of the substrate transport apparatus described herein;

FIGS. 6A and 6B are schematic illustrations of an exemplary substrate transfer apparatus including one or more brushless electrical machines in accordance with the present disclosure;

FIG. 7 is a schematic illustration of an exemplary substrate transfer apparatus including one or more brushless electrical machines in accordance with the present disclosure;

FIG. 8 is a schematic illustration of an exemplary substrate transfer apparatus including one or more brushless electrical machines in accordance with the present disclosure;

FIGS. 9A-9C are schematic illustrations of an exemplary substrate transfer apparatus including one or more brushless electrical machines in accordance with the present disclosure;

FIG. 10 is a schematic flow diagram of an operation of the substrate transfer apparatus of FIGS. 9A-9C in accordance with the present disclosure;

FIGS. 11 and 12 are exemplary flow diagrams of methods in accordance with the present disclosure;

FIG. 13A is a schematic side view illustration of an exemplary substrate transfer apparatus including one or more brushless electrical machines in accordance the present disclosure;

FIGS. 13B and 13C are exemplary plan view illustrations of the substrate transfer apparatus of FIG. 13A in accordance with the present disclosure;

FIG. 13D is a schematic side view illustration of an exemplary substrate transfer apparatus of FIG. 13A in accordance with the present disclosure;

FIGS. 13E and 13F illustrated exemplary substrate transfer operations in accordance with the present disclosure;

FIGS. 14A-14D are exemplary perspective illustrations of a substrate transfer apparatus including one or more brushless electrical machines in accordance with the present disclosure;

FIGS. 15A and 15B are exemplary perspective illustrations of a substrate transfer apparatus including one or more brushless electrical machines in accordance with the present disclosure; and

FIG. 16A is an exemplary perspective view illustration of a substrate transfer apparatus including one or more brushless electrical machines in accordance with the present disclosure;

FIGS. 16B and 16C are respective exemplary perspective view illustrations of the substrate transfer apparatus of FIG. 16A in respective extended configurations in accordance with the present disclosure;

FIGS. 16D and 16E are respective exemplary perspective view illustrations of the substrate transfer apparatus of FIG. 16A showing different motor configurations in accordance with the present disclosure;

FIG. 17A is an exemplary perspective view illustration of a substrate transfer apparatus including one or more brushless electrical machines in accordance with the present disclosure;

FIGS. 17B and 17C are respective exemplary perspective view illustrations of the substrate transfer apparatus of FIG. 17A in respective extended configurations in accordance with the present disclosure;

FIG. 18 is an exemplary perspective view illustration of a portion of the substrate transfer apparatus of FIGS. 16A-16C and 17A-17C in accordance with the present disclosure;

FIG. 19 illustrates an exemplary load lock of the substrate processing apparatus described herein that is serviced by the substrate transfer apparatus described herein in accordance with the present disclosure, the load lock being of and commensurate with a popular load lock configuration that has been widely adopted in the industry; and

FIG. 20 is a flow diagram of an exemplary method in accordance with the present disclosure.

### DETAILED DESCRIPTION

The following detailed description is meant to assist the understanding of one skilled in the art, and is not intended in any way to unduly limit claims connected or related to the present disclosure.

The following detailed description references various figures, where like reference numbers refer to like components and features across various figures, whether specific figures are referenced, or not.

The word “each” as used herein refers to a single object (i.e., the object) in the case of a single object or each object in the case of multiple objects. The words “a,” “an,” and “the” as used herein are inclusive of “at least one” and “one or more” so as not to limit the object being referred to as being in its “singular” form.

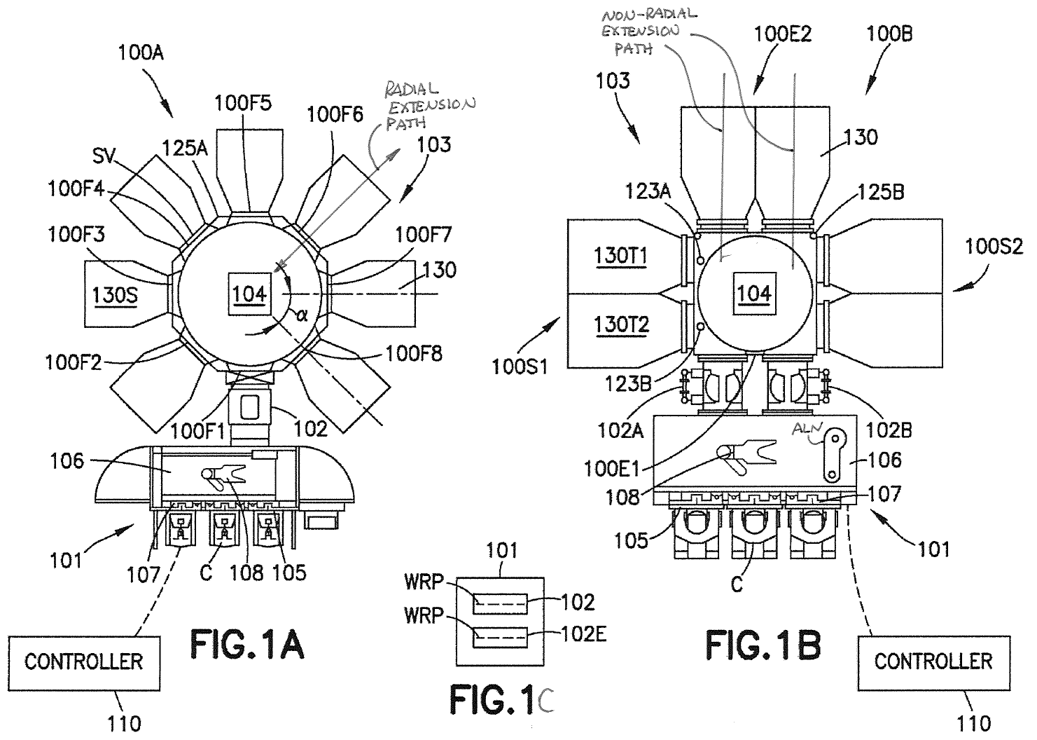

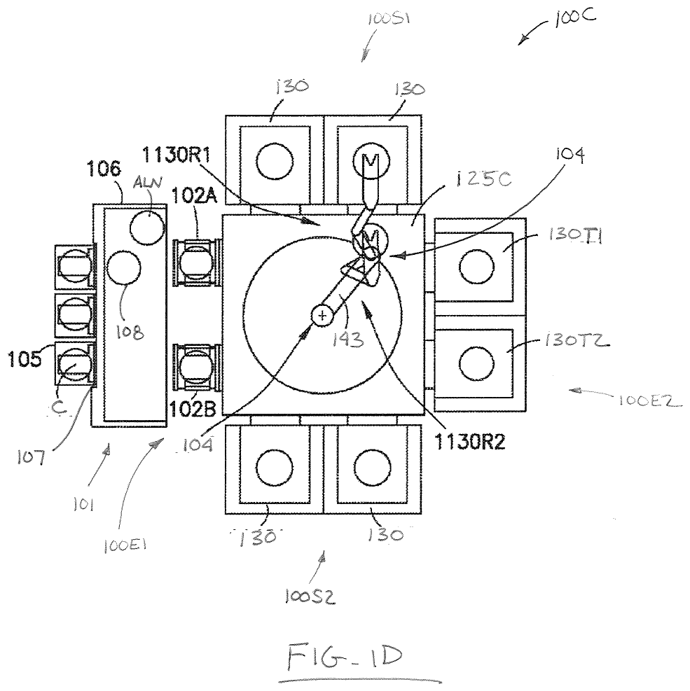

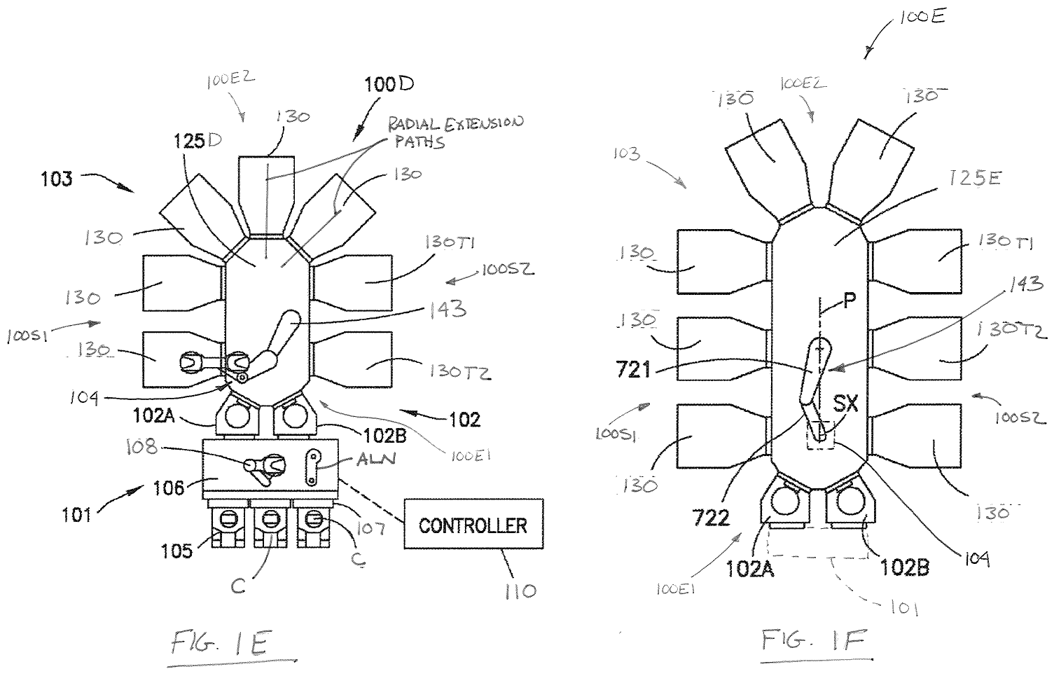

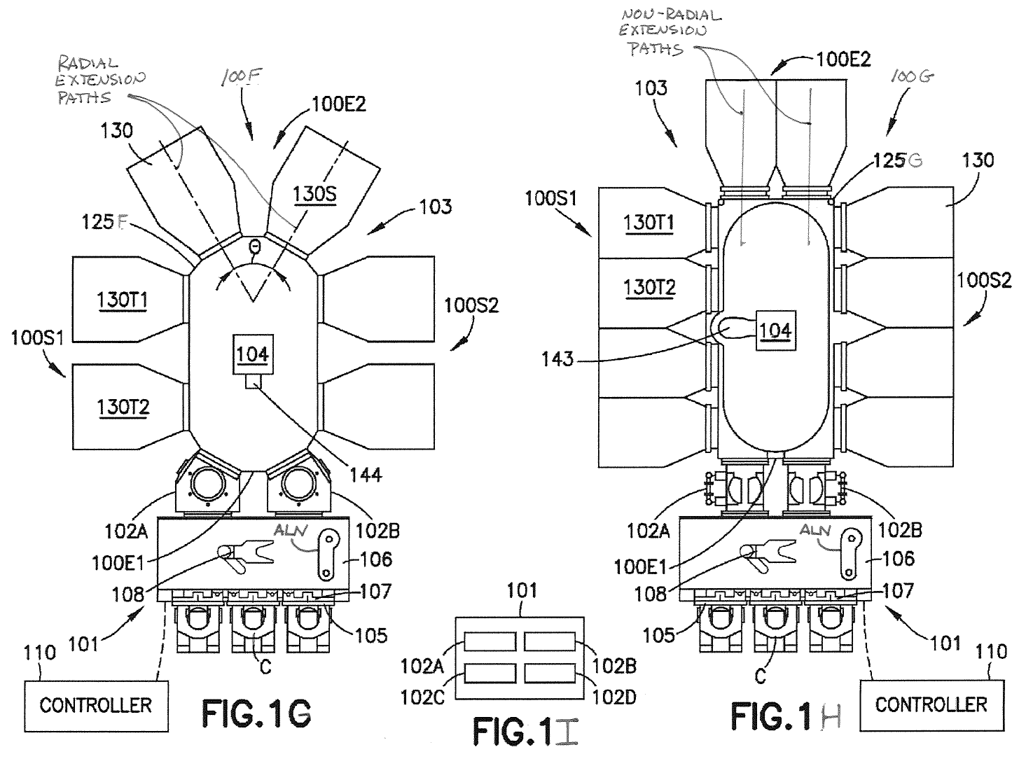

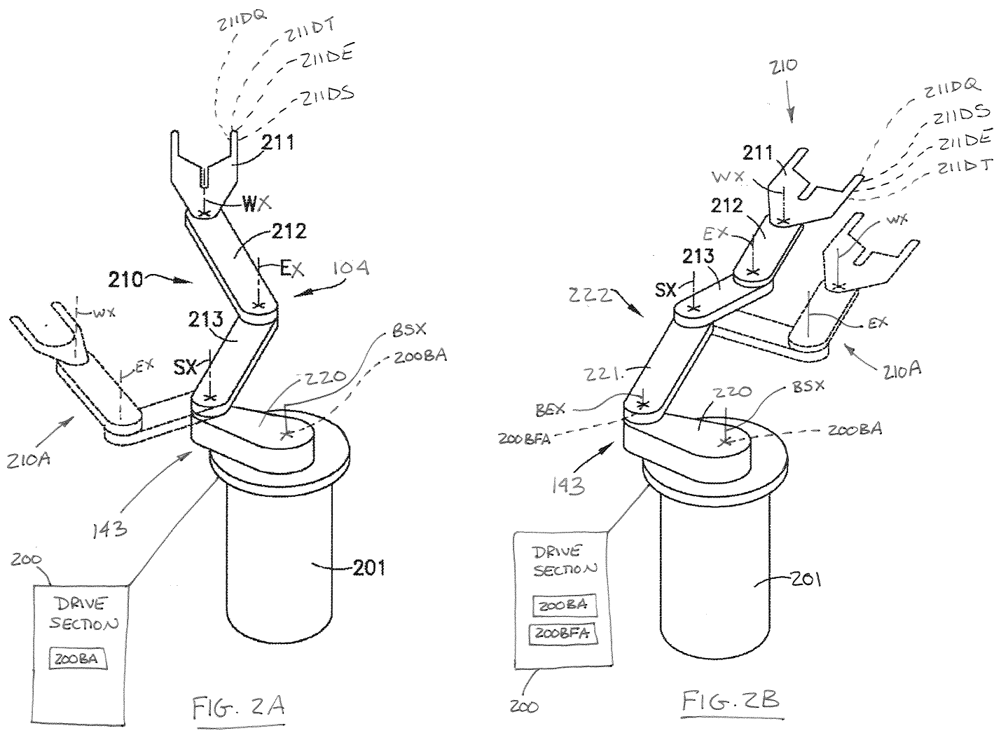

FIGS. 1A-1I are schematic illustrations of substrate processing apparatus in accordance with the present disclosure. Although the present disclosure will be described with reference to the drawings, it should be understood that the present disclosure could be embodied in many forms. In addition, any suitable size, shape or type of elements or materials could be used.

The present disclosure provides a robot architecture that integrates motors into one or more joints of the robot arm, where the motors are high-torque compact motors that may reduce the driven mass and overall size of the robot arm links. The robot architecture may be operated in one or more of vacuum and atmospheric environments.

The present disclosure provides a robot architecture that integrates motors (each may have a respective encoder providing position feedback) into one or more joints of the robot arm, where the motors are high-torque compact motors that may reduce the driven mass and overall size of the robot arm links compared to conventional robots with directly driven arm links. For example, typical semiconductor robots generally about 100 N/m of torque for the shoulder axis or motor and about 60 N/m of torque for the elbow axis or motor so as to rotate, for example, an upper arm and forearm of a SCARA transfer robot. The shoulder and elbow joints may be the dominant axes for typical motions of yaw or radial arm robots with Cartesian movements (such as those described herein). With ever-evolving semiconductor manufacturing (e.g., moving to longer stroke/heavier link robots, heavier payloads of new substrate materials, and higher throughputs/robot accelerations), torque demands of the motors is ever increasing. In accordance with the present disclosure, the motors integrated into and directly driving the one or more joints of the robot arm are axial flux motors that have a high torque, light weight, and low electrical power consumption. These motors employ rotors without permanent magnets (e.g., rotors constructed of any suitable magnetic permeable material) such as those described in U.S. Pat. No. 9,948,155 issued on Apr. 17, 2018 and U.S. Pat. No. 11,444,521 issued on Sep. 13, 2022 and U.S. patent application Ser. No. 17/790,722 filed on Jul. 1, 2022 (published as US 2023/0069099 on Mar. 2, 2023), the disclosures of which are incorporated herein by reference in their entireties.

In accordance with the present disclosure, one or more of the arm joints may include motors that have magnet/coil arrays that are axially stacked along the rotation axis of the motor, where the stacked coil arrays are configured to provide a predetermined motor torque output, which may result in a motor with a smaller footprint than that of a radial flux motor having the same torque output. For example, a typical torque density of a radial flux motor disposed at a shoulder axis of a SCARA transport arm is about 9.09 N/m/kg versus about 41.7 N/m/kg for an equivalent axial flux motor, where the power to drive the axial flux motor is lower than that of the radial flux motor (e.g., about 315 Watts (48 vDC) to drive the radial flux motor compared to about 49 Watts (48 vDC) to drive the axial flux motor. The lower power consumption of the axial flux motors provide for employment of smaller gauge electrical conductors and connectors for the motors, which is beneficial when routing the conductors through the arm links.

In accordance with the present disclosure, these stacked coil (stator) axial flux motors are sealed for operation in vacuum environments (noting that the stacked coil axial flux motors may be employed in atmospheric environments with or without being sealed). As noted above, the axial flux motors have stacked coils (also referred to as concentrator rings) where rotors (or armatures) are interleaved between the stacked coils. The stator seal provided herein includes an isolation wall that forms a static seal that is interleaved between the coils and rotors in a substantially serpentine configuration.

Still referring to FIGS. 1A-1I, the processing apparatus 100A, 100B, 100C, 100D, 100E, 100F, 100G such as for example a semiconductor tool station, is shown in accordance with the present disclosure. Although a semiconductor tool station is shown in the drawings, the present disclosure described herein can be applied to any tool station or application employing robotic manipulators. The processing apparatus 100A, 100B, 100C, 100D, 100E, 100F, 100G are shown as having cluster tool arrangements (e.g. having substrate holding stations connected to a central chamber), however the processing apparatus may be a linearly arranged tool, or the present disclosure may be applied to any suitable tool station. The apparatus 100A, 100B, 100C, 100D, 100E, 100F, 100G generally include an atmospheric front end 101, at least one vacuum load lock 102, 102A, 102B and a vacuum back end 103. The at least one vacuum load lock 102, 102A, 102B may be coupled to any suitable port(s) or opening(s) of the front end 101 and/or back end 103 in any suitable arrangement. For example, the one or more load locks 102, 102A, 102B may be arranged in a common horizontal plane in a side-by-side arrangement as can be seen in FIGS. 1B, 1D-1H. The one or more load locks may be arranged in a grid format such that at least two load locks 102A, 102B, 102C, 102D are arranged in rows (e.g. having spaced apart horizontal planes) and columns (e.g. having spaced apart vertical planes) as shown in FIG. 1I. The one or more load lock may be a single in-line load lock 102 as shown in FIG. 1A. The at least one load lock 102, 102E may be arranged in a stacked in-line arrangement as shown in FIG. 1C. While the load locks are illustrated on end 100E1 or facet 100F1 of a transport chamber 125A, 125B, 125C, 125D, 125E, 125F, 125G, the one or more load lock may be arranged on any number of sides 100S1, 100S2, ends 100E1, 100E2 or facets 100F1-100F8 of the transport chamber 125A, 125B, 125C, 125D, 125E, 125F, 125G. Each of the at least one load lock may include one or more wafer/substrate resting planes WRP (FIG. 1C) in which substrates are held on suitable supports within the respective load lock. The tool station may have any suitable configuration. The components of each of the front end 101, the at least one load lock 102, 102A, 102B and back end 103 may be connected to a controller 110 which may be part of any suitable control architecture such as, for example, a clustered architecture control. The control system may be a closed loop controller having a master controller, cluster controllers and autonomous remote controllers such as those disclosed in U.S. Pat. No. 7,904,182 entitled “Scalable Motion Control System” issued on Mar. 8, 2011 the disclosure of which is incorporated herein by reference in its entirety. Any suitable controller and/or control system may be utilized.

The front end 101 generally includes load port modules 105 and a mini-environment 106 such as for example an equipment front end module (EFEM). The load port modules 105 may be box opener/loader to tool standard (BOLTS) interfaces that conform to SEMI standards E15.1, E47.1, E62, E19.5 or E1.9 for 300 mm load ports, front opening or bottom opening boxes/pods and cassettes. The load port modules may be configured as 200 mm wafer/substrate interfaces, 450 mm wafer/substrate interfaces or any other suitable substrate interfaces such as for example larger or smaller semiconductor wafers/substrates, flat panels for flat panel displays, solar panels, reticles or any other suitable object. Although three load port modules 105 are shown in FIGS. 1A, 1B, 1D, 1E, 1F, 1G, 1H, any suitable number of load port modules may be incorporated into the front end 101. The load port modules 105 may be configured to receive substrate carriers or cassettes C from an overhead transport system, automatic guided vehicles, person guided vehicles, rail guided vehicles or from any other suitable transport method. The load port modules 105 may interface with the mini-environment 106 through load ports 107. The load ports 107 may allow the passage of substrates between the substrate cassettes and the mini-environment 106.

The mini-environment 106 generally includes any suitable transfer robot 108, which may incorporate one or more features of the present disclosure described herein. The robot 108 may be a track mounted robot such as that described in, for example, U.S. Pat. No. 6,002,840 issued on Dec. 14, 1999; U.S. Pat. No. 8,419,341 issued Apr. 16, 2013; and U.S. Pat. No. 7,648,327 issued on Jan. 19, 2010, the disclosures of which are incorporated by reference herein in their entireties. The robot 108 may be substantially similar to that described herein with respect to the back end 103. The mini-environment 106 may provide a controlled, clean zone for substrate transfer between multiple load port modules.

The at least one vacuum load lock 102, 102A, 102B may be located between and connected to the mini-environment 106 and the back end 103. The load port modules 105 may be coupled substantially directly to the at least one load lock 102, 102A, 102B or the transport chamber 125A, 125B, 125C, 125D, 125E, 125F, 125G where the substrate carrier C is pumped down to a vacuum of the transport chamber 125A, 125B, 125C, 125D, 125E, 125F, 125G and substrates are transferred directly between the substrate carrier C and the load lock or transfer chamber. The substrate carrier C may function as a load lock such that a processing vacuum of the transport chamber extends into the substrate carrier C. Where the substrate carrier C is coupled substantially directly to the load lock through a suitable load port, any suitable transfer apparatus may be provided within the load lock or otherwise have access to the carrier C for transferring substrates to and from the substrate carrier C. It is noted that the term vacuum as used herein may denote a high vacuum such as 1×10⁻⁵ Torr or below in which the substrates are processed. The at least one load lock 102, 102A, 102B generally includes atmospheric and vacuum slot valves. The slot valves of the load locks 102, 102A, 102B (as well as for the processing stations 130) may provide the environmental isolation employed to evacuate the load lock after loading a substrate from the atmospheric front end and to maintain the vacuum in the transport chamber when venting the lock with an inert gas such as nitrogen. As will be described herein, the slot valves of the processing apparatus 100A, 100B, 100C, 100D, 100E, 100F, 100G may be located in the same plane, different vertically stacked planes or a combination of slot valves located in the same plane and slot valves located in different vertically stacked planes (as described above with respect to the load ports) to accommodate transfer of substrates to and from at least the processing stations 130 and load locks 102, 102A, 102B coupled to the transport chamber 125A, 125B, 125C, 125D, 125E, 125F, 125G. The at least one load lock 102, 102A, 102B (and/or the front end 101) may include an aligner ALN for aligning a fiducial of the substrate to a desired position for processing or any other suitable substrate metrology equipment. The vacuum load lock may be located in any suitable location of the processing apparatus and have any suitable configuration.

The vacuum back end 103 generally includes a transport chamber 125A, 125B, 125C, 125D, 125E, 125F, 125G one or more processing station(s) 130 and any suitable number of transfer unit modules 104 that includes one or more transfer robots, which may include one or more features of the present disclosure described herein. The transport chamber 125A, 125B, 125C, 125D, 125E, 125F, 125G may have any suitable shape and size that, for example, complies with SEMI standard E72 guidelines. The transfer unit module(s) 104 and the one or more transfer robot will be described below and may be located at least partly within the transport chamber 125A, 125B, 125C, 125D, 125E, 125F, 125G to transport substrates between the load lock 102, 102A, 102B (or between a cassette C located at a load port) and the various processing stations 130. The transfer unit module 104 may be removable from the transport chamber 125A, 125B, 125C, 125D, 125E, 125F, 125G as modular unit such that the transfer unit module 104 complies with SEMI standard E72 guidelines.

The processing stations 130 may operate on the substrates through various deposition, etching, or other types of processes to form electrical circuitry or other desired structure on the substrates. Typical processes include but are not limited to thin film processes that use a vacuum such as plasma etch or other etching processes, chemical vapor deposition (CVD), plasma vapor deposition (PVD), implantation such as ion implantation, metrology, rapid thermal processing (RTP), dry strip atomic layer deposition (ALD), oxidation/diffusion, forming of nitrides, vacuum lithography, epitaxy (EPI), wire bonder and evaporation or other thin film processes that use vacuum pressures. The processing stations 130 are communicably connected to the transport chamber 125A, 125B, 125C, 125D, 125E, 125F, 125G in any suitable manner, such as through slot valves SV, to allow substrates to be passed from the transport chamber 125A, 125B, 125C, 125D, 125E, 125F, 125G to the processing stations 130 and vice versa. The slot valves SV of the transport chamber 125 may be arranged to allow for the connection of twin (e.g. more than one substrate processing chamber located within a common housing) or side-by-side process stations 130T1, 130T2, single process stations 130S and/or stacked process modules/load locks (FIGS. 1C and 1I).

It is noted that the transfer of substrates to and from the processing station 130, load locks 102, 102A, 102B (or cassette C) coupled to the transfer chamber 125A, 125B, 125C, 125D, 125E, 125F, 125G may occur when one or more arms of the transfer unit module 104 are aligned with a predetermined processing station 130. In accordance with the present disclosure one or more substrates may be transferred to a respective predetermined processing station 130 individually or substantially simultaneously (e.g. such as when substrates are picked/placed from side-by-side or tandem processing stations as shown in FIGS. 1B, 1D and 1H. The transfer unit module 104 may be mounted on a boom arm 143 (see, e.g., FIGS. 1E, 1F, 1H) or linear carriage 144 (see, e.g., FIG. 1C) such as that described in U.S. Pat. Nos. 10,777,438 titled “Processing Apparatus” and issued on Sep. 15, 2020 and International patent application number PCT/US13/25513 entitled “Substrate Processing Apparatus” and filed on Feb. 11, 2013, the disclosures of which are incorporated herein by reference in their entireties.

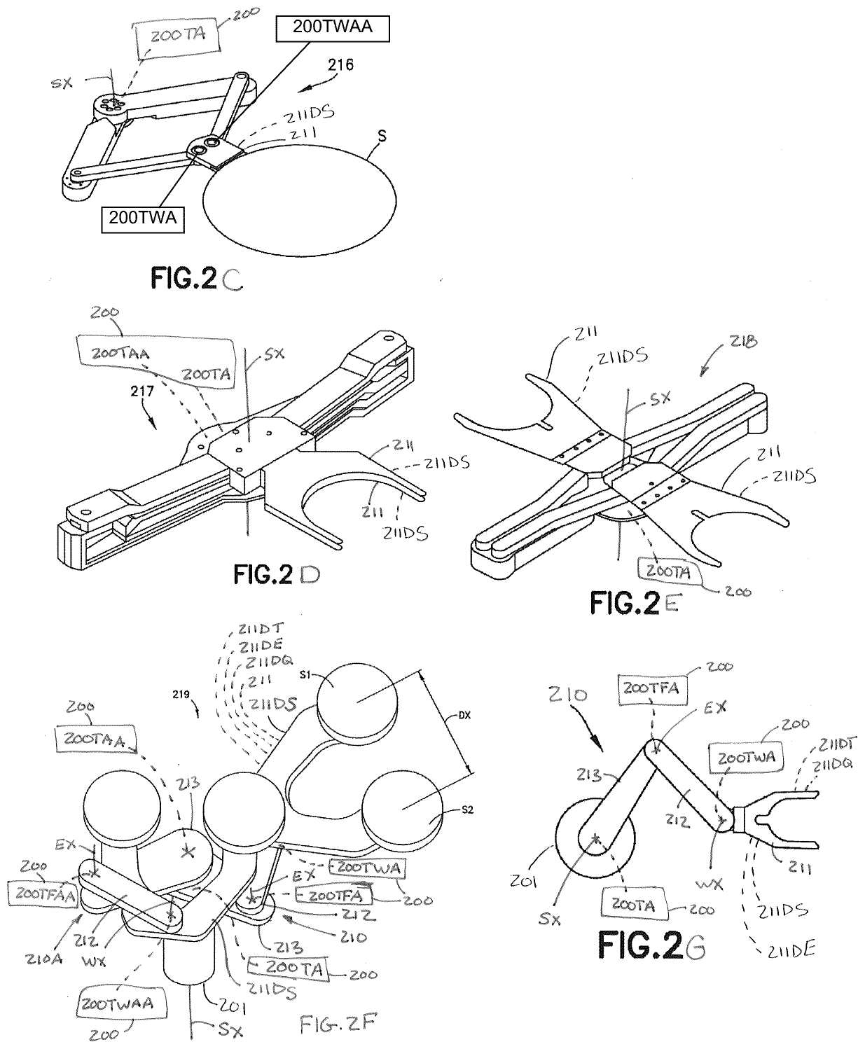

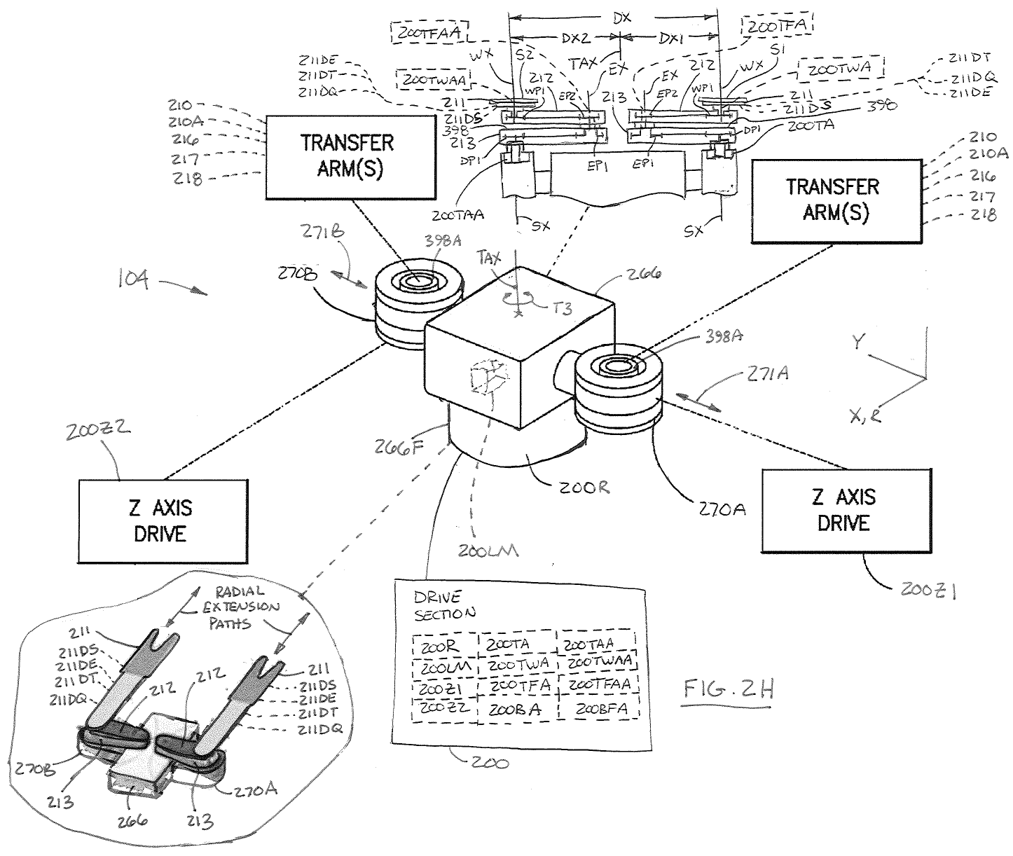

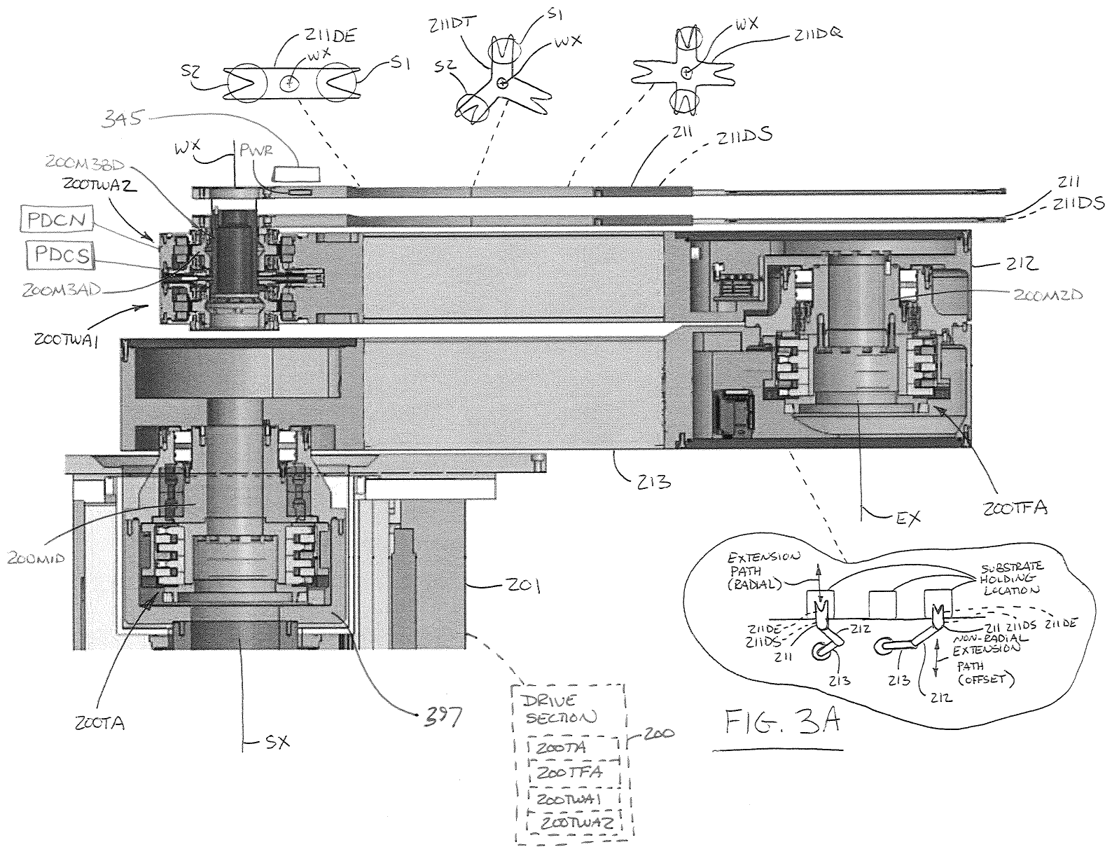

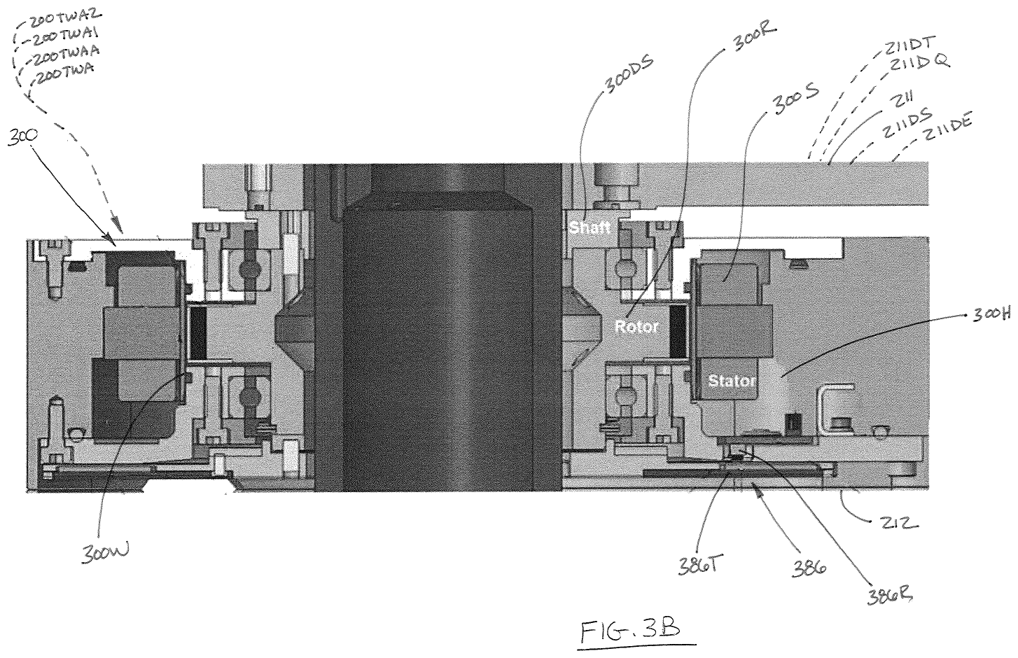

Referring to FIGS. 2A and 2B, exemplary boom arm configurations, to which the transfer unit module 104 may be coupled, will be described. The boom arm 143 and the transfer unit module 104 may collectively be referred to as a substrate transport apparatus (although, where the transfer unit module 104 is employed without the boom arm 143, the transfer unit module may be referred to as the substrate transport apparatus). The boom arm 143 may be a single unarticulated link boom arm 220 (FIG. 2A) or an articulated link boom arm 222 (FIG. 2B).

With reference to FIG. 2A, the single unarticulated link boom arm 220 is rotatably coupled to a frame or base 201 of the transport apparatus and is directly driven by a motor 200BA, the motor 200BA being substantially similar to the direct drive motor 500 (see FIGS. 5A-5C, also referred to herein as an axial flux brushless electrical/electric machine) described herein. The motor 200BA is coupled to the frame and disposed at the boom arm rotation axis BSX for directly driving the boom arm 143 in a manner similar to that described herein. The transfer unit module 104 is coupled to a distal end of the boom arm 143 (opposite the boom arm rotation axis BSX). While the transfer unit module 104 is illustrated as having a SCARA arm 210 (or dual SCARA arm 210, 210A) configuration, the transfer unit module 104 may have any suitable arm configuration including, but not limited to those described herein.

With reference to FIG. 2B, the articulated link boom arm 220 includes an upper boom link 220 that is rotatably coupled to a frame or base 201 (at the boom arm rotation axis BAX) of the transport apparatus at a proximate end of the upper boom link 220. The other or distal end of the upper boom link 220 is rotatably coupled to a proximate end of a forearm boom link 221 at a boom joint axis of rotation BEX, where the transfer unit module 104 is coupled to and supported by the forearm boom link 221 at a distal end of the forearm boom link 221. The upper boom link 220 is directly driven by the motor 200BA that is coupled to the frame 201 and located at the boom arm rotation axis BSX in a manner similar to that described herein.

The articulated link boom arm 222 may have a hybrid drive where the motor 200BA directly drives the upper boom link 220 and the forearm boom link 221 is slaved in rotation (e.g., a band and pulley transmission slaves rotation of the forearm boom link 221 to the frame 201). The forearm boom link 221 is directly driven by a motor 200BFA that is located at the axis of rotation BEX of the forearm boom link 221 and within at least one of the upper boom link 220 and the forearm boom link 221 (in a manner similar to that described herein, the motor 200BFA being substantially similar to the direct drive motor 500 (see FIGS. 5A-5C) described herein). The articulated link boom arm 222 may have any suitable number of links serially coupled to each other where one or more of the links are directly driven by a respective motor disposed at a respective axis of rotation of the one or more of the links. Suitable examples of boom arms that may be employed with the present disclosure are described in U.S. patent application Ser. No. 15/215,143 filed on Jul. 20, 2016 and titled “Substrate Processing Apparatus,” the disclosure of which is incorporated herein by reference in its entirety.

While the transfer unit module 104 in FIGS. 2A and 2B is illustrated as having a SCARA arm 210 (or dual SCARA arm 210, 210A) configuration, the transfer unit module 104 may have any suitable transfer arm configuration including, but not limited to those described herein. For example, the transfer unit module may have any other desired arrangement such as a frog-leg arm 216 (FIG. 2C) configuration, a leap-frog arm 217 (FIG. 2D) configuration, a bi-symmetric arm 218 (FIG. 2E) configuration, etc. The frog-leg arm 216 may be directly driven by a drive motor 200TA disposed at the shoulder axis SX of the frog-leg arm 216. Each end effector of the leap-frog arm 217 may be extended and retracted by a respective drive motor 200TA, 200TAA (disposed at the shoulder axis SX) that directly drives a respective frog-leg arm of the respective end effector 211, 211DS. The bi-symmetric arm 218 may be directly driven in extension and retraction by a drive motor 200TA disposed at the shoulder axis of the bi-symmetric arm 218. The motors 200TA, 200TAA being substantially similar to the direct drive motor 500 (see FIGS. 5A-5C) described herein.

With reference to FIG. 2C, a direct drive motor 200TWA, 200TWAA (such as described herein) may be located at each of the wrist joints where the frog leg links are coupled to the end effector 211, 211DS. The direct drive motors 200TWA, 200TWAA at the wrist joints may provide for driving the frog leg arm moves past any singularity that may exist in the extension/retraction of the arm. The direct drive motors 200TWA, 200TWAA at the wrist joints may provide for driving rotation of the end effector 211, 211DS about the wrist joints, skewing the end effector from a radial extension path so as to provide for automatic wafer centering and/or to assist with picking and placing of substrates. The other joints (e.g., such as at the elbows or shoulder axes) may be driven (such as by any suitable motors and/or transmissions), or not driven at all as the frog-leg arm may be extended and retracted by the motors 200TWA, 200TWAA at the wrist axes alone.

As another example, referring to FIG. 2F, transfer unit module 104 may be configured as the transfer arm 219. The transfer arm 219 includes at least a first and second articulated SCARA arm 210, 210A where each arm 210, 210A includes an end effector 211DS, 211, 211DE, 211DT, 211DQ configured to hold at least two substrates S1, S2 side by side in a common transfer plane (each substrate holding location of the end effector 211DS shares a common drive for picking and placing the substrates S1, S2) where the spacing DX between the substrates S1, S2 corresponds to a fixed spacing between side by side substrate holding locations. Referring to FIGS. 2F and 2G, the SCARA arm 210 (and arm 210A) includes an upper arm 213, a forearm 212, and an end effector 211, 211DS, 211DE, 211DT, 211DQ that are serially coupled to one another to form an articulated chain of arm links. At least one of the arm links 213, 212, 211 is directly driven by a respective drive motor 200TA, 200TAA, 200TFA, 200TFAA, 200TWA, 200TWAA (the drive motors being substantially similar to the direct drive motor 500 (see FIGS. 5A-5C) described herein) that is located at a respective joint SX, EX, WX of the transfer arm. Each of the arm links 213, 212 and end effector(s) 211, 211DS, 211DE, 211DT, 211DQ may be directly driven, although both the arm links 212, 211 and end effector(s) 211, 211DS, 211DE, 211DT, 211DQ may be slaved (e.g., by respective band/pulley transmissions), or the end effector 211, 211DS, 211DE, 211DT, 211DQ may be slaved (e.g., to the upper arm) while the links 213, 212 are directly driven in the manner described herein.

Suitable examples of transfer arms to which the present disclosure may be employed can be found in U.S. Pat. No. 6,231,297 issued May 15, 2001, U.S. Pat. No. 5,180,276 issued Jan. 19, 1993, U.S. Pat. No. 6,464,448 issued Oct. 15, 2002, U.S. Pat. No. 6,224,319 issued May 1, 2001, U.S. Pat. No. 5,447,409 issued Sep. 5, 1995, U.S. Pat. No. 7,578,649 issued Aug. 25, 2009, U.S. Pat. No. 5,794,487 issued Aug. 18, 1998, U.S. Pat. No. 7,946,800 issued May 24, 2011, U.S. Pat. No. 6,485,250 issued Nov. 26, 2002, U.S. Pat. No. 7,891,935 issued Feb. 22, 2011, U.S. Pat. No. 11,569,111 issued on Jan. 31, 2023, U.S. Pat. No. 8,752,449 issued on Jun. 17, 2014, U.S. Pat. No. 8,918,203 issued on Dec. 23, 2014, and U.S. Pat. No. 11,235,935 issued Feb. 1, 2022, and U.S. patent application Ser. No. 13/293,717 entitled “Dual Arm Robot” and filed on Nov. 10, 2011 and Ser. No. 13/270,844 entitled “Coaxial Drive Vacuum Robot” and filed on Oct. 11, 2011 the disclosures of which are all incorporated by reference herein in their entireties. Suitable examples of band/pulley transmission that may be employed in the present disclosure are described in U.S. Pat. No. 5,682,795 issued on Nov. 4, 1997, U.S. Pat. No. 5,778,730 issued on Jul. 14, 1998, and U.S. Pat. No. 11,201,073 issued Dec. 14, 2021, the disclosures of which are incorporated herein by reference in their entireties.

Referring to FIG. 2H, another transfer unit module 104 is illustrated. The transfer unit module of FIG. 2H, like the other transfer unit modules described herein, may be coupled to a boom arm 143 (see, e.g., FIGS. 1H, 2A and 2B) so as to be transported by the boom arm 143, to a linear carriage 144 (see, e.g., FIG. 1G) so as to be transported by the linear carriage 144, or stationarily fixed to a frame of the transport chamber 125A, 125B, 125C, 125D, 125E, 125F, 125G (or a frame of the mini-environment 106). The transfer unit module 104 includes a frame 266F, to which a turret 266 is rotatably coupled for rotation about a turret axis of rotation TAX. The drive section 200 includes a turret drive 200R disposed at the turret axis of rotation TAX that directly drives rotation of the turret 266 in direction T3, the turret drive 200R being substantially similar to the direct drive motor 500 (see FIGS. 5A-5C) described herein. The turret 266 includes transfer arm supports 270A, 270B that extend from opposite sides of the turret 266, and to which a respective transfer arm(s) 210, 210A, 216, 217, 218 are coupled. The transfer arm supports 270A, 270B are spaced apart from each other so that the respective transfer arms are supported by the turret 266 in a side by side arrangement, where the side by side transfer arms each include end effector(s) 211, 211DS, 211DE, 211DT, 211DQ configured to hold at least one substrate side by side in a common transfer plane where the spacing DX between the substrates S1, S2 corresponds to a fixed spacing between side by side substrate holding locations (e.g., in a manner similar to that described with respect to FIG. 2F and as described in U.S. Pat. No. 10,134,621 issued on Nov. 20, 2018, the disclosure of which is incorporated herein by reference in its entirety).

The turret 266 may include one or more linear motors 200LM that are coupled to a respective transfer arm support 270A, 270B for moving the respective transfer arm support 270A, 270B in direction 271A, 271B for effecting adjustment in the distance DX (or independent adjustment of the respective distance DX1, DX2 from the axis TAX) to account for substrate-holding-station to substrate-holding-station variability and the independent automatic wafer centering with respect to the transfer arm(s) held on the respective transfer arm support 270A, 270B and. The turret 266 provides for individual or independent Cartesian adjustment for each respective transfer arm supports 270A, 270B (and the respective transfer arm(s) coupled thereto) to maintain substrate alignment and reduce substrate swap times as position correction effected by the Cartesian (e.g., X-Y) positioning of the end effector 211, 211DS, 211DE, 211DT, 211DQ of at least one transfer arm coupled to transfer arm support 270A is performed in parallel with the Cartesian positioning of the end effector 211, 211DS, 211DE, 211DT, 211DQ of at least one other transfer arm coupled to transfer arm support 270B. Each transfer arm support 270A, 270B may include a respective Z-axis drive 200Z1, 200Z2 for moving the respective transfer arm(s) held on the transfer arm support 270A, 270B independent of Z axis movement of the respective transfer arms held on the other transfer arm support 270A, 270B. Another Z-axis drive may be provided for moving the turret 266 and any transfer arms coupled thereto as a unit in the Z direction.

Referring to FIGS. 5A-5C, one or more of motors 200R, 200TA, 200TWA, 200TFA, 200TAA, 200TWAA, 200TFAA, 200BA, 200BFA of the drive section 200 of the substrate transport apparatus (i.e., where the substrate transport apparatus is the transfer unit module 104 by itself or the transfer unit module 104 coupled to a boom arm 143) is an axial flux blushless motor or electrical machine 500. The motor 500 is a compact motor having a high torque. For example, the compact motor has a stator outer diameter of about 170 mm or less (with the stator surrounding/circumscribing the rotor). The high torque, for motor 500 with the stator sealed from the rotor by an isolation wall, is a torque of about twice that of a radial flux motor having a similar stator diameter and air gap. The high torque, for motor 500 with the stator sealed from the rotor using ferro-fluidic seals, is a torque of about five times that of a radial flux motor having a similar stator diameter and similar air gap. For exemplary purposes only, the motor with a stator outer diameter of about 170 mm has a peak torque of about 212 Nm and a torque density of about 53.0 Nm/kg, although the peak torque may be more or less than about 212 Nm and the torque density may be more or less than about 53.0 Nm/kg. With the stator sealed from the rotor by the isolation wall, the power of the motor 500 may be reduced by about 60% or less compared to the motor 500 without the stator sealed from the rotor by the isolation wall (but as noted above, even with the reduced power the motor 500 with the isolation wall produces a torque of about twice that of a radial flux motor having a similar stator diameter and air gap).

The motor 500 has a frame or housing 500H, an electrical machine stator 501, and an electrical machine rotor 505. The stator 501 is connected to the frame 500H and has a phase coil 501AC, 501BC, 501CC disposed in an atmospheric volume holding an atmospheric environment. The rotor 505 is cooperatively coupled to the stator 501 so as to generate an output under stimulation from the stator, where the rotor 505 is disposed in a sealed environment that is sealed from and different than the atmospheric volume. As will be described herein, a seal 510 seals the rotor 505 from the stator 501. As will be described herein, the rotor 505 and stator 501 are disposed in an axial gap arrangement with an axial gap between the rotor 505 and stator 501 disposed astride the stator 501. The seal or isolation wall 510 is arranged in the axial gap so as to seal each stator 501 from each rotor 505 stimulated by the stator 501 across the seal 510.

The stator 501 includes at least one phase or stator coils 501AC, 501BC, 501CC and rotors 505A, 505B, 505C,m 505D interleaved or interdigitated with each other. A portion of such axial flux motor 500 is illustrated in FIGS. 5A-5C. The motor 500 may include at least one phase coils 501AC, 501BC, 501CC (three are illustrated for exemplary purposes only, however there may be more or less than three stator coils) stacked or arrayed axially. Each stator coil 501AC, 501BC, 501CC is disposed on a respective concentrator ring 501AR, 501BR, 501CR (also referred to herein as stator rings), where the concentrator rings (inclusive of the coils) form the stator 501. The rotor 505 includes armatures 505A, 505B, 505C, 505D (also referred to as rotor rings-four are illustrated for exemplary purposes only, however there may be more or less than four, depending on the number of concentrator rings 501AR-501CR) that are stacked or arrayed axially, where the concentrator rings 501AR-501CR extend between the stacked armatures 505A-505D so as to be interleaved or interdigitated with the stacked armatures 505A-505D so as to have the axial gap arrangement with an axial gap between the stator and rotor portions (see FIGS. 5A and 5B). The axial gap arrangement is configured to that the stator 501 stimulates the rotor 505 across the axial gap.

As described herein, the substrate transport apparatus are employed in at least a (high) vacuum environment. The rotor 505 may be constructed of a magnetic permeable material (e.g., without permanent magnets) so as to be configured for employment in the vacuum environment. At least a portion of the interior of the arm links of the substrate transport apparatus may be exposed to the vacuum environment while other portions of the interior of the arm links may be exposed to an atmospheric environment. For example, as can be seen in FIG. 5A, the stator 501 is located within an interior portion of the arm link that is exposed to the atmospheric environment while the rotor 505 is disposed within an interior portion of the arm link that is exposed to the vacuum environment. To maintain separation of the vacuum and atmospheric environments the motor 500 (or arm link) includes the isolation wall or seal 510, that is static seal (i.e., no moving parts). The sealed environment (e.g., holding the vacuum) and the atmospheric environment, in the sealed volume, may be sealed respectively from each other by the isolation wall 510.

As described herein, the rotor 505 is constructed of a magnetic permeable material such that the motor 500 may operate as an induction motor having an axial air gap between the stator 501 and rotor 505 of between about 0.3 mm and about 1.0 mm and preferably between about 0.3 mm and 0.8 mm. The isolation wall 510 axially intervenes between each rotor element (e.g., each rotor ring 505A-505D) and each stator element (e.g., each stator/concentrator ring 501AR-501CR) that stimulates the rotor 505. For example, the isolation wall 510 is shaped and sized so as to be conformal to at least one of the stator 501 and rotor 505. The isolation wall 510 may follow a contour of the air gap between the stator 501 concentration rings 501AR-501CR (having respective coils 501AC-501CC) and the rotor 505 armatures 505A-505D of the rotor 505. As can be seen in FIGS. 5A and 5B, the isolation wall 510 has a serpentine cross section that follows the serpentine air gap between the stator 501 and rotor 505. The serpentine cross section includes at least one seal disc portion 510D that spans radially separating the stator 501 from the rotor 505 throughout the axial gap.

The isolation wall 510 is constructed of a non-magnetic material having a low electrical conductivity that can sustain the pressure differential load (e.g., between the atmospheric and vacuum environments) and allow for magnetic field passage between the stator 501 and rotor 505. A suitable material from which the isolation wall 510 may be constructed includes, but is not limited to, 300-series stainless steel.

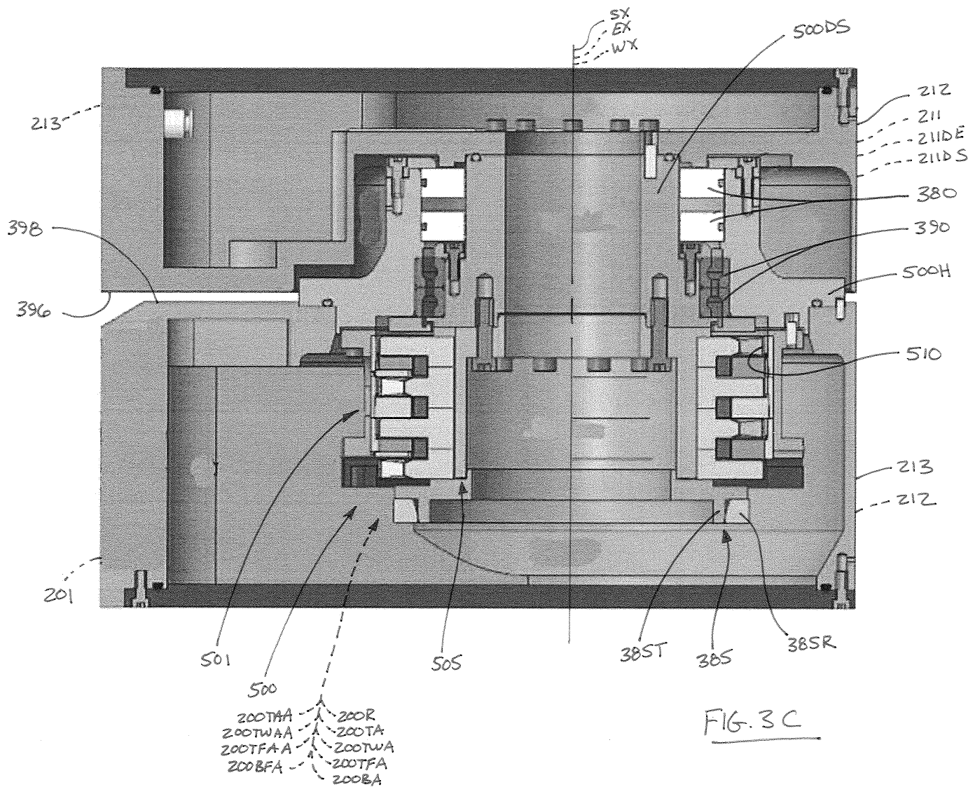

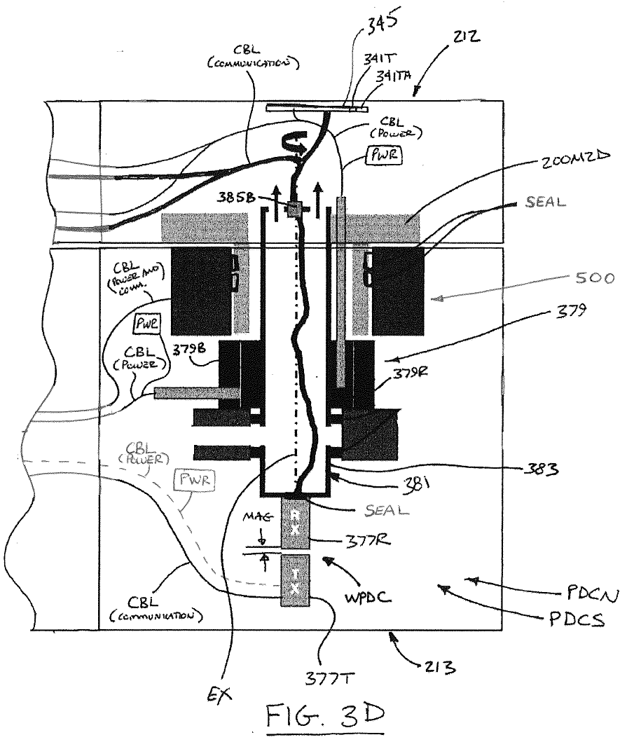

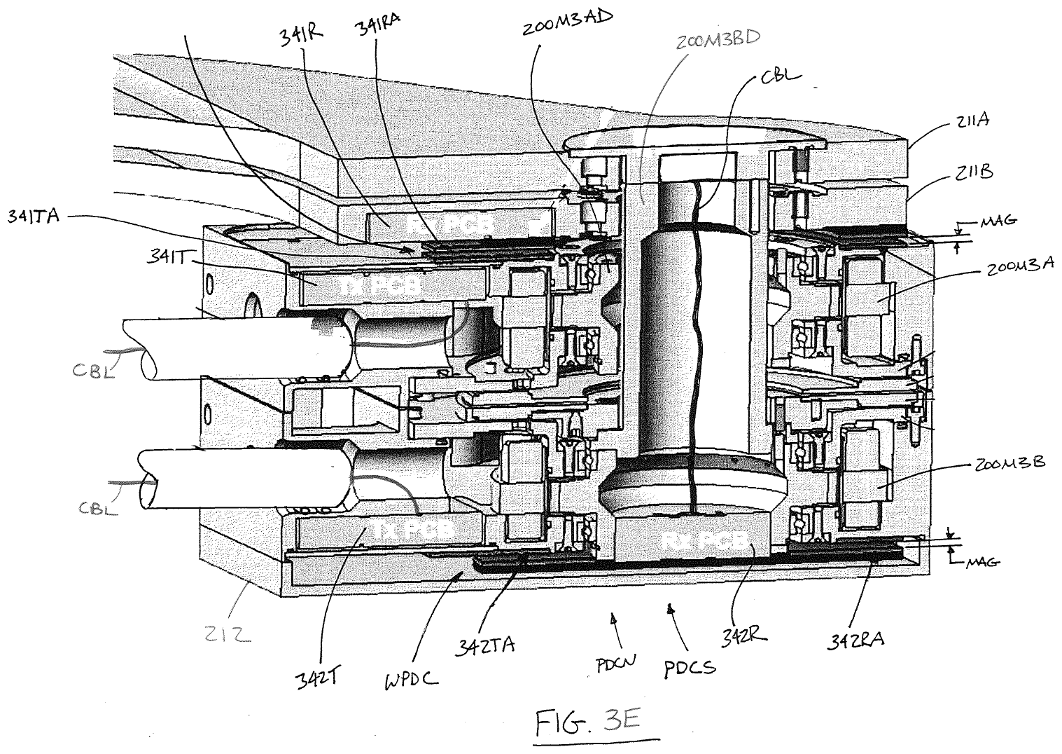

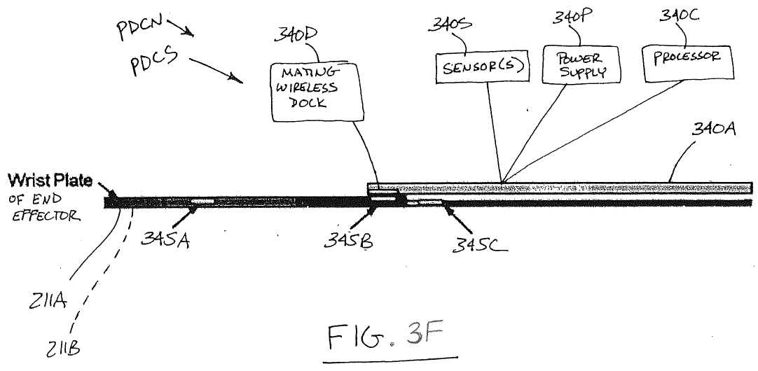

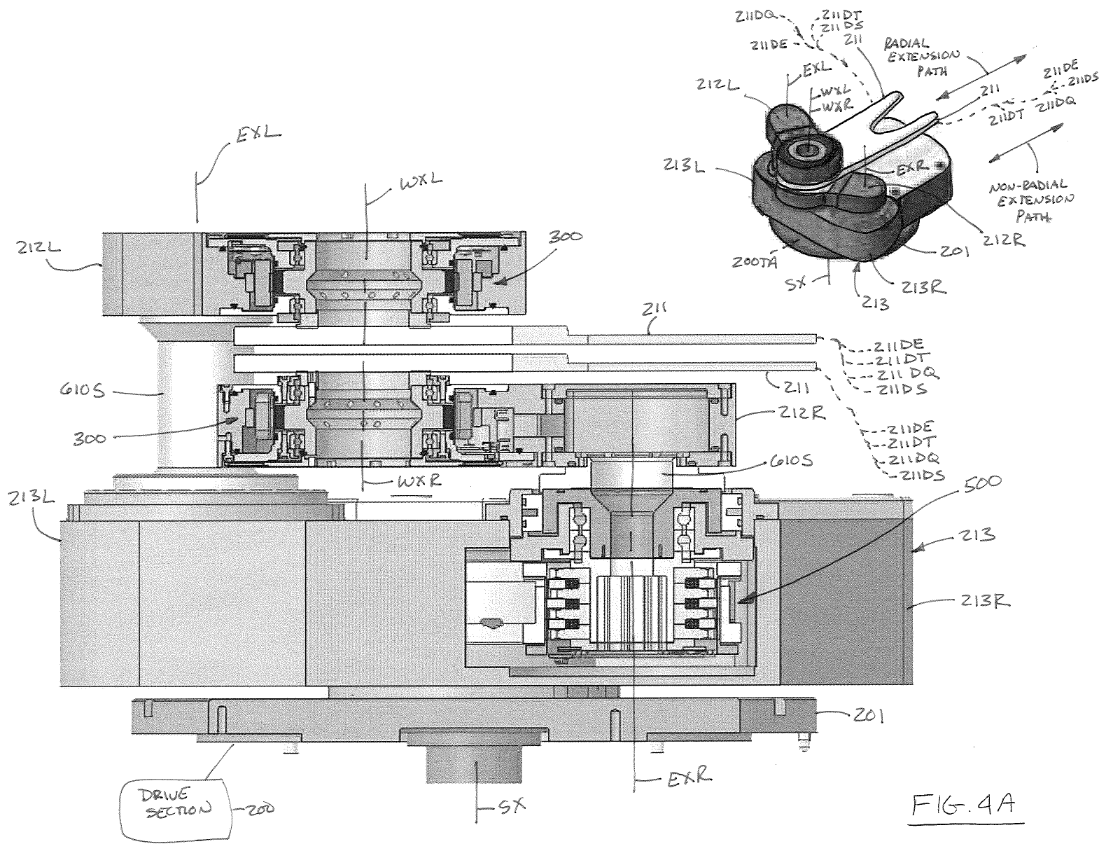

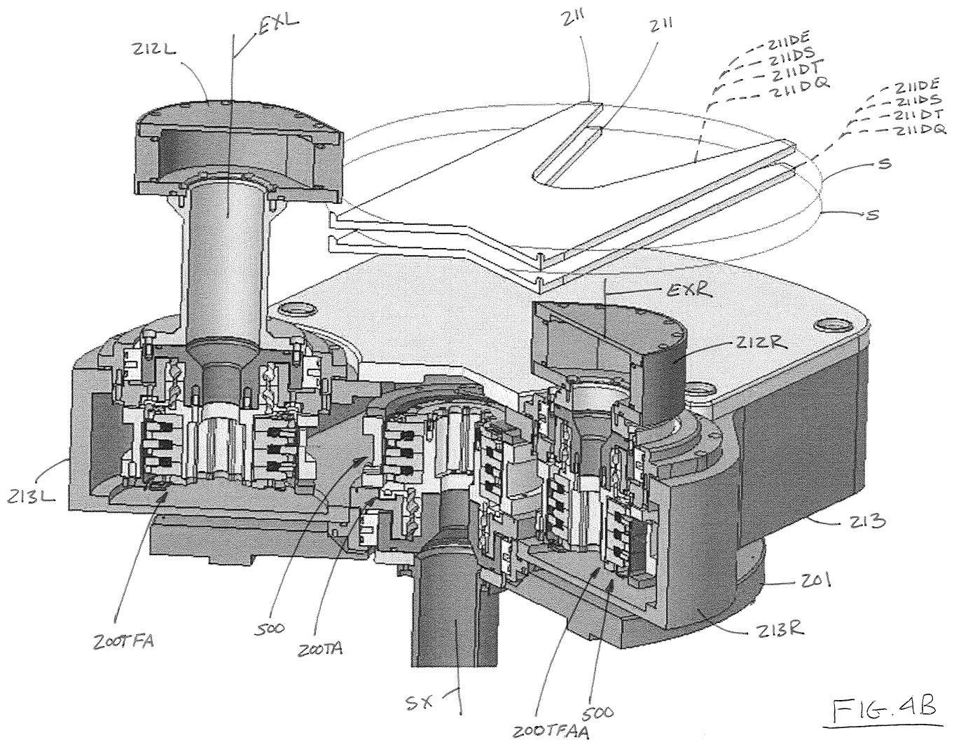

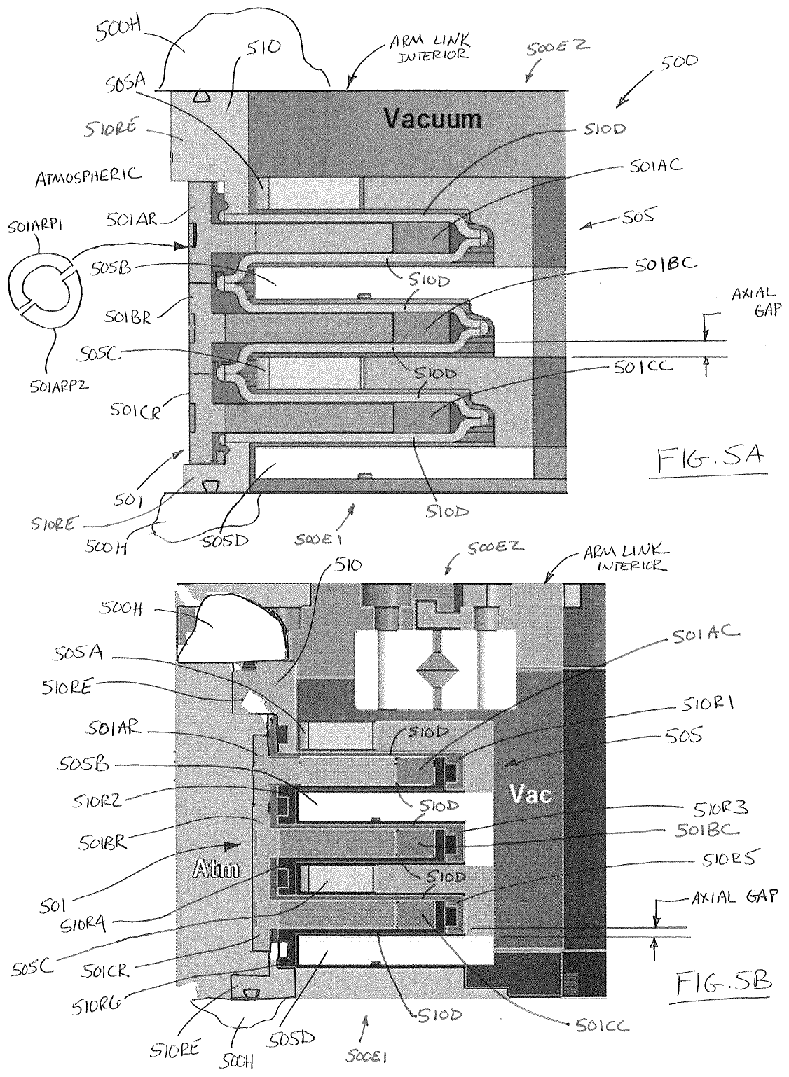

The isolation wall 510 may be constructed as a single unitary member (see FIG. 5A) that is hydro-formed or welded in a manner similar to the way a metal bellows is constructed so that the seal is a solid unitary seal with no radial splits. The isolation wall 510 is constructed of two or more isolation rings 510R1-510R6 that may be assembled/stacked with the stacking of the motor concentrator rings 501AR-501CR and rotor armatures 505A-505D. Each of the isolation rings 510R1-510R6 is sealed (e.g., via any suitable seal, such as an O-ring or other static seal) against one or more adjacent isolation rings 510R1-510R6 where terminal isolation rings (e.g., isolation rings 510R1, 510R6) may be sealed against the adjacent isolation ring (e.g., isolation ring 510R6 is sealed against adjacent isolation ring 510R5 and isolation ring 510R1 is sealed against adjacent isolation ring 510R2) and a respective isolation wall end cap 510RE (which is a monolithic, one-piece unitary structure or member) that forms a seal (e.g., via any suitable seal, such as an O-ring or other static seal) between the isolation wall 510 and a housing 500H of the motor 500 (see FIG. 3C) or interior of the arm link.

The motor components (e.g., the stator concentrator rings 501AR-501CR and the rotor armatures 505A-505D may be assembled around the isolation wall 510. The isolation wall 510 may provide support for the coils 501AC-501CC, where the coils 501AC-501CC may be fit to or otherwise seated on the isolation wall. For example, referring to coil 501AC, with the isolation wall 510 assembled (as illustrated in FIG. 5A with the isolation wall 510 as a unitary one piece member or in FIG. 5B with the isolation wall 510 formed of the isolation rings 510R1, 510R2) the coil is wound around and supported by the isolation wall 510 (in FIGS. 5A and 5B the windings of the coil 501AC extend into/out of the page). The concentrator ring 501AR is constructed in at least two portions 501ARP1, 501ARP2 that are each radially inserted (e.g., towards the center/axis of rotation of the motor 500) into the isolation wall 510 so as to be closely fit and interface with the respective coil 501AC and each other portion of the concentrator ring 501ARP1, 501ARP2. Again, referring to coil 501AC, the concentrator ring 501AR is radially inserted into the isolation wall 510 to closely fit with coil 501AC (e.g., so as to electrically interface with the coil 501AC), where the isolation wall 510 is closely fitted to the concentrator ring 501AR. As used herein, the expression closely fit or closely fitted means supporting, substantially touching, contacting, and/or being proximate to. Assembly of the coils 501BC, 501CC and the respective concentrator rings 501BR, 501CR may be assembled into the isolation wall 510 in a manner similar to that described above with respect to coil 501AC and concentrator ring 501AR.

As described above, the isolation wall 510 includes stacked seal disc portions 510D that span radially separating the stator 501 from the rotor 505 throughout the axial gap. Each of the seal disc portions 510D is a monolithic, one-piece unitary structure or member that may be joined together (e.g., via welding as in FIG. 5A or via seals as in FIG. 5B) to form the isolation wall 510. Assembly of the motor 500 includes a stepwise assembly. For example, still referring to FIGS. 5A and 5B, starting from end 500E1 of the motor 500, the rotor ring 505D is closely fitted to the isolation wall end cap 510RE. A seal disc 510D is coupled (at its radially outer side) to the isolation wall end cap 510RE, and another seal disc 510D is coupled (at its radially inner side) to the seal disc 510D so as to form a recess in which the coil 501CC and concentrator ring 501CR are disposed. The coil 501CC is wound within the recess and the concentrator ring portions 501ARP1, 501ARP2 of the concentrator ring 501CR may be inserted into the recess in the manner described herein so that the coil 501CC is supported by the isolation wall 510 and the concentrator ring 501CR is closely fit to the recess of the isolation wall 510. The rotor ring 505C is assembled to the rotor ring 505D and yet another seal disc 501D is coupled to the other seal disc 510D at its radially outer side and still another seal disc 510D is coupled (at its radially inner side) to the seal disc 510D so as to form a recess in which the coil 501BC and concentrator ring 501BR are disposed. The coil 501BC is wound within the recess and the concentrator ring portions 501ARP1, 501ARP2 of the concentrator ring 501BR may be inserted into the recess in the manner described herein so that the coil 501BC is supported by the isolation wall 510 and the concentrator ring 501BR is closely fit to the recess of the isolation wall 510. Assembly of the other rotor rings 505A-505D, coils 501AC-501CC, concentrator rings 501AR-501CR, and scal discs 510D is effected in a manner similar so that above so that a desired number of stator and rotor rings may be assembled and sealed from each other.

While some of the transfer arms are described herein as having a single-ended end effector 211, the transfer arms may include any one or more of: the single-ended end effector 211, a double-ended end effector(s) 211DE each being configured to hold at least two substrates S1, S2 on opposite sides of the wrist axis WX (see FIG. 3A), a side by side end effector 211DS, a triple end effector 211DT having substrate stations that are radially spaced from each other by about 120°, and a quad end effector 211DQ having holding stations that are radially spaced from each other by about 90°. Where the transfer unit module 104 has multiple arms, the different end effectors 211, 211DE, 211DS, 211DT, 211DQ may be employed on the multiple arms in any suitable combinations. Fast swapping of substrates at a substrate holding location may be performed by a single transfer arm having the double-ended effector 211DE by picking/placing a first substrate from/to a substrate holding location, rotating the transfer arm as a unit to change the facing direction of the double-ended end effector 211DE, and then placing/picking a second substrate to/from the same substrate holding location. Fast swapping of substrates at a holding location with a single transfer arm having the double-ended effector 211DE, the triple end effector 211DT, and the quad end effector 211DQ may be effected with rotation of the end effector with a direct drive motor located at the respective wrist joint/axis WX. For example, the transfer arm is extended to pick/place a first substrate from/to a substrate holding location, the transfer arm is retracted and the end effector is rotated to change the facing direction of the end effector 211DE, 211DT, 211DQ, and then extended to place/pick a second substrate to/from the same substrate holding location. Fast swapping of substrates with multiple transfer arms may be effected by extending a first transfer arm to pick/place a substrate from/to a substrate holding location, retracting the first transfer arm, and then extended a second transfer arm to place/pick a second substrate to/from the same substrate holding location (noting that one or more of the multiple arms may be configured as noted above to effect, by itself, a fast swap of substrates).

Where more than one holding station is included on an end effector, the different holding stations may be employed to transport objects having different levels of cleanliness. For example, one of the holding stations may be employed or designated to transport substrates S to be processed (e.g., in process substrates) while another of the holding stations may be employed or designated to transport processing equipment/accessories within the substrate processing apparatus (such as those described herein) that may not have the same cleanliness level as an in process substrate S.

Referring to FIGS. 2F, 2G, 2H, 3A-3C, 4A-4B, 6A-6B, 7, 8, and 9A-9C, exemplary arm and motor 500 configurations will be described with respect to SCARA or radius transfer arms that may be employed on a boom arm 143 (one or more of the SCARA arms may be disposed on the boom arm 143 as illustrated in FIGS. 2A and 2B) or without a boom arm 143. With reference to FIGS. 2F and 2G, the SCARA arms 210, 210A may be substantially similar to that illustrated in FIGS. 3A-3C, although in FIG. 3 the SCARA arm is illustrated with dual end effectors 211, 211DS, 211DE, 211DT, 211DQ disposed for rotation about a common wrist axis WX. The arm link 220 of the boom arm 143 in FIG. 2A may be substantially similar to the upper arm link of the SCARA arm in FIG. 3A and the arm links 220, 221 of the boom arm 143 in FIG. 2B may be substantially similar to the upper arm and forearm links of the SCARA arm in FIG. 3B (noting the boom arm motion is separate and distinct from the kinematic motion of the SCARA arm(s) (or transfer unit module 104) coupled thereto), where the link(s) of the boom arms 143 are similarly configured and driven in rotation in a manner similar to that of the arm links with respect to FIG. 3A.

For exemplary purposes, referring to FIGS. 2A-9C, the substrate transport apparatus includes a frame or base 201 to which the arm is coupled. The arm has a terminal joint (e.g., at the shoulder axis SX), about which the arm rotates and extends. The arm has more than one arm links 213, 212, 212L, 212R and an end effector 211, 322DC, 211DE, 211DT, 211DQ dependent therefrom. Each arm link 213, 212 is joined in series with the (respective) end effector 211, 322DC, 211DE, 211DT, 211DQ at a distal end of the SCARA arm.

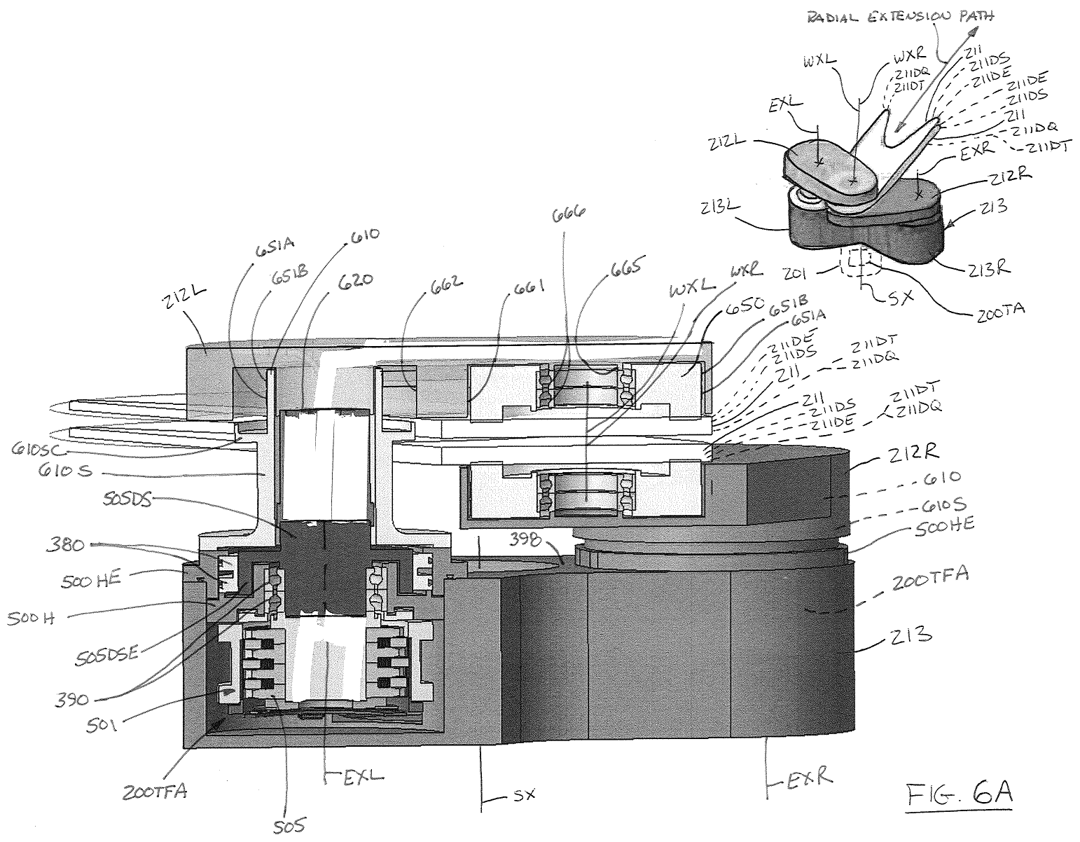

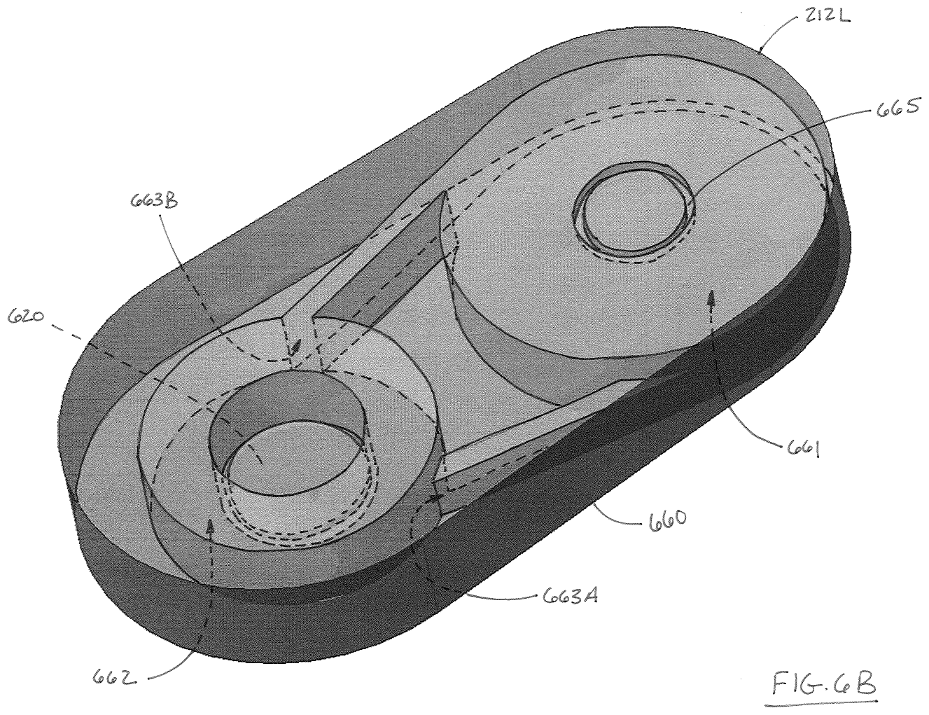

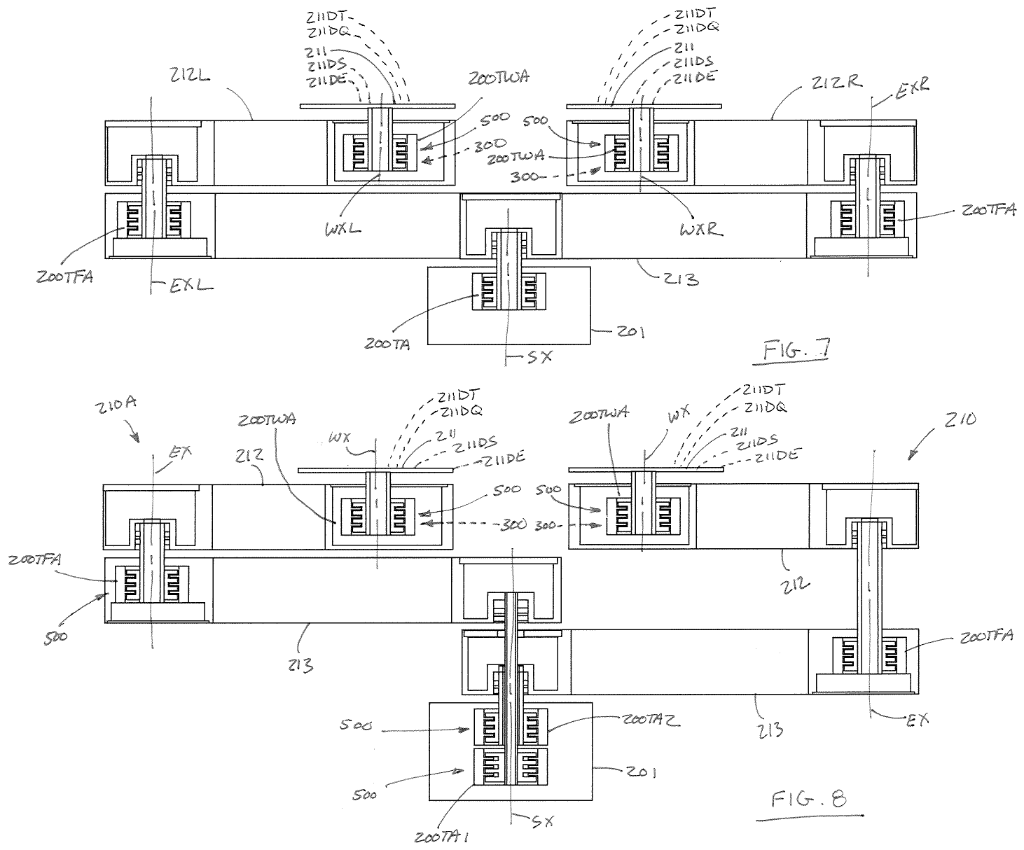

As can be seen in FIGS. 3A, 4A, 6A, 7, 8, and 9B the arm has a distributed drive section 200, with more than one degrees of freedom. The distributed drive section 200 is operably coupled to the arm to effect motion of the end effector 211, 322DC, 211DE, 211DT, 211DQ commensurate to the more than one degrees of freedom. An arm link 212, 212L, 212R, of the more than one arm links 213, 212, 212L, 212R, is a direct drive link dependent and directly driven from a direct drive motor 200TFA, 200TFAA, of the distributed drive section 200, disposed on the SCARA arm at a link joint (e.g., such as at the elbow axis EX, EXL, EXR) distal to the terminal joint SX. The end effector 211, 322DC, 211DE, 211DT, 211DQ, or at least another arm link 212, 212L, 212R of the more than one arm links 213, 212, is at least one of directly driven by another direct drive motor 200TWA1, 200TWA2, 200TFA, 200TFAA of the distributed drive section 200, on the arm, and slaved to the direct drive link 212, 213. The arms in FIGS. 3A, 4A, 7, 8, and 9 are illustrated with a drive motor 200TA, 200TFA, 200TWA1, 200TWA2 at each arm joint or axis SX, EX, WX (e.g., an all motor configuration) for exemplary purposes only; however, one or more of the arm links and end effector may be slaved as illustrated in FIGS. 6A and 2H (as described herein).

Referring to FIG. 3A, each of the drive motors 200TA, 200TFA, 200TWA1, 200TWA2 directly drives a respective arm link 213, 212 or end effector 211, 211DS, 211DE, 211DT, 211DQ and may each be referred to as a direct drive motor. As described herein the motors 200TA, 200TFA disposed at the shoulder axis AX and elbow axis EX are substantially similar to direct drive axial flux motor 500 described herein, where each direct drive motor 500, on the SCARA arm, has a sealed rotor 505 sealed from an atmospheric environment of the stator 501 of the direct drive motor 500 (see FIGS. 5A and 5B). The motors 200TWA1, 200TWA2 may be substantially similar to the axial flux motor 500; although the motors 200TWA1, 200TWA2 may be radial flux motors (also referred to herein as radial flux brushless electrical/electric machines) substantially similar to radial flux motor 300 illustrated in FIG. 3B. Having a motor at each joint of the SCARA arm provides for non-radial or offset extension path of the end effector, where the end effector 211, 211DS, 211DE, 211DT, 211DQ is maintained in alignment with a substrate holding station along the path with rotation of the end effector about the wrist axis SX by the respective wrist motor 200TWA1, 200TWA2 (scc FIG. 3A).

Referring also to FIG. 3C and also to FIGS. 5A and 5B, the motor 500 includes a housing 500H that houses at least the stator 501, where the isolation wall 500 seals against the housing 500H to isolate the stator 501 from any vacuum environment (where the motor or transfer arm is employed in a vacuum environment). Where the motor 500 is disposed at the elbow axis EX or wrist axis WX, the housing 500H is coupled to a surface 398 of the arm link 213 so that the stator 501 extends past the surface 398 into the arm link 213, which surface 398 opposes a surface 396 of the next link 212 (or end effector 211, 211DS, 211DE, 211DT, 211DQ) in the serially coupled arm links. Where the motor 500 is disposed at the shoulder axis SX the housing 500H is coupled to any suitable motor support 397 of the frame 201 so that the stator 501 is disposed at least partially within the frame 201.

The housing 500H extends above the surface 398 (or frame 201) so as to form a stanchion to which the rotor 505 is coupled. For example, the housing 500H forms an aperture, the internal wall of which includes one or more bearings 390 and one or more seals 380. The rotor 505 is coupled to an output or drive shaft 505DS that extends through the aperture of the housing 500H so that the drive shaft 505DS (and the rotor 505 coupled thereto) are supported by the one or more bearings 390 and sealed against the housing 500H by the seals 380. The seals 380 may be any suitable seals such as ferro-fluidic seals. The drive shaft 505DS is coupled to the surface 396 of the next link 212 (or end effector 211, 211DT, 211DQ, 211DS, 211DE) so that the next link 212 (or end effector 211, 211DS, 211DE, 211DT, 211DQ) is supported by and integral with the drive shaft 505DS (e.g., the drive link is a direct drive link that has an integral motor rotor of the direct drive motor directly driving the link). As can be seen in FIG. 3C, the direct drive motor 500, at the joint SX, EX, WX, and the direct drive link 212, 211, 211DE, 211DS, 211DT, 213 driven by the direct drive motor 500 are coupled to each other with a transmission-less coupling formed by the coupling between the stator 501 and rotor 505. The surface 396 of the next link 212 may be a recessed surface so as maintain the stacked arm links in close proximity to one another, where a portion of the motor housing is disposed in a height both arm links.

Referring to FIG. 3B, the wrist axis WX may include one or more radial flux motors 300 (see FIG. 3B) having a stator 300S, a rotor 300R, and an output or drive shaft 300DS coupled to the rotor 300R. The end effector 211, 211DS, 211DE, 211DT, 211DQ is coupled to the drive shaft 300DS for rotation about the wrist axis WX. The stator 300S may be sealed, from any vacuum environment in which the transfer arm operates, by any suitable isolation wall 300W. Suitable examples of a radial flux motor that can be incorporated into the wrist axis WX are described in U.S. Pat. No. 9,948,155 issued Apr. 17, 2018, previously incorporated by reference herein in its entirety.

Referring to FIGS. 3C, 4A, and 6A, the motors 500 may be installed and removed from the arm links 212, 212L, 212R, 213 or frame 201 as modular units so that one or more direct drive motors 500 at a respective joint or axis SX, EX may be configured with part of a pulley transmission and/or one or more direct drive motors at joint or axis WX may be swapped with a pulley of the pulley transmission. For example, the motors 200TFA, 200TFAA may be selectably replaced or swapped in a modular fashion from the motor configuration illustrated in FIG. 5C (e.g., an all motor configuration) with the motor configuration illustrated in 6A (e.g., with the drive pulley 620 for a slaved configuration). The arm link 212 in FIG. 3A may be selectively swapped with the arm link 212L (see FIG. 6B) including the wrist driven pulley 650 to complete the transmission for slaving the end effector 211, 211DS, 211DE, 211DT, 211DQ to the surface 398 of the arm link 213. As such, the SCARA arm is selectably configurable between a hybrid configuration wherein the end effector 211, 211DS, 211DE, 211DT, 211DQ, or at least the other arm link 212, 212L, 212R of the more than one arm links 212, 212L, 212R, 213, is slaved to the direct drive link (such as in FIGS. 2H and 6A), and an all motor configuration (such as in FIGS. 3A, 7, and 8) wherein the end effector 211, 211DS, 211DE, 211DT, 211DQ, or at least the other arm link 212, 212L, 212R of the more than one arm links is directly driven by the other direct drive motor so that in the all motor configuration, each arm link 212, 212L, 212R, 213 and the end effector are directly driven by a respective direct drive motor.

Referring to FIG. 3B, the motors 500, 300 include any suitable encoders 385, 386 for sensing or otherwise detecting rotation of the respective rotor 505, 300R. The encoders 385, 386 may be coupled to the controller 110 in any suitable manner, such as with the electrical conductors EC or with a wireless connection. The encoders 385, 386 may be any suitable encoders including, but not limited to, optical, magnetic, and electromagnetic induction encoders. Each encoder 385, 386 includes a read head 385R, 386R and an encoder track 385T, 386T. The read head 385R, 386R is coupled in a fixed location to the motor housing 500H, 300H in any suitable manner, and may be isolated from any vacuum atmosphere by any suitable isolation wall (e.g., that is optically clear and/or non-magnetic). The encoder track 385T, 386T is coupled to and rotates as a unit with the rotor 505, 300R. The encoder 385, 386 provides signals, that embody a motor position, to the controller 110 for effecting kinematic motion of the transfer arm of the transfer module unit 104 and/or the boom arm 143.

Although the transfer unit module 104 or substrate transport apparatus is illustrated as having a single SCARA arm in FIG. 3A, more than one independently movable SCARA arm may be provided. For example, referring to FIGS. 2A, 2B, and 8, the frame 201 includes, for example, two drive motors 200TA1, 200TA2 coaxially arranged at the shoulder axis SX for directly driving a respective upper arm 213 of a respective one of the SCARA arms 210, 210A. Each SCARA arm 210, 210A includes a drive motor 200TFA at the elbow axis EX for directly driving a respective forearm 212. Each SCARA arm 210, 210A may include a drive motors 200TWA at the wrist axis WX for directly driving a respective end effector(s) 211, 211DS, 211DE, 211DT, 211DQ. The upper arm 213 and forearm 212 may have substantially equal lengths from joint center to joint center (see FIGS. 2A and 2B); although, the upper arm 213 and forearm 212 have unequal lengths from joint center to joint center. For exemplary purposes, in FIG. 8 the forearm 212 is shorter in length than the upper arm 213 for each of the SCARA arms 210, 210A. The shorter forearms 212 provide for placement of the forearm 212 of SCARA arm 210 in a common plane with the forearm 212 of the SCARA arm 210A. Likewise, the end effectors 211, 211DS, 211DE, 211DT, 211DQ of the SCARA arms 210, 210A may be disposed in a common plane with each other. The drive motors 200TA2, 200TFA, 200TWA of SCARA arm 210 may be driven substantially simultaneously to extend the end effector 211, 211DS, 211DE, 211DT, 211DQ along a substantially straight line path or trajectory. The drive motors 200TA1, 200TFA, 200TWA of SCARA arm 210A may be driven substantially simultaneously to extend the end effector 211, 211DS, 211DE, 211DT, 211DQ along a substantially straight line path or trajectory.

Referring again to FIG. 2H, as described herein, one or more of the arm links may be slaved in rotation, rather than directly driven. FIG. 2H illustrates an example where the upper arm link 213 of each transfer arm is directly driven by a respective motor 200TA, 200TAA while the forearm links and end effectors are slaved (e.g., by any suitable transmission such as a band and pulley transmission substantially similar to that illustrated and described with respect to FIGS. 6A and 6B herein) in rotation to maintain alignment of the end effector along a radial axis of extension and retraction. For example, a drive pulley DPI may be disposed within the upper arm 213 at the shoulder axis SX where the shoulder drive pulley is fixed to a respective motor housing 500H or a respective one of the transfer arm supports 270A, 270B in a manner similar to that described with respect to pulley 610 in FIG. 6A. An elbow driven pulley EPI is disposed within the upper arm 213 at the elbow axis EX and fixed to the forearm 212 so as to rotate as a unit with the forearm 212. One or more bands (or belts) coupled the shoulder drive pulley DPI to the elbow driven pulley EPI to constrain rotation of the forearm 212 as the upper arm 213 is rotated by the respective drive motor 200TA, 200TAA. An elbow drive pulley EP2 is (non-rotatably) fixed to the surface 398 (e.g., the surface facing the forearm 212) of the upper arm 213 in a manner similar to that described with respect to pulley 610 in FIG. 6A. A wrist driven pulley WPI is disposed within the forearm 212 at the wrist axis WX and fixed to the end effector 211, 211DS, 211DE, 211DT, 211DQ so as to rotate as a unit with the end effector 211, 211DS, 211DE, 211DT, 211DQ. One or more bands (or belts) coupled the elbow drive pulley EP2 to the wrist driven pulley WPI to constrain rotation of the end effector 211, 211DS, 211DE, 211DT, 211DQ as the forearm 212 is rotated in slaved response to rotation of the upper arm 213 by the respective drive motor 200TA, 200TAA. A 1:2 and 2:1 pulley ratio is employed respectively within the upper arm 213 and forearm 212 to maintain alignment of the end effector 211, 211DS, 211DE, 211DT, 211DQ along a radial path of extension and retraction (the radial path of extension/retraction passing through the shoulder axis SX).

An example of grounding or non-rotatably fixing a drive pulley (of a slaved transmission) to a surface 398 of the upper arm 213 (or motor housing 500H or a (top) surface 398A of the transfer arm supports 270A, 270B (the identifier “top” being used for convenience noting any suitable identifier may be used to denote the outer surface of the turret oriented in any suitable direction)) is illustrated in FIG. 6A, where a similar pulley grounding may be employed at the shoulder axis SX with respect to the shoulder drive pulley. This exemplary grounding of drive pulleys (of slaved transmissions) may be employed for any drive pulley (of a slaved transmission) of any of the transfer arms of the transfer module units 104 or links of the boom arms 143 described herein. Referring to FIG. 6A, an exemplary dual SCARA transfer arm where the forearms 212R, 212L extend from opposite ends of a common upper arm 312 is illustrated. Suitable examples of a transport apparatus having a common upper arm arrangement to which the present disclosure may be employed is described in, for example, U.S. Pat. No. 8,376,685 issued on Feb. 19, 2013 and U.S. Pat. No. 8,752,449 issued on Jun. 17, 2014, the disclosures of which are incorporated herein by reference in their entireties. The dual SCARA transfer arm may include upper arm 213, two forearms 212R, 212L depending from opposite ends 213R, 213L (e.g., relative to the shoulder axis SX) of the common (substantially rigid and unarticulated) upper arm 213. Forearm 212R is coupled to end 213R of the upper arm 213 at elbow axis EXR. Forearm 212L is coupled to end 213L of the upper arm 213 at elbow axis EXL. Each forearm 212R, 212L has at least one end effector 211, 211DS, 211DE, 211DT, 211DQ coupled thereto at a respective wrist axis WXR, WXL. In FIG. 6A, the rotation of the end effectors 211, 211DS, 211DE, 211DT, 211DQ may be slaved to the respective upper arm portion; however, a drive motor 500, 300 may be provided at the wrist axis for directly driving the rotation of the end effectors 211, 211DS, 211DE, 211DT, 211DQ. In the manner described herein, providing drive motors at each axis SX, EXR, EXL, WXR, WXL effects non-linear or offset extension of the end effectors 211, 211DS, 211DE, 211DT, 211DQ where the drive motors are driven substantially simultaneously to extend the end effector 211, 211DS, 211DE, 211DT, 211DQ along a radial or non-radial path or trajectory.

The upper arm 213 is coupled to the frame 201 and is directly driven by drive motor 200TA in a manner similar to that described herein with respect to FIGS. 3A-3C. Each forearm 212R, 212L is directly driven by a respective drive motor 200TFA in a manner similar to that described herein with respect to FIGS. 3A-3C; however, to accommodate the grounding of the elbow drive pulley 610 to the surface 398 of the upper arm 213, the drive shaft 505DS may include an annular extension 505DSE that extends from the extends from the drive shaft so as to at least partially circumscribe (so as to maintain a compact height of the motor 500, 200TFA) the bearings 390 that support and couple the drive shaft 505DS to the housing 500H. The housing 500H includes an annular extension 500HE that is coplanar with the annular extension 500DSE of the drive shaft 500DS, where the seals 380 are disposed between the annular extension 500HE and the annular extension 500DSE.

As illustrated in FIG. 6A, the elbow drive pulley 610 is disposed on a stanchion 610S. The elbow drive pulley 610 and the stanchion 610S may be of a unitary one-piece construction or coupled to each other in any suitable manner (e.g., such as with any suitable mechanical and/or chemical fasteners). The stanchion 610S (and elbow drive pulley 610) circumscribe the drive shaft 505DS and are non-rotatably coupled to the annular extension 500HE of the housing 500H, which as described above, the housing 500H is coupled to the surface 389 of the upper arm 213 (e.g., grounding the elbow drive pulley 610 to the surface 398). As can be seen in FIG. 6A, the stanchion 610S may have any suitable height or length depending on the arm configuration so that at least a portion of the forearms 212R, 212L and the respective end effectors 211, 211DS, 211DE, 211DT, 211DQ are stacked one over one another (e.g., at least with the forearms and end effectors in the retracted configuration illustrated in FIG. 6A).

Referring also to FIG. 6B, the forearms 212R, 212L are configured so as to receive the elbow drive pulley 610, a wrist driven pulley 650, and band(s) coupling the elbow drive pulley 610 to the wrist driven pulley 650. While the forearm configuration is described herein with respect to forearm 212L, it should be understood that the forearm 212R has a substantially similar configuration. The forearm 212L has a housing 660 that includes a driven pulley recess 661 and a drive pulley recess 662. The driven and drive pulley recesses 661, 662 are connected by band recesses 663A, 663B. The drive pulley recess 662 includes a drive shaft mount 620 to which the drive shaft 505DS is coupled so that the forearm 212L rotates as a unit with the drive shaft 505DS. With the forearm 212L mounted to the drive shaft 505DS, the elbow drive pulley 610 extends into the drive pulley recess 662 and circumscribes the drive shaft mount. The stanchion 610S may include an annular cup 610SC that extends from the stanchion 610S and interfaces with the drive pulley recess 662 so as to form a labyrinth seal with or otherwise substantially enclose the drive pulley recess 662.

The driven pulley recess 661 is shaped and sized to receive the wrist driven pulley 650 (the ratio between the elbow drive pulley 610 and the wrist driven pulley 650 being a 1:2 ratio or any other suitable ratio). The driven pulley recess includes a bearing mount 665 to which bearings 666 are coupled, where the wrist driven pulley 650 is coupled to the bearings 666 for rotation about the wrist axis WX. Bands 651A, 651B extend through a respective band channel 663A, 663B and are wrapped around the drive and driven pulleys 610, 650 in an opposing manner so that each band 651A, 651B is always tensioned against the other band 651A, 651B. The end effector 211, 211DS, 211DE, 211DT, 211DQ is coupled to the wrist driven pulley 650 so as to rotate as a unit with the wrist driven pulley 650. The end effector 211, 211DS, 211DE, 211DT, 211DQ is shaped and sized so that the end effector substantially encloses (or forms a labyrinth seal with) the driven pulley recess 661. The housing 660 of the forearm 212L may include any suitable covers for enclosing the band channels 663A, 663B. As described herein, in FIG. 6A the rotation of the end effector 211, 211DS, 211DE, 211DT, 211DQ is slaved to the surface 389 of the upper arm 213. As the transfer arm is extended, the rotation of the end effector 211, 211DS, 211DE, 211DT, 211DQ is constrained so that the end effector remains aligned with and travels along a radial axis of extension and retraction R.

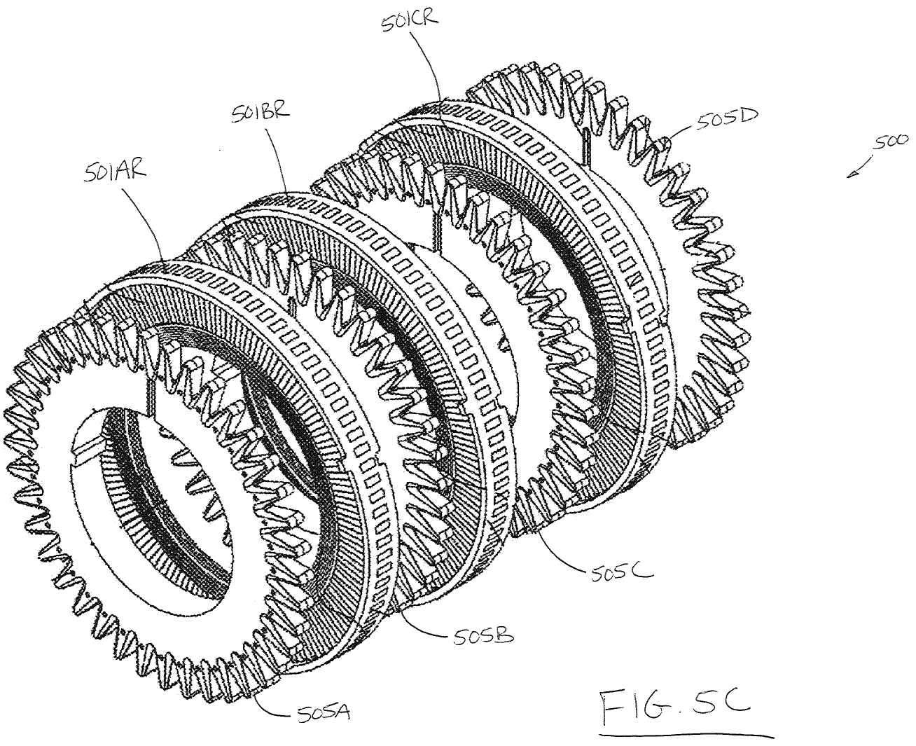

Referring to FIGS. 4A and 4B, a transfer arm similar to that of FIG. 6A is illustrated; however, the transfer arm may include axial flux direct drive motors 500 at the shoulder axis SX and elbow axes EXR, EXL and a radial flux direct drive motor 300 are the wrist axes WXR, WXL (although an axial flux motor 500 may be employed at the wrist axes). As described herein, providing motors at each joint or axes SX, EXR, EXL, WXR, WXL effects movement of the end effectors 211, 211DS, 211DE, 211DT, 211DQ along radial and non-radial paths of travel.

Referring to FIG. 7, the dual SCARA arm of FIG. 6A may include drive motors at each joint SX, EXR, EXL, WXR, WXL and have unequal length arm links. For example, in FIG. 7 the forearm 212 is shorter in length than the respective upper arm portion 213R, 213L. The shorter forearms 212 provide for placement of the forearms 212R, 212L in a common plane. Likewise, the end effector(s) 211, 211DS, 211DE, 211DT, 211DQ coupled to the forearms 212R, 212L may be disposed in a common plane with each other. The drive motors 200TA, 200TFA, 200TWA may be driven substantially simultaneously to extend the end effector(s) 211, 211DS, 211DE, 211DT, 211DQ along a substantially straight line path or trajectory. As the end effector corresponding to one of arm portions 213R, 213L is extended to pick or place a substrate, the end effector corresponding to the other arm portion 213R, 213L may remain retracted (so as not to pick or place a substrate) or extend in substantially the opposite direction (so as to pick or place a substrate).

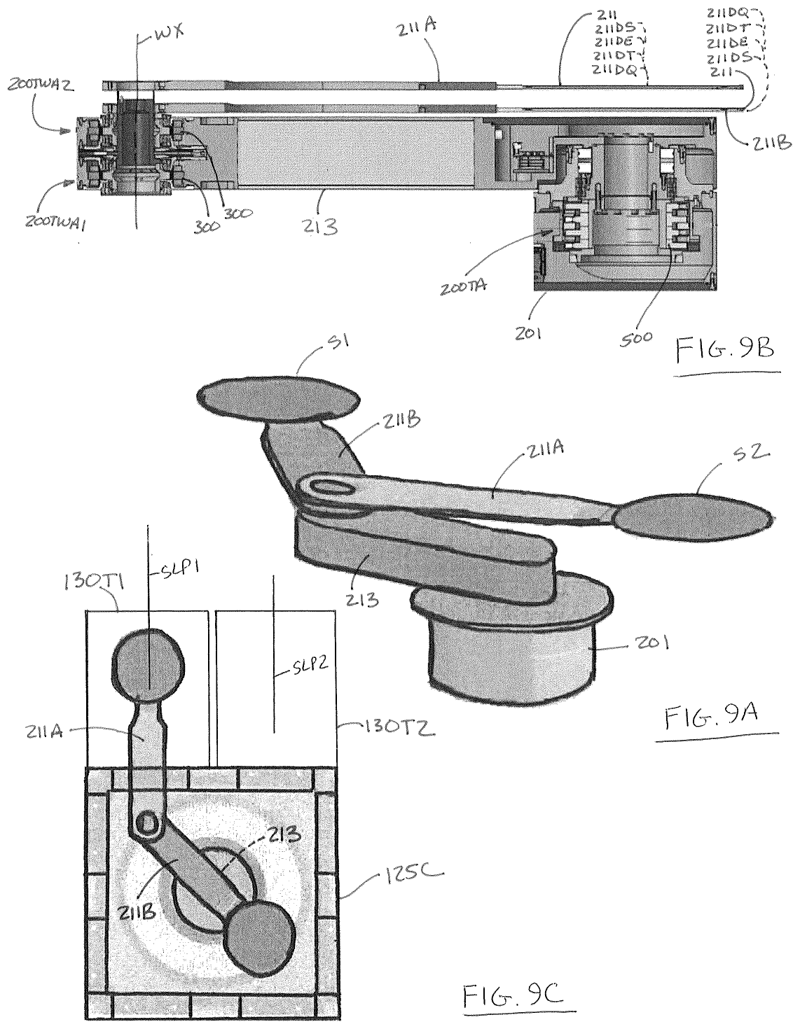

Referring to FIGS. 9A-9C, another exemplary transfer arm configuration is illustrated. The transfer arm may include the frame 201, a single arm link 213, and one or more end effectors 211, 211DS, 211DE, 211DT, 211DQ. The single arm link 213 is an unarticulated arm link that is coupled to and directly driven in rotation about the shoulder axis SX by the drive motor 200TA (which is substantially similar to drive motor 500). The coupling between the single arm link 213 and the drive motor 200TA may be substantially similar to that described herein with respect to FIG. 3C. Each of the end effectors 211, 211DS, 211DE, 211DT, 211DQ is coupled to and directly driven in rotation about the wrist axis WX by a respective drive motor 200TWA1, 200TWA2. The coupling between the end effectors 211, 211DS, 211DE, 211DT, 211DQ and the respective drive motor 200TWA1, 200TWA2 is substantially similar to that described herein with respect to FIG. 3B. While the drive motors 200TWA1, 200TWA2 are illustrated as radial flux motors 300, one or more of the drive motors 200TWA1, 200TWA2 may be axial flux motors 500.

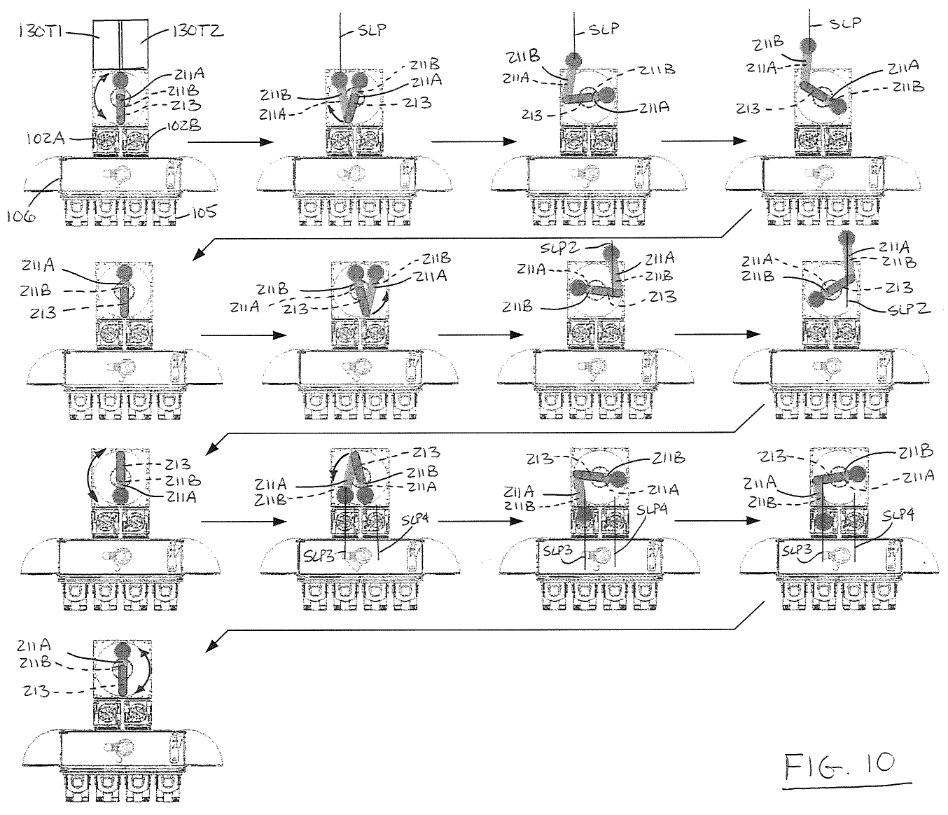

Still referring to FIGS. 9A-9C, and also to FIG. 10, the end effectors will be denoted 211A, 211B for sake of differentiating the end effectors for description purposes. The transfer arm is illustrated in FIG. 9C as being disposed within a transfer chamber 125C substantially similar to that illustrated in FIG. 1D, having side-by-side process modules 130T1, 130T2 (only two of which are shown in FIGS. 9C and 10). In operation, to place or pick a substrate S to process module 130T1 with end effector 211B the transfer arm is rotated as a unit in a clockwise or counter-clockwise direction so that the end effector 211B faces a side of the transfer chamber 125C to which the process module 130T1 is coupled. The motor 200TA may rotate the arm link 213, while motors 200TWA1, 200TWA2 may be energized to maintain the end effectors 211A, 211B in substantial alignment with the arm link 213 throughout rotation of the arm link 213. To extend the end effector 211B into the process module 130T1, the drive motor 200TA rotates the arm link 213 in a clockwise direction while the motor 200TWA2 rotates end effector 211B in a counter-clockwise direction so that the substrate S travels along an offset (relative to the shoulder axis SX) substantially straight line path SLP1 into the process module 130T1. The motor 200TWA1 may be energized to maintain the end effector 211A in substantial alignment with the arm link 213 throughout rotation of the arm link 213 and extension/retraction of end effector 211B to/from the process module 130T1. Retraction of the end effector 211B from the process module 130T1 is effected in a manner substantially opposite that described above into the process module 130T1. Extension and retraction of the end effector 211A into process module 130T1 is effected in a manner similar to that described above with respect to end effector 211B.

To place or pick a substrate S to process module 130T2 with end effector 211A the transfer arm is rotated as a unit in a clockwise or counter-clockwise direction so that the end effector 211A faces a side of the transfer chamber 125C to which the process module 130T2 is coupled. The motor 200TA may rotate the arm link 213, while motors 200TWA1, 200TWA2 may be energized to maintain the end effectors 211A, 211B in substantial alignment with the arm link 213 throughout rotation of the arm link 213. To extend the end effector 211A into the process module 130T2, the drive motor 200TA rotates the arm link 213 in a counter-clockwise direction while the motor 200TWA1 rotates end effector 211B in a clockwise direction so that the substrate S travels along an offset (relative to the shoulder axis SX) substantially straight line path SLP2 into the process module 130T2. The motor 200TWA2 may be energized to maintain the end effector 211B in substantial alignment with the arm link 213 throughout rotation of the arm link 213 and extension/retraction of end effector 211A to/from the process module 130T2. Retraction of the end effector 211A from the process module 130T2 is effected in a manner substantially opposite that described above into the process module 130T2. Extension and retraction of the end effector 211B into process module 130T2 is effected in a manner similar to that described above with respect to end effector 211A.

To place or pick a substrate S to load lock 102A with end effector 211A the transfer arm is rotated as a unit in a clockwise or counter-clockwise direction so that the end effector 211A faces a side of the transfer chamber 125C to which the load lock 102A is coupled. The motor 200TA may rotate the arm link 213, while motors 200TWA1, 200TWA2 may be energized to maintain the end effectors 211A, 211B in substantial alignment with the arm link 213 throughout rotation of the arm link 213. To extend the end effector 211A into the load lock 102A, the drive motor 200TA rotates the arm link 213 in a counter-clockwise direction while the motor 200TWA1 rotates end effector 211A in a clockwise direction so that the substrate S travels along an offset (relative to the shoulder axis SX) substantially straight line path SLP3 into the load lock 102A. The motor 200TWA2 may be energized to maintain the end effector 211B in substantial alignment with the arm link 213 throughout rotation of the arm link 213 and extension/retraction of end effector 211A to/from the load lock 102A. Retraction of the end effector 211A from the load lock 102A is effected in a manner substantially opposite that described above into the process module 130T2. Extension and retraction of the end effector 211B into load lock 102A is effected in a manner similar to that described above with respect to end effector 211A. Extension of the end effectors 211A, 211B into load lock 102B along the substantially straight line path SLP4 is effected in a manner substantially similar to that described above with respect to extension into process module 130T1. The transfer arm may be rotated as a unit in the clockwise or counter-clockwise direction in a manner similar to that described above to pick/place substrate to any of the process modules 130 or load locks 102A, 102B coupled to the transfer chamber 125C (see FIG. 1D).

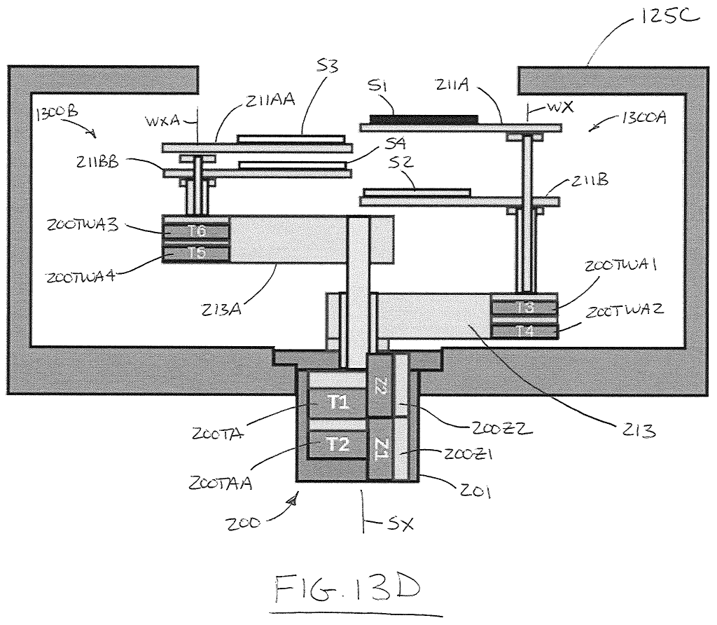

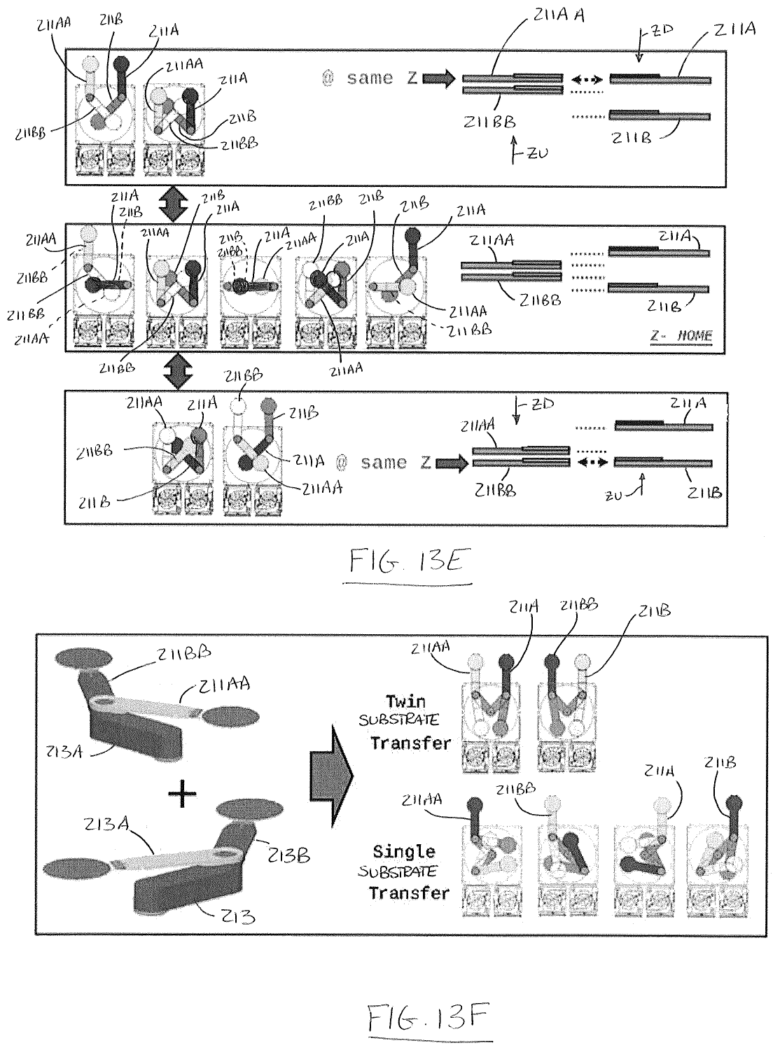

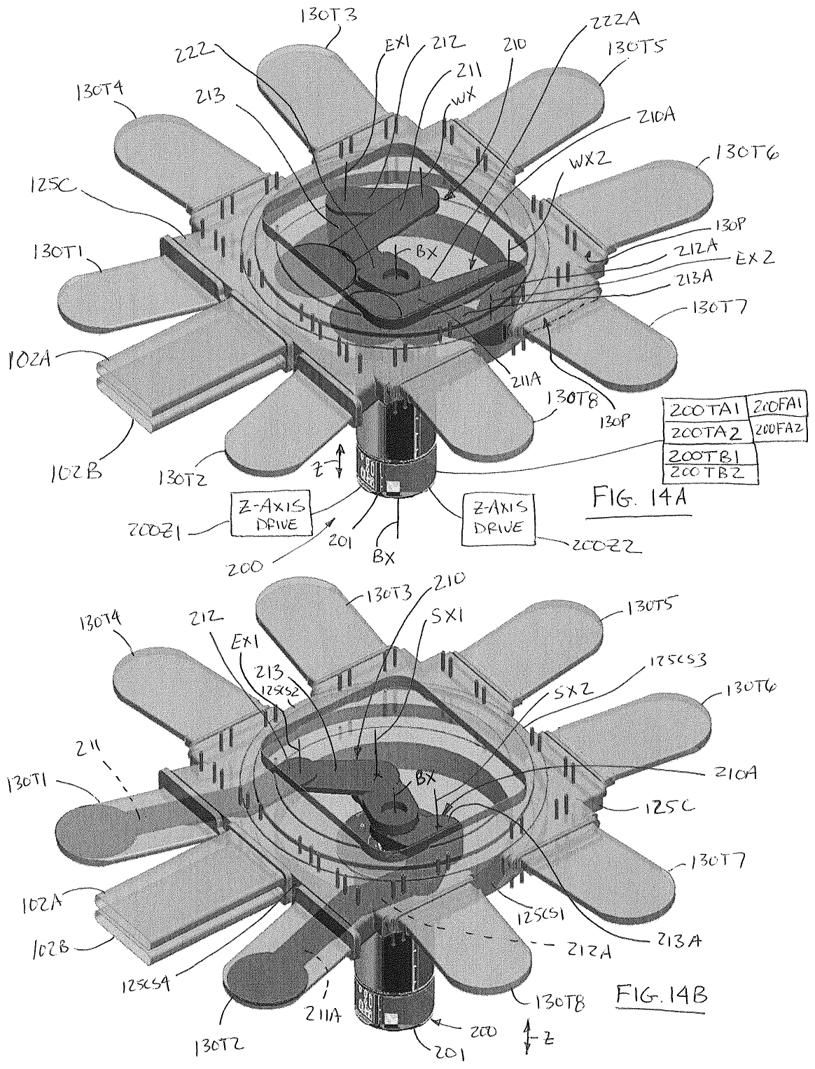

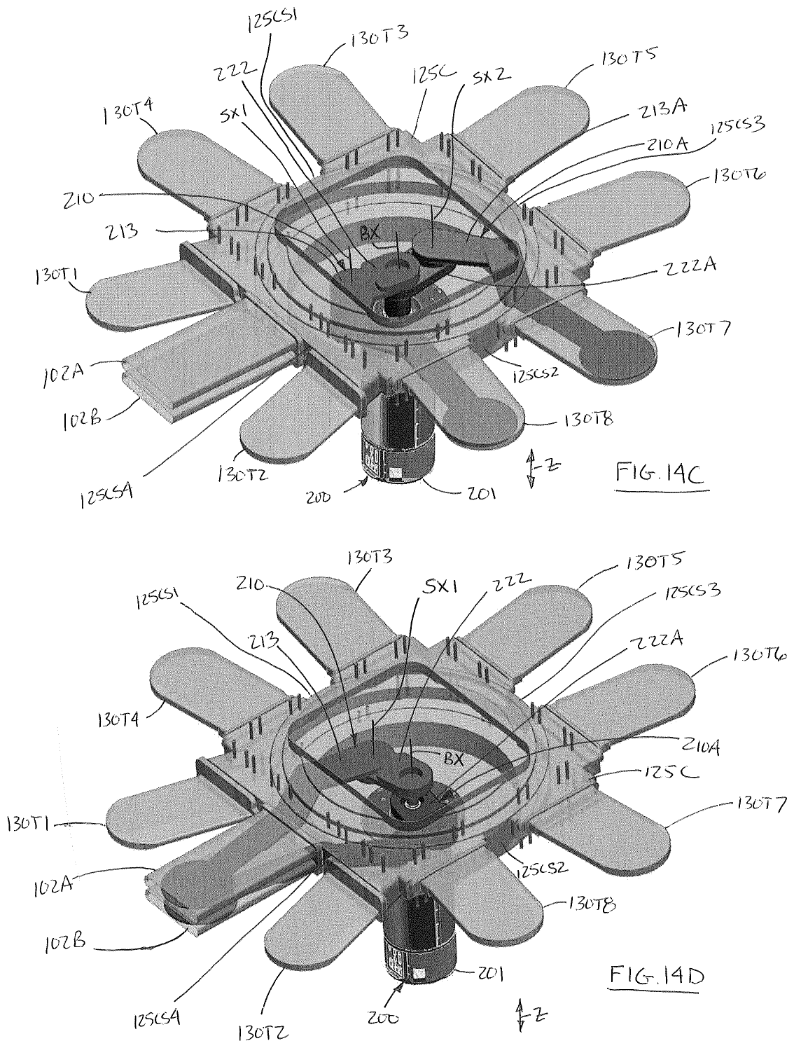

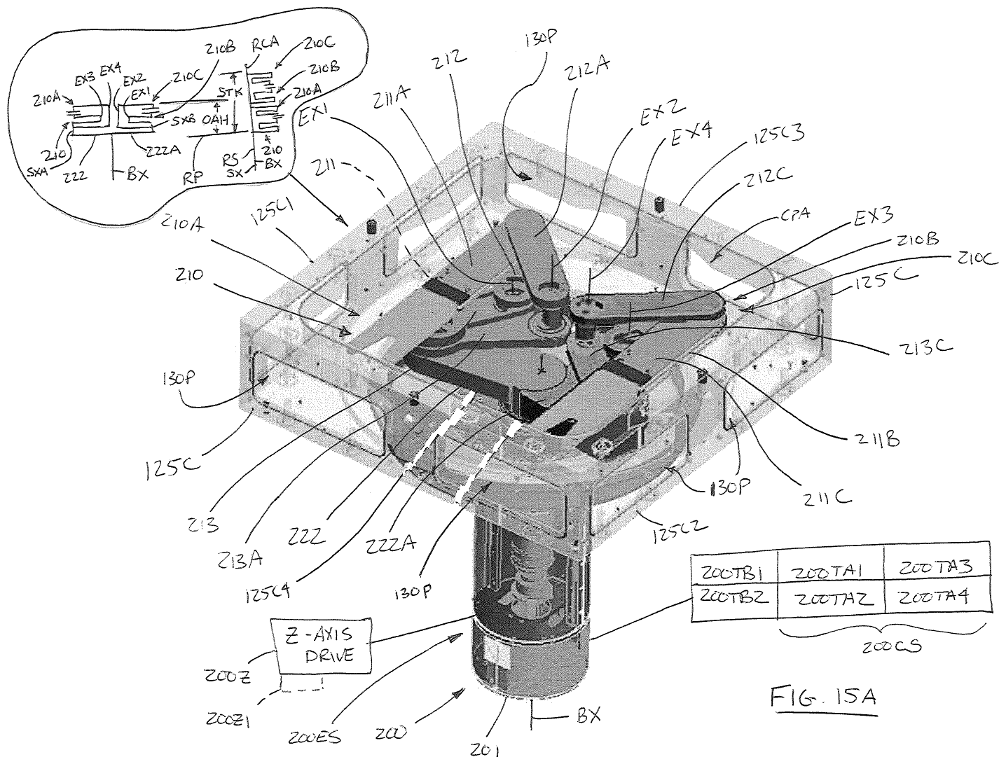

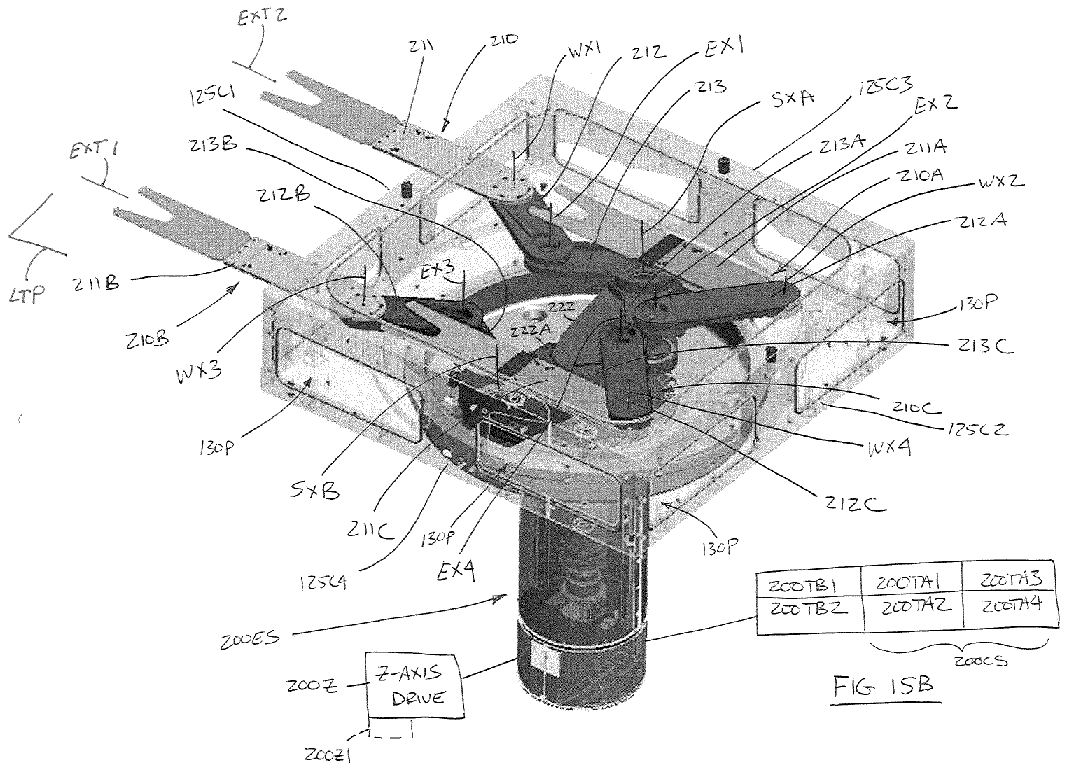

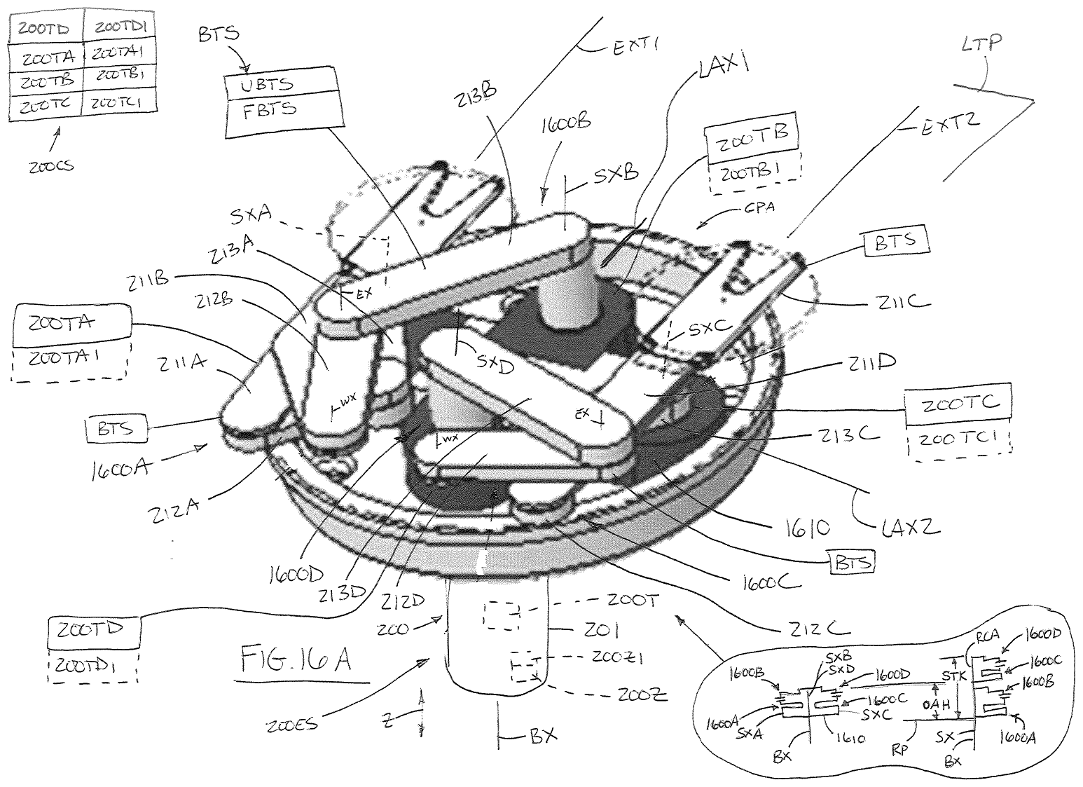

Referring to FIGS. 13A-14D, exemplary transfer arm configurations of a substrate transport apparatus is illustrated. The substrate transport apparatus includes a base or frame 201, at least two juxtaposed arms 1300A, 1300B, 210, 210A, and a distributed drive section 200. Each arm 1300A, 1300B, 210, 210A has a terminal joint (such as the shoulder axis SX (FIGS. 13A-13C) or boom axis BX (FIGS. 14A-14D)) about which the arm 1300A, 1300B, 210, 210A rotates and extends. The terminal joint being common to and joining each arm 1300A, 1300B, 210, 210A to the base or frame 201 via the common terminal joint. Each arm respectively has at least one arm link 213, 213A (see FIG. 13A-13C), 212, 213, 212A, 213A, 222, 222A (see FIGS. 14A-14D) and an end effector 211, 211A, 211B, 211AA, 211BB dependent therefrom, where each arm link is joined in series with the end effector at a distal end of the arm 1300A, 1300B, 210, 210A.

The distributed drive section 200 is operably connected to each arm 1300A, 1300B, 210, 210A, wherein the distributed drive section 200 has more than one separate motors 200TA, 200TAA, 200TWA1-200TWA4 (see, e.g., FIG. 13A), 200TA, 200TA2, 200TB1, 200TB2, 200FA1, 200FA2 (see, e.g., FIG. 14A), each defining an independent drive axis, operably connected to each arm 1300A, 1300B, 210, 210A to describe at least one degrees of freedom motion of the end effector 211, 211A, 211B, 211AA, 211BB of the respective arm 1300A, 1300B, 210, 210A commensurate to the more than one independent drive axis connected to the respective arm 1300A, 1300B, 210, 210A. The end effector 211, 211A, 211B, 211AA, 211BB, or an arm link of the at least one arm link, of each respective arm 1300A, 1300B, 210, 210A of the at least two juxtaposed arms 1300A, 1300B, 210, 210A, is dependent and directly driven from a direct drive motor, of the distributed drive section 200, disposed on the respective arm at a link joint distal to the terminal joint.

The at least one degrees of freedom motion of the end effector 211, 211A, 211B, 211AA, 211BB, or the arm link 213, 213A (see FIG. 13A-13C), 212, 213, 212A, 213A, 222, 222A (see FIGS. 14A-14D), is decoupled from the at least one degrees of freedom motion of each other end effector 211, 211A, 211B, 211AA, 211BB, or each other arm link 213, 213A (see FIG. 13A-13C), 212, 213, 212A, 213A, 222, 222A (see FIGS. 14A-14D), of other respective arms 1300A, 1300B, 210, 210A of the at least two juxtaposed arms 1300A, 1300B, 210, 210A.

A Z drive motor 200Z2 may be disposed at the link joint distal to the terminal joint of at least one arm, so as to decouple (effect differential) Z motion of the end effector of the respective arm 1300A, 1300B, 210, 210A from each other arm 1300A, 1300B, 210, 210A of the at least two juxtaposed arms 1300A, 1300B, 210, 210A. A Z drive 200Z1, 200Z2 may be provided at the terminal joint SX (see, e.g., FIG. 13A), BX (see, e.g., FIG. 14A) effecting differential Z motion between each arm 1300A, 1300B, 210, 210A of the at least two juxtaposed arms 1300A, 1300B, 210, 210A.

Each respective arm 1300A, 1300B, 210, 210A, may have two end effectors 211A, 211B, 211AA, 211BB (the arms in FIGS. 14A-14D may have two end effectors, although one is shown on each arm for exemplary purposes), and stacked drive motors 200TWA1-200TWA4 at the link joint distal to the terminal joint (see FIG. 13A, noting such stacked motors may be disposed at a link joint distal to the terminal joint in FIGS. 14A-14D) so as to independently drive each end effector 211, 211A, 211B, 211AA, 211BB of the respective arm 1300A, 1300B, 210, 210A from each other end effector 211, 211A, 211B, 211AA, 211BB of the respective arm 1300A, 1300B, 210, 210A.

Each direct drive motor, on the arm 1300A, 1300B, 210, 210A, has a sealed rotor sealed from an atmospheric environment of a stator of the direct drive motor (such as in the manner described herein).

Referring to FIGS. 13A-13F, each of the arms 1300A, 1300B is substantially similar to what is described herein with respect to FIGS. 9A-9C. The arm 1300A includes the single arm link 213, and the end effectors 211A, 211B, although any one or more of end effectors 211, 211DS, 211DE, 211DT, 211DQ may be included. The single arm link 213 is an unarticulated arm link that is coupled to and directly driven in rotation about the shoulder axis SX by the drive motor 200TA (which is substantially similar to drive motor 500). The coupling between the single arm link 213 and the drive motor 200TA may be substantially similar to that described herein with respect to FIG. 3C. Each of the end effectors 211A, 211B is coupled to and directly driven in rotation about the wrist axis WX by a respective drive motor 200TWA1, 200TWA2. The coupling between the end effectors 211A, 211B and the respective drive motor 200TWA1, 200TWA2 is substantially similar to that described herein with respect to FIG. 3B. The drive motors 200TWA1, 200TWA2 may be radial flux motors 300, although one or more of the drive motors 200TWA1, 200TWA2 may be axial flux motors 500.

The arm 1300B includes a single arm link 213A, and end effectors 211AA, 211BA, although any one or more of end effectors 211, 211DS, 211DE, 211DT, 211DQ may be included. The single arm link 213A is an unarticulated arm link that is coupled to and directly driven in rotation about the shoulder axis SX by the drive motor 200TAA (which is substantially similar to drive motor 500). The coupling between the single arm link 213A and the drive motor 200TAA may be substantially similar to that described herein with respect to FIG. 3C. Each of the end effectors 211A, 211B is coupled to and directly driven in rotation about the wrist axis WXA by a respective drive motor 200TWA3, 200TWA4. The coupling between the end effectors 211A, 211B and the respective drive motor 200TWA3, 200TWA4 is substantially similar to that described herein with respect to FIG. 3B. The drive motors 200TWA3, 200TWA4 may be radial flux motors 300, although one or more of the drive motors 200TWA3, 200TWA4 may be axial flux motors 500.

A Z-axis drive 200Z1 may be provided and coupled to the frame 201 in any suitable manner for moving the arms 1300A, 1300B in direction Z as a unit. One or more of the arms 1300A, 1300B may include another Z-axis drive 200Z2 located at the wrist axis WX, WXA (see FIG. 13A) or located at the shoulder axis SX (see FIG. 13D). The other Z-axis drive 200Z2 may operate in concert (e.g., in a coordinated manner) with or independent of the Z-axis drive 200Z1 to effect pick/place operations where the end effectors 211A, 211B of arm 1300A and/or the end effectors 211AA, 211BB of the arm 1300B simultaneously pick or place substrates S1-S4 (e.g., the other Z-axis drive 200Z2 may compensate for any discrepancy between a Z direction distance between stacked substrate holding locations and a Z direction distance between the stacked end effectors 211A, 211B and 211AA, 211BB.

The arms 1300A, 1300B are coupled to the frame 201 about the shoulder axis SX in an opposing configuration (see FIG. 13C) so that the arms 1300A, 1300B may be extended simultaneously (or one at a time) into two side-by-side process modules 130T1, 130T2 as illustrated in FIG. 13B. Extension of each arm 1300A, 1300B into a respective one of the two side-by-side process modules 130T1, 130T2 may occur the manner described above with respect to FIGS. 9A-C and 10.

As illustrated in FIG. 13A, the arms 1300A, 1300B may be configured so that the end effectors 211A, 211B, 211AA, 211BB are arranged on different planes (e.g., at different elevations or Z heights) with respect to each other. As illustrated in FIG. 13D, the arms 1300A, 1300B may be arranged so that the end effectors 211A, 211AA may be placed on the same plane (at the same Z height) and so that the end effectors 211B, 211BB may be placed on the same plane. For example, with the Z-axis drives 200Z1, 200Z2 in a home (origin) position the end effectors 211A, 211B, 211AA, 211BB may be disposed at different Z heights as illustrated in the middle of FIG. 13E. To place the end effectors 211A, 211AA at the same Z height, the drive 200Z1 may move arm 1300B upwards and/or the drive 200Z2 may move the arm 1300A downwards so that the end effectors 211A, 211AA may simultaneously pick/place substrates (as illustrated in FIG. 13F-twin substrate transfer). To place the end effectors 211B, 211BB at the same Z height, the drive 200Z1 may move arm 1300B downwards and/or the drive 200Z2 may move the arm 1300A upwards so that the end effectors 211B, 211BB may simultaneously pick/place substrates. The arms 1030A, 1300B may effect a single substrate transfer with the end effectors 211A, 211B, 211C, 211D in any of the positions (relative to each other) illustrated in FIG. 13E.

The arms 1300A, 1300B may provide for one or more of: independent (for each arm 1300A, 1300B) automatic wafer centering and pitch correction; twin or single substrate exchange; left to right (or right to left) process module substrate transfer (i.e., arm 1300A may place substrates to either of process modules 130T1, 130T2 and arm 1300B may place substrates to either of process modules 130T1, 130T2); the arms 1300A, 1300B may be constructed of any suitable material so that the arms 1300A, 1300B are high temperature and corrosion resistant; no metal bands, pulleys, gears or transmission assemblies are needed in the arms 1300A-130B; a compact drive design for improved serviceability; accurate placement repeatability; and distributed controls, sensors, and machine vision for on-the-fly data.

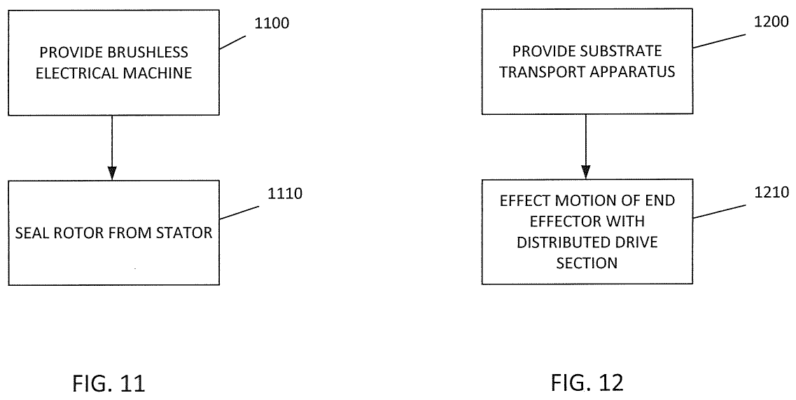

Referring to FIGS. 2A-9C, 13A-13C, and 11, an exemplary method will be described. The method includes providing the brushless electrical machine 500 described herein (FIG. 11, Block 1100). The electric machine rotor 505 is sealed from the electric machine stator 501 by the seal or isolation wall 510 (FIG. 11, Block 1110) so that the phase coil 501AC-501CC is disposed in an atmospheric volume holding an atmospheric environment and the electric machine rotor 505 is disposed in a sealed environment sealed from and different than the atmospheric volume. The electric machine rotor 505 and electric machine stator 501 are disposed in an axial gap arrangement (see FIG. 5C) with an axial gap between the electric machine rotor 505 and electric machine stator 501 disposed astride the electric machine stator 501, and the seal 510 is arranged in the axial gap so as to seal each electric machine stator 501 from each electric machine rotor 505 stimulated by the electric machine stator 501 across the seal 510.

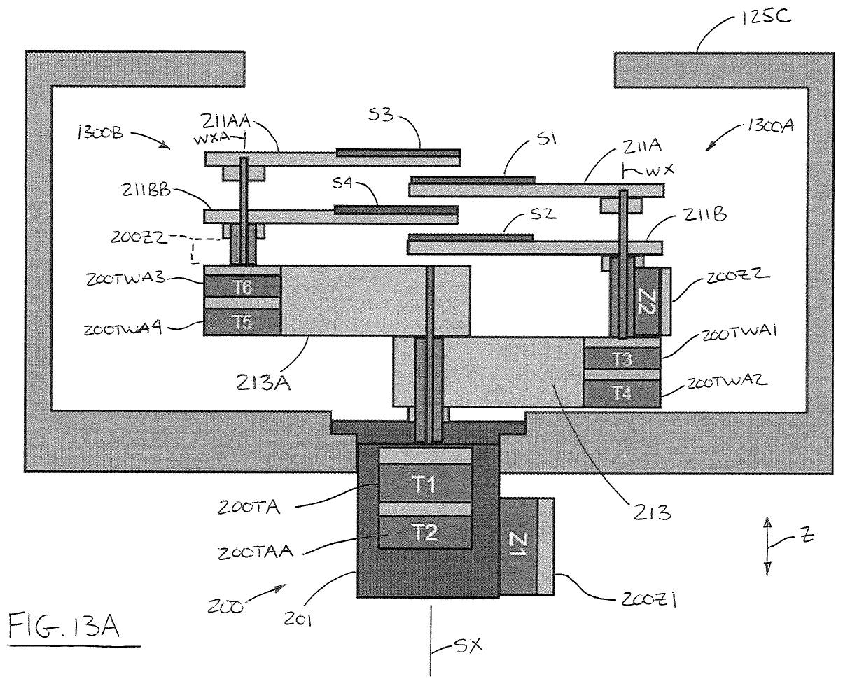

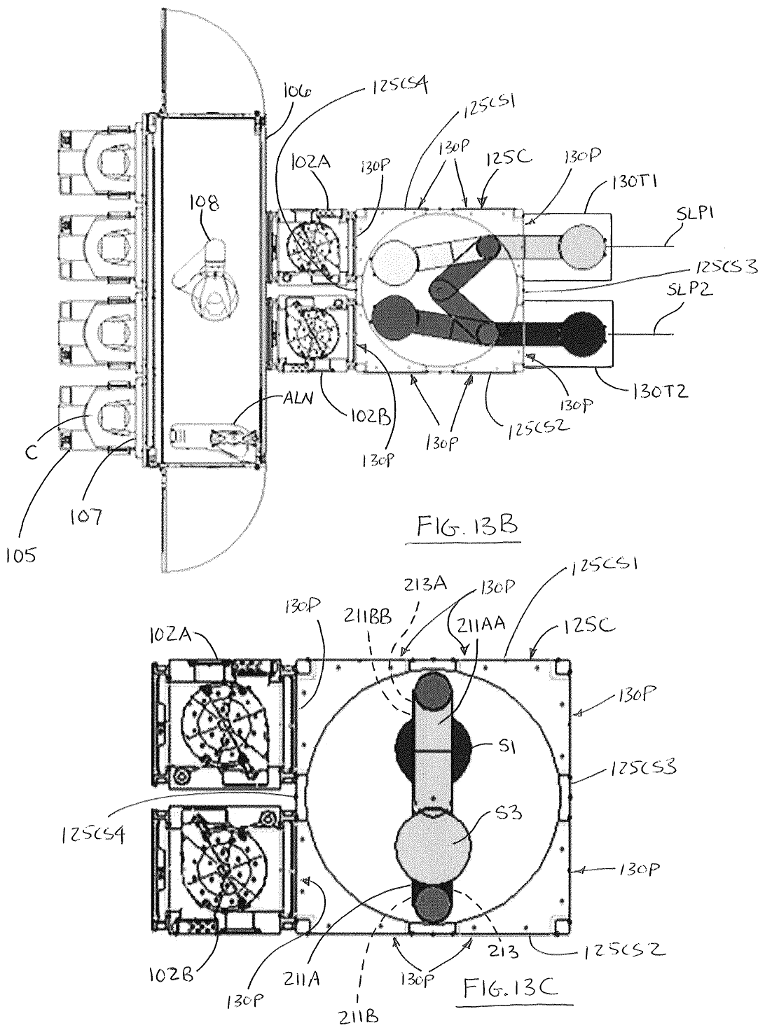

Referring to FIGS. 2A-9C, 13A-13C, and 12, an exemplary method will be described. The method includes providing substrate transport apparatus (such as any of those illustrated in FIGS. 2A-9C (FIG. 12, Block 1200). In particular, the substrate transport apparatus has at least one arm with a terminal joint SX, about which the arm rotates and extends, and having more than one arm links 212, 212L, 212R, 213 and an end effector 211, 211DE, 211DS, 211DT, 211DQ dependent therefrom, each arm link being joined in series with the end effector at a distal end of the arm. Motion of the end effector 211, 211DE, 211DS, 211DT, 211DQ is effected, with the distributed drive section 200, commensurate to the more than one degrees of freedom of the distributed drive section 200 (FIG. 12, Block 1210). As described herein, arm link 212, 212L, 212R, of the more than one arm links 213, 212, 212L, 212R, is a direct drive link dependent and directly driven from a direct drive motor 200TFA, 200TFAA, of the distributed drive section 200, disposed on the SCARA arm at a link joint (e.g., such as at the elbow axis EX, EXL, EXR) distal to the terminal joint SX. The end effector 211, 322DC, 211DE, 211DT, 211DQ, or at least another arm link 212, 212L, 212R of the more than one arm links 213, 212, is at least one of directly driven by another direct drive motor 200TWA1, 200TWA2, 200TFA, 200TFAA of the distributed drive section 200, on the arm, and slaved to the direct drive link 212, 213.

Referring to FIGS. 14A-14D, an exemplary transfer arm is illustrated that has a dual SCARA arm 210, 210A configuration. Each of the SCARA arms 210, 210A is rotatably mounted to a respective boom arm 222, 222A, where the boom arms 222, 222A rotate about a boom axis BX. The SCARA arms 210, 210A may be similar to those SCARA arms described herein where each SCARA arm 210, 210A includes an upper arm 213, 213A, a forearm 212, 212A, and an end effector 211, 211A (and/or any one or more of end effectors 211DS, 211DE, 211DT, 211DQ) serially coupled to each other and the respective boom arm 222, 222A by respective shoulder axes SX, SX1, elbow axes EX, EX1, and wrist axes WX, WX1. The transfer arm includes a frame or base 201 to which the arms 210, 210A are coupled and boom arms 222, 222A are coupled.

The transfer arm of FIGS. 14A-14D includes a distributed drive section 200, with more than one degrees of freedom defined by respective motors 200TB1, 200TB2, 200TA1, 200TA2 of the distributed drive section 200. The distributed drive section 200 is operably coupled to the arm to effect motion of the end effector 211, 211A commensurate to the more than one degrees of freedom. The motors 200TB1, 200TB2, 200TA1, 200TA2 may be substantially similar to those described herein. The boom arm 222 may be driven about boom axis BX by motor 200TB1. The boom arm 222A may be driven about boom axis BX by motor 200TB2. The upper arm 213 may be driven about shoulder axis SX1 by motor 200TA1. The upper arm 213A may be driven about shoulder axis SX2 by motor 200TA1. The forearm 212 may be drive about elbow axis EX1 by motor 200FA1. The forearm 212A may be driven about elbow axis EX2 by motor 200FA2. The end effectors 211, 211A may be slaved to the respective upper arm 213, 213, although motors 200TWA may be provided at the respective wrist axis WX1, WX2 for driving rotation of the end effectors 211, 211A about the respective wrist axis WX1, WX2.

The arms 210, 210A are configured for independent Z direction travel. For example, the drive section 200 includes Z-axis drive 200Z1 for moving the boom arm 222 and the arm 210 in the Z direction independent of the boom arm 222A and arm 210A. The drive section 200 includes Z-axis drive 200Z2 for moving the boom arm 222A and the arm 210A in the Z direction independent of the boom arm 222 and arm 210. The independent Z direction movement provided by the Z-axis drives 200Z1, 200Z2 may effect transfer of substrates to stacked substrate holding locations, such as stacked load locks 102A, 102B.

The independent rotation of the boom arms 222, 222A may provide for alignment of an extension axis of each of the arms 210, 210A to effect end effector 211, 211A extension into substrate holding stations, such as the stacked load locks 102A, 120B) that are disposed radially in-line with the boom axis BX (see FIG. 14D). For placement into the stacked substrate holding stations, the boom arm 222 is moved upwards to align the arm 210 extension with load lock 102A, while the boom 222A is moved downwards to align the arm 210A extension with the load lick 102B.

The independent rotation of the boom arms 222, 222A may provide for alignment of the arms 210, 210A extension axes into side-by-side process stations 130T1-130T8. In FIGS. 14A-14D, the transfer chamber 125C is illustrated as having at least two side-by-side substrate holding stations on each side of the transfer chamber 125C. The boom arms 222, 222A may be rotated to align the arm 210, 210A extension axes with a respective one of the side-by-side process stations 130T1-130T8 on a respective side of the transfer chamber 125C (see FIGS. 14B-14D). The process stations 130T1-130T8 are illustrated as having an axis that is angled with respect to the respective transfer chamber 125C side to which the process stations 130T1-130T8 are coupled, where the angle of the process station coincides with the axis of extension of the respective arm 210, 210A; although where each arm link 213, 212, 211, 213A, 212A, 211A is independently driven in rotation, the arms 210, 210A may extend non-radially into process stations that have an axis that is substantially orthogonal to the respective transfer chamber side.

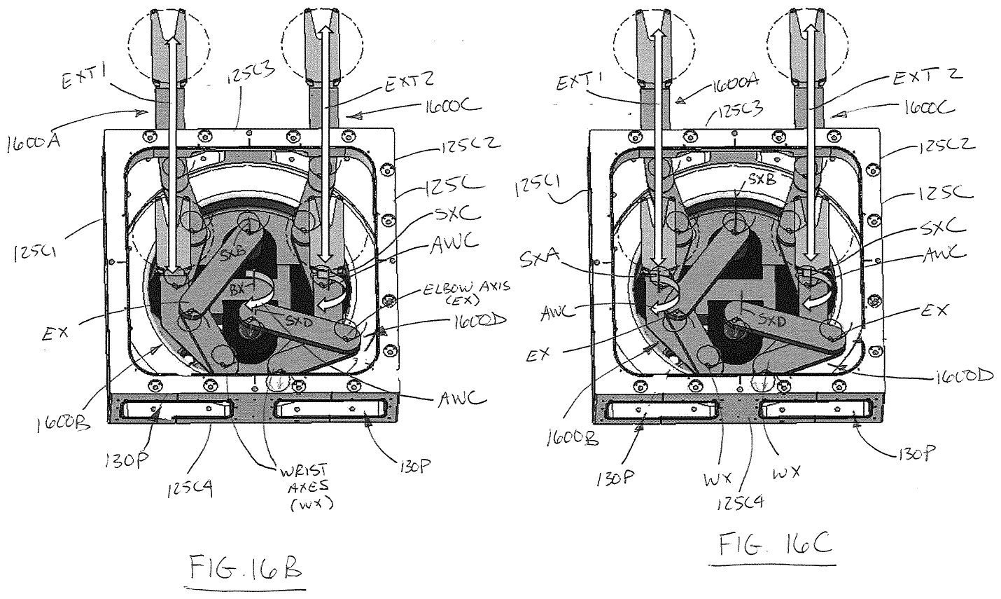

Referring to FIGS. 15A-18, exemplary transfer arms of a substrate transport apparatus are illustrated. The substrate transport apparatus includes a base or frame 201, a common rotary joint BX, at least two juxtaposed arms 210, 210A, 210B, 210C, 1600A-1600D, and a distributed drive section 200. Each arm 210, 210A, 210B, 210C, 1600A-1600D has a respective terminal joint SXA-SXD about which each respective arm 210, 210A, 210B, 210C, 1600A-1600D rotates and extends. The terminal joint SXA-SXD of each respective arm 210, 210A, 210B, 210C, 1600A-1600D joins the respective arm 210, 210A, 210B, 210C, 1600A-1600D to the base 201 via the common rotary joint BX. Each arm respectively has more than one arm link (see FIGS. 15A-18, as described herein) and an end effector 211, 211A, 211B, 211C, 211D dependent therefrom, where each arm link is joined in series with the end effector 211, 211A, 211B, 211C, 211D at a distal end of the arm 210, 210A, 210B, 210C, 1600A-1600D.

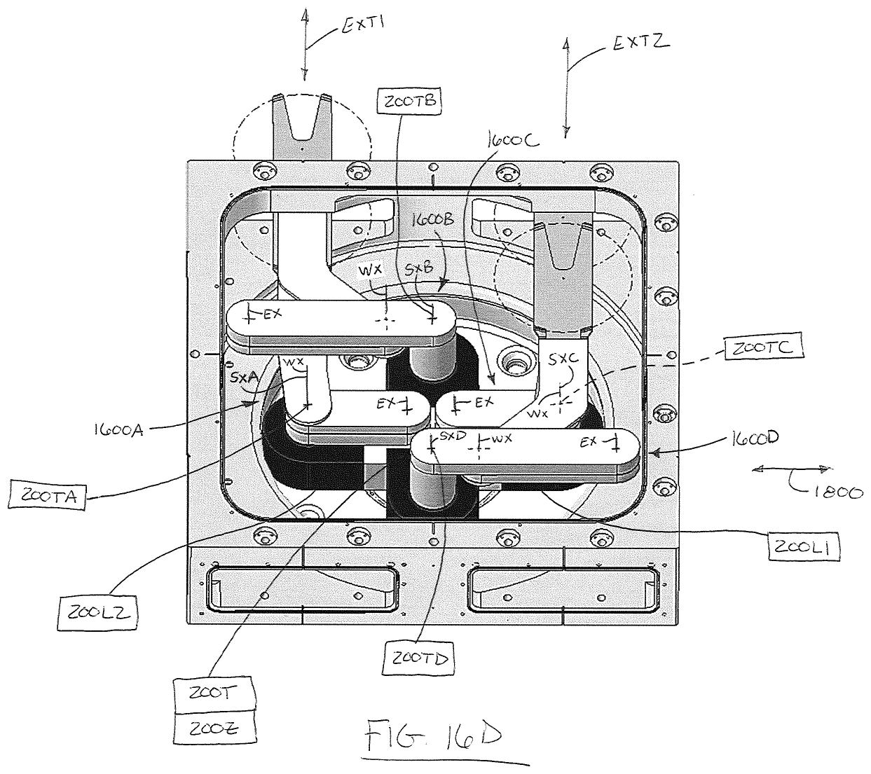

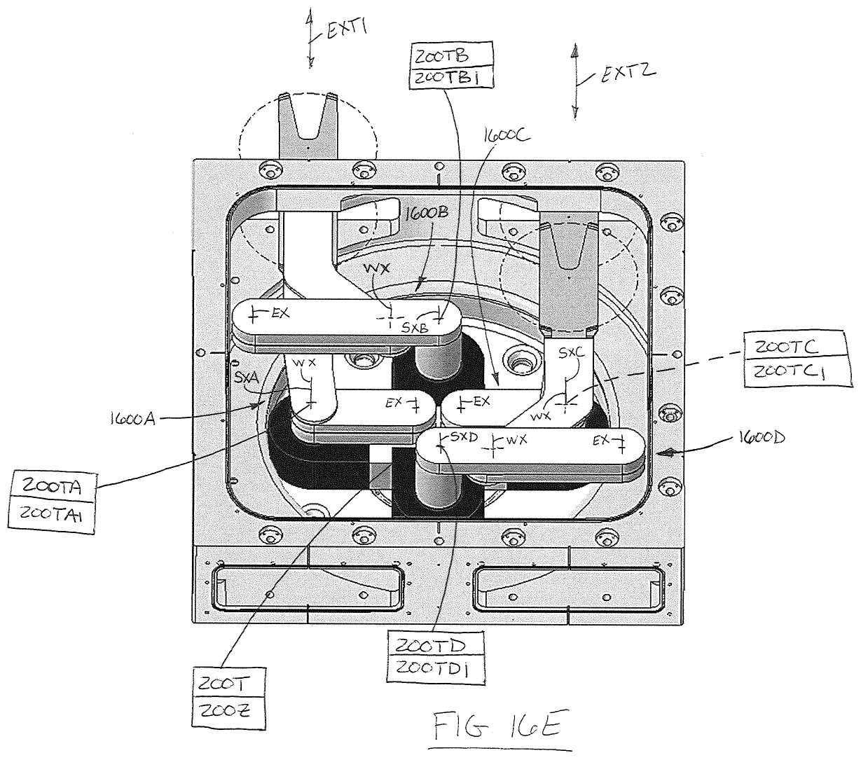

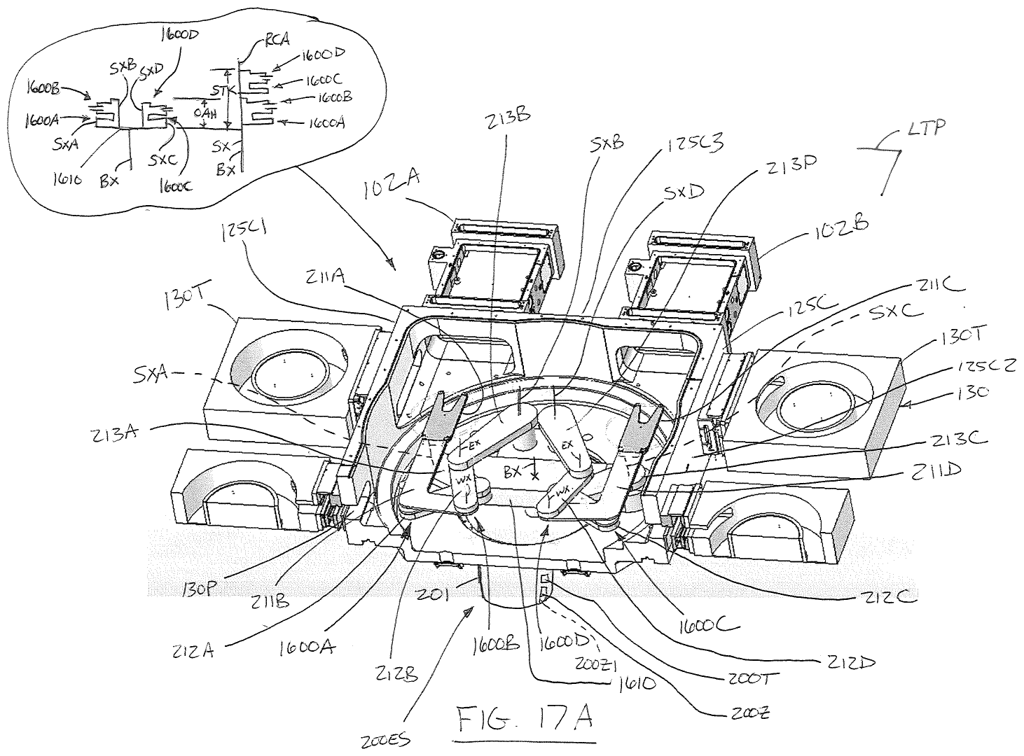

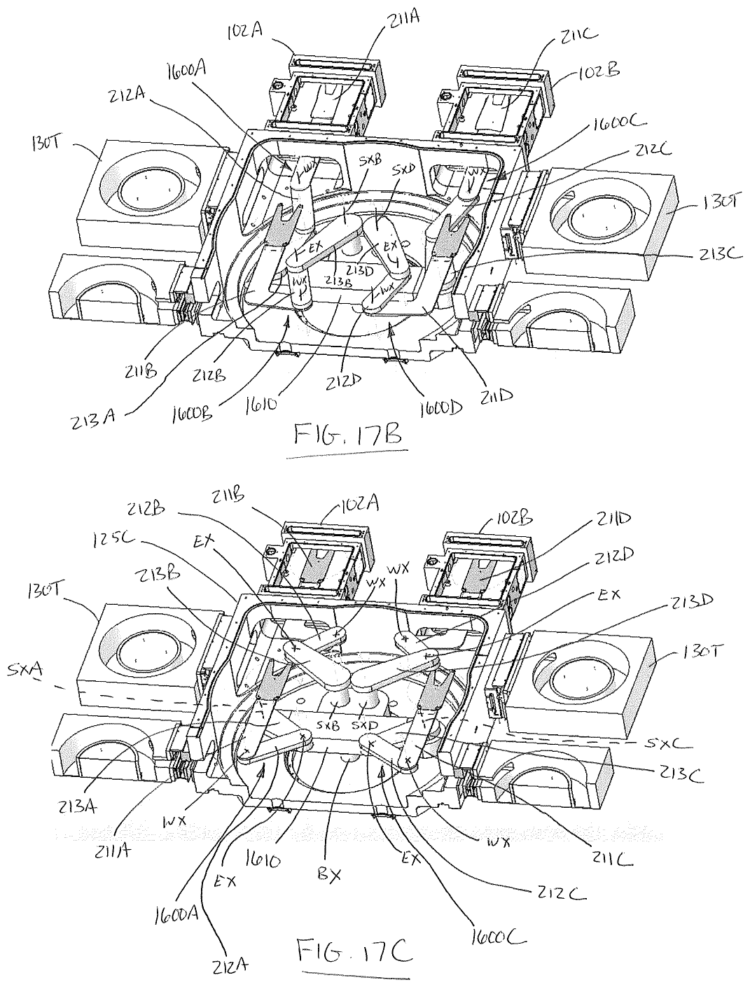

The distributed drive section 200 is operably connected to each arm 210, 210A, 210B, 210C, 1600A-1600D, wherein the distributed drive section 200 has more than one separate motors 200TA1-200TA4, 200TB1, 200TB2 (as described with respect to, e.g., FIGS. 15A and 15B), 200T, 200TA-200TD, 200TA1-200TD1 (as described with respect to, e.g., FIGS. 16A-18) each defining an independent drive axis, operably connected to each arm 210, 210A, 210B, 210C, 1600A-1600D to describe at least one degrees of freedom motion of the end effector 211, 211A, 211B, 211C, 211D of the respective arm 210, 210A, 210B, 210C, 1600A-1600D commensurate to the more than one independent drive axis connected to the respective arm 210, 210A, 210B, 210C, 1600A-1600D. An arm link of the more than one arm link, of each respective arm 210, 210A, 210B, 210C, 1600A-1600D of the at least two arms 210, 210A, 210B, 210C, 1600A-1600D, is a direct drive link dependent and directly driven from a direct drive motor, of the distributed drive section 200, disposed on the respective arm at a link joint distal to the terminal joint SXA-SXD.

The end effector 211, 211A, 211B, 211C, 211D, or at least another arm link of the more than one arm links of a respective arm 210, 210A, 210B, 210C, 1600A-1600D, is at least one of: directly driven by another direct drive motor of the distributed drive section 200, on the arm 210, 210A, 210B, 210C, 1600A-1600D; and slaved to the direct drive link.

The at least two juxtaposed arms 210, 210A, 210B, 210C, 1600A-1600D includes stacked arms, where stacks of arms are juxtaposed relative to each other (see, e.g., FIGS. 15A-18). At least one of the at least two juxtaposed arms has equal length arm links (see, e.g., FIGS. 15A-18). At least one of the at least two juxtaposed arms has unequal length arm links (see, e.g., FIGS. 15A-18).

Referring to FIGS. 15A and 15B, an exemplary transfer arm is illustrated that has a quad SCARA arm 210, 210A, 210B, 210C configuration. Each of the SCARA arms 210, 210A, 210B, 210C is rotatably mounted to a respective boom arm 222, 222A, where the boom arms 222, 222A rotate about a boom axis BX. The SCARA arms 210, 210A, 210B, 210C may be similar to those SCARA arms described herein where each SCARA arm 210, 210A, 210B, 210C includes an upper arm 213, 213A, 213B, 213C, a forearm 212, 212A, 212B, 212C, and an end effector 211, 211A, 211B, 211C (and/or any one or more of end effectors 211DS, 211DE, 211DT, 211DQ) serially coupled to each other and the respective boom arm 222, 222A by respective shoulder axes SXA, SXB, elbow axes EX, EX1, and wrist axes WX, WX1. The transfer arm includes a frame or base 201 to which the arms 210, 210A are coupled and boom arms 222, 222A are coupled.

The transfer arm of FIGS. 15A and 15B includes a distributed drive section 200, with more than one degrees of freedom defined by respective motors 200TB1, 200TB2, 200TA1, 200TA2, 200TA3, 200TA4 of the distributed drive section 200. The distributed drive section 200 is operably coupled to the arm to effect motion of the end effector 211, 211A commensurate to the more than one degrees of freedom. The drive section 200 may include a Z-axis drive 200X for moving the arms 210, 210A, 210B, 210C and the boom arms 222, 222A in the Z direction as a unit. The motors 200TB1, 200TB2, 200TA1, 200TA2, 200TA3, 200TA4 may be substantially similar to those described herein. The boom arm 222 may be driven about boom axis BX by motor 200TB1. The boom arm 222A may be driven about boom axis BX by motor 200TB2. The upper arm 213 may be driven in rotation about the shoulder axis SXA by motor 200TA1. The upper arm 213A may be driven in rotation about the shoulder axis SXA by motor 200TA2. The upper arm 213B may be driven in rotation about the shoulder axis SXB by motor 200TA3. The upper arm 213C may be driven in rotation about the shoulder axis SXB by motor 200TA4. The forearms 212, 212A, 212B, 212C and end effectors 211, 211A, 211B, 211C of each respective arm 210, 210A, 210B, 210C may be slaved to the respective boom arm 222, 222A so that the respective arm 210, 210A, 210B, 210C is extended with actuation of the respective motor 200TA1, 200TA2, 200TA3, 200TA4 alone or in combination respective boom arm 222, 222B rotation about the boom axis BX, where the rotation of the respective boom arm 222, 222A is under impetus of the respective motor 200TB1, 200TB2. Extension of each of the arms 210, 210A, 210B, 210C with one motor (i.e., a respective one of the motors 200TA1, 200TA2, 200TA3, 200TA4) alone or in combination with the respective boom arm 222, 222A motor 200TB1, 200TB2 may provide for a compact arm link height (e.g., at least of the upper arms and forearms) that may reduce the Z direction chamber height and increase throughput (e.g., pump and vent times are decreased due to smaller internal volume of the transfer chamber 125C). The compact arm link height (e.g., at least of the upper arms and forearms) may reduce the mass moment of inertia of the arms providing for increased arm speeds which may decreasing pick/place cycle times. The compact Z height may be effected, at least in part, because the drives (such as the direct drive motors located at one or more of the arm joints) may not vertically overlap with each other, but rather vertically coincide with each other (e.g., are arranged to the sides of each other) instead of being stacked one over the other.

As can be seen in FIGS. 15A and 15B, the arms 210A, 210C are configured as pass-through arms. For example, a z direction distance between the upper arm 213A and forearm 212A of arm 210A and the length of each of the upper arm 213A and forearm 212A are such that the elbow axis EX1 of the arm 210 passes between the upper arm 213A and forearm 212A to the inside (with respect to the shoulder axis SXA) of the elbow axis EX2 of the arm 210A in what may be referred to as an offset elbow arrangement. Similarly, a z direction distance between the upper arm 213C and forearm 212C of arm 210C and the length of each of the upper arm 213C and forearm 212C are such that the elbow axis EX3 of the arm 210B passes between the upper arm 213C and forearm 212C to the inside (with respect to the shoulder axis SXB) of the elbow axis EX4 of the arm 210C in what may be referred to as an offset elbow arrangement. These offset elbow arrangements may provide the transfer arm of FIGS. 15A and 15B with a minimized height of the transfer arm, so as to reduce the internal volume of the transfer chamber 125C.

Referring to FIGS. 16A-16E, an exemplary transfer arm configuration is illustrated. The transfer arm includes a base 201 to which the arm is coupled. The transfer arm includes a distributed drive section 200, and a base arm link 1610 coupled to the base 201 for rotation about the base arm axis BX under impetus of drive motor 200T of the distributed drive section 200. Four arms 1600A, 1600B, 1600C, 1600D are coupled to the base arm link 1610 for rotation about a respective shoulder axis SXA, SXB, SXC, SXD. The base arm link 1610 may include an interior that is isolated from the environment in which the arm operates. Each arm 1600A, 1600B, 1600C, 1600D includes an upper arm 213A, 213B, 213C, 213D, a forearm 212A, 212B, 212C, 212D, and an end effector 211A, 211B, 211C, 211D, which may be of unequal lengths. The shoulder axes SXA, SXB, SXC, SXD are arranged in a substantial crossed configuration (e.g., so that the shoulder axes SXA and SXC are arranged along a line/axis LAX2 that is substantially perpendicular to the axes of extension/retraction EXT1, EXT2 of the arms 1600A, 1600B, 1600C, 1600D and the shoulder axes SXB, SXD are arranged along a line/axis LAX1 that is substantially parallel to the axes of extension/retraction EXT1, EXT2 of the arms 1600A, 1600B, 1600C, 1600D). The drive motor 200T rotates the base arm link 1610 and the four arms 1600A, 1600B, 1600C, 1600D as a unit about the base arm axis BX. The distributed drive section 200 may include a Z-axis drive 200Z for moving the arms 1600A, 1600B, 1600C, 1600D and the base arm 1610 in the Z direction as a unit.

The distributed drive section 200 may include at least one drive motor for each arm 1600A, 1600B, 1600C, 1600D disposed in the base arm link 1610 at a respective shoulder axis SXA, SXB, SXC, SXD. For example, where each arm 1600A, 1600B, 1600C, 1600D has a slaved configuration, a single respective drive motor 200TA, 200TB, 200TC, 200TD may extend/retract each respective arm 1600A, 1600B, 1600C, 1600D (see also FIG. 16D). Where the upper arm 213A, 213B, 213C, 213D and forearm 212A, 212B, 212C, 212D of each arm are independently rotated and the end effector 211A, 211B, 211C, 211D is slaved to the upper arm, each arm 1600A, 1600B, 1600C, 1600D may be provided with two coaxial drive motors 200TA, 200TA1, 200TB, 200TB1, 200TC, 200TC1, 200TD, 200TD1 so as to rotate each arm 1600A, 1600B, 1600C, 1600D as unit about the respective shoulder axis SXA, SXB, SXC, SXD and extend/retract the arm 1600A, 1600B, 1600C, 1600D (see also FIG. 16E). One arm 1600B, 1600D on axis LAX1 may have a slaved configuration (i.e., the one drive motor configuration) and the other arm 1600B, 1600D may have the slaved end effector configuration (i.e., two drive motor configuration). One arm 1600A, 1600C on axis LAX2 may have a slaved configuration (i.e., the single drive motor configuration) and the other arm 1600A, 1600C may have the slaved end effector configuration (i.e., two drive motor configuration).

Providing at least one arm 1600A, 1600B, 1600C, 1600D on each axis LAX1, LAX2 with two drive motors may provide for automatic wafer centering AWC where the base arm 1610 drive motor 200T is employed to center a substrate held by the arm with the single drive motor and the two drive motors 200TA, 200TA1, 200TB, 200TB1, 200TC, 200TC1, 200TD, 200TD1 of the other arm are employed to center the substrate held by the other arm (see FIG. 16B). Where each arm 1600A, 1600B, 1600C, 1600D includes two drive motors 200TA, 200TA1, 200 TB, 200TB1, 200TC, 200TC1, 200TD, 200TD1 the respective two drive motors may be employed to effect automatic wafer centering AWC for the respective arm without employing the base arm 1610 drive motor 200T (see FIG. 16C). Where the arms 1600A, 1600C along the axis LAX2 include a single drive motor, the base arm 1610 may include at least one linear drive motor 200L1, 200L2 (see FIGS. 16D and 18) for moving the at least one of the shoulder axes SXA, SXC (or at least one of shoulder axis pairs SXA, SXB and SXC, SXD, i.e., shoulder axes SXA, SXB may move as a unit in direction 1800 by motor 200L2 and shoulder axes SXC, SXD may move as a unit in direction 1800 by motor 200L1) in direction 1800 along axis LAX2 to effect automatic wafer centering AWC. While FIGS. 16B and 16C are illustrated with respect automatic wafer centering of arms 1600A, 1600C with shoulder axes disposed along axis LAX2, the automatic wafer centering description and FIGS. 16B and 16C apply equally to arms 1600B, 1600D with the shoulder axes disposed along axis LAX1.

With respect to FIGS. 16A-16E, where arm links, such as the upper arms 213B, 213D and the forearms 212B, 212D are unequal in length (e.g., from joint center to joint center) such as illustrated with arms 1600B, 1600D, and each arm 1600B, 1600D has two drive motors 200TB, 200TB1, 200TD, 200TD1 for extending/retracting the arm 1600B, 1600D, the two drive motors 200TB, 200TB1, 200TD, 200TD1 of each arm may be employed in combination (e.g., operated cooperatively or substantially simultaneously) to maintain movement of the respective end effector 211B, 211D along a respective radial extension path EXT1, EXT2. Where arm links, such as the upper arms 213B, 213D and the forearms 212B, 212D are unequal in length (e.g., from joint center to joint center) such as illustrated with arms 1600B, 1600D, and each arm 1600B, 1600D has a single drive motor 200TB, 200TD for extending/retracting the arm 1600B, 1600D and a motor 200L1, 200L2 for moving the respective arm 1600B, 1600D in direction 1800, the drive motors 200TB, 200TD, 200L1, 200L2 of each arm may be employed in combination (e.g., operated cooperatively or substantially simultaneously) to maintain movement of the respective end effector 211B, 211D along a respective radial extension path EXT1, EXT2. The configuration of the arms 1600A-1600D shown and described herein may also provide for installation of the arms 1600A-1600D through a top opening of the transfer chamber in which the arm operates.

Each arm 1060A, 1600B, 1600C, 1600D includes a band and pulley transmission system BTS configured to maintain substantially straight line extension/retraction of the respective arm 1600A, 1600B, 1600C, 1600D. The drive pulley ratio for the arm links (e.g., upper arm to forearm and forearm to end effector) may be 2+:1:2+. For example, where the arms 1600A-1600D are configured in a slaved configuration and are extended/retracted with a single motor (e.g., as illustrated in FIG. 16D and generically in FIG. 16A), the upper arm band and pulley transmission UBTS includes a drive ratio (shoulder pulley to elbow pulley) of about greater than two to one (a ratio of 2+:1) while the forearm band and pulley transmission FBTS includes a drive ratio (elbow pulley to wrist pulley) of about one to greater than two (a ratio of 1:2+). Where the arms 1600A-1600D are configured so that the end effector is slaved to the upper arm and are extended/retracted with two motors (e.g., as illustrated in FIG. 16E and generically in FIG. 16A), the upper arm band and pulley transmission UBTS includes a drive ratio (shoulder pulley to elbow pulley) of about greater than one to one (a ratio of 1+:1) while the forearm band and pulley transmission FBTS includes a drive ratio (elbow pulley to wrist pulley) of about one to greater than two (a ratio of 1:2+). The pulleys of the band and pulley transmission system BTS may be round pulleys without band overwrap on the pulleys. Where the arm 1600A, 1600B, 1600C, 1600D is provided with two drive motors, the two drive motors may be employed for AWC and refine the straight line movement of the respective arm.

The lengths of each arm link 213A, 212A are such that the elbow axis of arm 1600A swings inside of (without contacting) the shoulder axes SXB, SXD of arms 1600B, 1600D. The lengths of each arm link 213C, 212C are such that the elbow axis of arm 1600C swings inside of (without contacting) the shoulder axes SXB, SXD of arms 1600B, 1600D. The arms 1600A, 1600B, 1600C, 1600D are configured so that the end effectors 211A, 211B are disposed vertically adjacent one another and the end effectors 211C, 211D are disposed vertically adjacent one another to minimize Z-axis movement for effecting a fast swap of substrates.

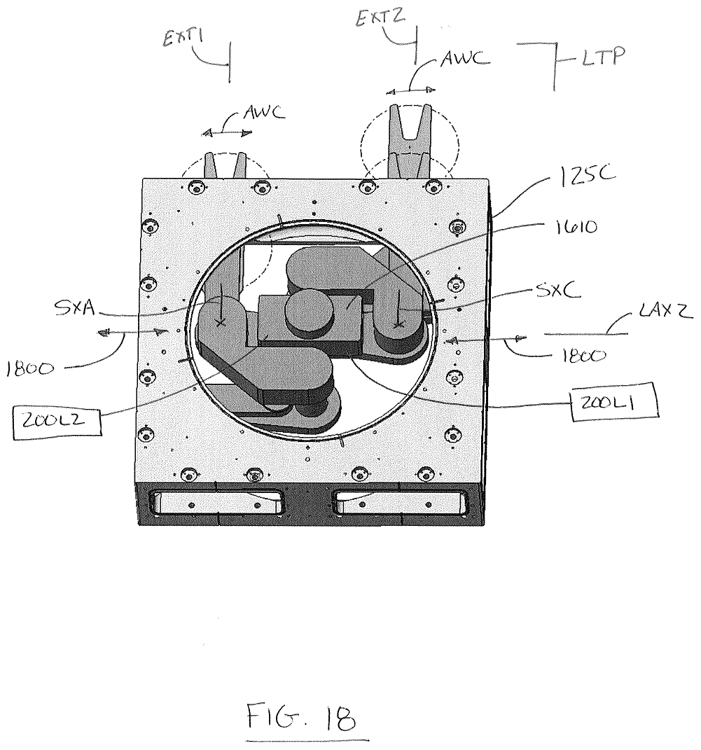

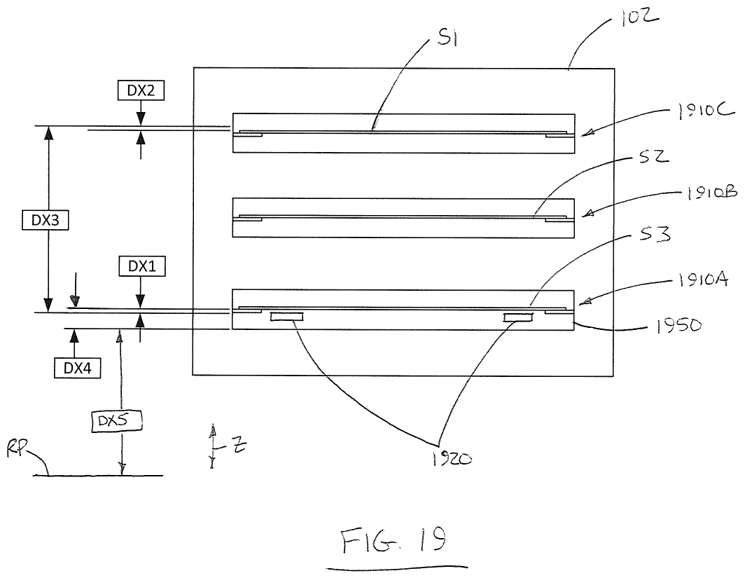

Referring to FIGS. 17A-17C an exemplary transfer arm configuration is illustrated. The transfer arm illustrated in FIG. 17A-17C is substantially similar to that described with respect to FIGS. 16A-16C but for the shoulder axes SXB, SXD of the arms 1600B, 1600D being disposed on a single side of the base arm 1610. In FIGS. 17A-17C the shoulder axes SXB, SXD are illustrated as being on what may be referred to as the “front” side of the base arm 1610 (i.e., a side of the base arm 1610 closest to the pick/place location along the axis of extension/retraction EXT1, EXT2); although the shoulder axes SXB, SXD may be disposed on what may be referred to as the “rear” side of the base arm 1610 (i.e., a side of the base arm 1610 farthest from the pick/place location along the axis of extension/retraction EXT1, EXT2). FIG. 17B illustrates arms 1600A, 1600C extended into load locks 102A, 120B (or other suitable substrate holding location) while arms 1600B, 1600D are in a retracted configuration. FIG. 17C illustrates arms 1600B, 1600D extended into load locks 102A, 120B (or other suitable substrate holding location) while arms 1600A, 1600C are in a retracted configuration.

The arm configurations of FIGS. 13A-14D and 15A-18 correspond to small or compact transport chambers 125C that have two process modules 130T1, 130T2 (or two transport openings) per side, where the size of the arms depends on the spacing of the two side-by-side process modules 130T1, 130T2 (or side-by-side transport openings). For example, the substrate processing apparatus of FIGS. 13A-18 has a substantially hexahedron shaped (or compact) substrate transport chamber 125C that is sealed to hold a chamber atmosphere. The transport chamber 125C has two linear sides 125CS1, 125CS2 of the hexahedron extending in a lateral direction, and at least one end wall 125CS3, 125CS4 of the hexahedron substantially orthogonal to the linear sides 125CS1, 125CS2. The at least one end wall 125CS3, 125CS4 has two end substrate transport openings 130P, where each opening 130P of the end and side substrate transport openings 130P being arranged for transferring a substrate there through in and out of the substrate transport chamber 125C. At least one of the linear sides 125CS1, 125CS2 has two side substrate transport openings 130P arrayed (e.g., proximate to each other) on a common level in the lateral direction. Each of the substrate transport openings 130P coupling to a respective processing module (such as process modules 130), and communicate with the substrate transport chamber 125C (and describe the compact size of the transport chamber 125C).

As illustrated in FIGS. 15A-18, dual pairs of SCARA arms are connected to the frame or base 201 and are disposed within the sealed chamber of the transport chamber 125C. Each SCARA arm is a multi-link arm having an independent drive axis for extending and retracting the respective arm so that a first SCARA arm has a first independent drive axis, a second SCARA arm has a second independent drive axis, a third SCARA arm has a third independent drive axis, and a fourth SCARA arm has fourth independent drive axis, each of the first, second, third and fourth drive axis being different than each other. An outside drive section 200ES (of the distributed drive section 200) is located outside the sealed chamber of the transport chamber 125C and is connected to the dual pairs of SCARA arms for moving the dual pairs of SCARA arms about a common axis BX. An inside drive section 200CS is located inside the sealed chamber of the transport chamber 125C and includes a sealed housing configured to hold a sealed atmosphere different than the chamber atmosphere (e.g., such as in the manner described herein).

The sealed housing (similar to that described above with respect to FIGS. 3A-8) has different sealed motors 200TA1, 200TA2, 200TA3, 200TA4, 200TA, 200TB, 200TC, 200TA, 200TB1, 200TC1 distributed in the sealed chamber, including: a first sealed rotary motor for a first drive axis that describes the first independent drive axis of at least the first SCARA arm, a second sealed rotary motor, sealed apart from the first sealed rotary motor, and providing a second drive axis that is different than the first drive axis, where the second drive axis describes the second independent drive axis of the at least second SCARA arm, a third sealed rotary motor, sealed apart from the first and second sealed rotary motors, and providing a third drive axis that is different than the first and second drive axis, the third drive axis describes the third independent drive axis of the third SCARA arm, and a fourth sealed rotary motor, sealed apart from the first, second and third sealed rotary motors, and providing a fourth drive axis that is different than each of the first, second and third drive axis, the fourth drive axis describes the fourth independent drive axis of the fourth SCARA arm. The first, second, third, and fourth sealed motors are distributed in the sealed chamber of the transport chamber 12C in close packed cluster arrangement CPA (with each sealed motor offset from each other-see the rotary joints of the arms in FIGS. 15A-18 at which the motors are located) so that an outermost span width of the close packed cluster arrangement CPA (of the sealed motors) is commensurate with an outer edge to outer edge lateral distance of the two side substrate transport openings 130P (see FIGS. 15A, 15B, 16B, 16C, and 17A-18).

The present disclosure may provide for a power bus and high-speed data communication bus (which may form a common (e.g., combined) bus or separate buses) that are distributed throughout an arm or arms of the substrate transport apparatus 104. For example, referring to FIGS. 3A, 3D, and 3E, power distributed through the power bus may be direct current power or alternating current power. A power and data communication system PDCS may be distributed through the articulated arm (inclusive of all the articulated arms described herein with respect to FIGS. 1A-19), where the power and communication data system PDCS has a (at least one) wireless power and data communication interface WPDC (see FIGS. 3D and 3E) routed through each rotary joint (e.g., the joint(s) at respective axes BSX, BEX, SX, EX, WX, and the other axes/joints rotatably coupling adjacent arm links to each other) of the housing of the at least one movable arm link. The wireless power and data communication interface WPDC, through each rotary joint, is configured as a noncontact wireless communication interface. A data communication and bus power network PDCN (e.g., a network formed by and of the power and data communication system PDCS) is resident on board the articulated arm. The data communication and bus power network PDCN is distributed throughout the articulated arm from a terminal joint (such as one or more of joints SX, BSX) through the distal joint (e.g., joint WX). The data communication and bus power network PDCN is housed in and crosses each rotary joint of the housing. The data communication and bus power network PDCN incorporates local controls (e.g., transmitters, receivers, controllers, etc. of the substrate transport apparatus described herein), and sensors (e.g., the encoders, substrate sensors, sensors of metrology kits, sensors of accessory devices, imaging/vision sensors, thermal sensors, displacement sensors, and other sensors described herein) disposed respectively on the at least one movable link and each of at least the other of the movable arm links and the end effector, coupled via a network interface (e.g., such as a respective wireless power and data communication interface WPDC described herein) so as to effect local, on board, on the fly controls of at least one of active thermal control of the end effector, kinematic motion of the substrate holding station SHS via articulation of the one or more movable arm links of the articulated arm, substrate or process metrology, imaging of at least part of the articulated arm with an on board imaging sensor, and on board health monitoring of the articulated arm.

The present disclosure may provide routing of the power and communication components to electrical components (e.g., motors, motor encoders, power docks, communication docks, accessory components, etc.) disposed outside the vacuum environment (such as the environment in which the articulated arm operates) within or coupled to the arm(s) in a manner where the power and communication components may not be subject to the vacuum environment and outgassing. The conductors (e.g., electrical and communication wires) within the arm(s) are fixed relative to the respective arm links so that the conductors do not flex relative to the articulated arm as a result of arm articulation, which may increase the useful life of the electrical conductor and cooling tubing as well as increase reliability of the substrate transport apparatus 104.

At least the data communication provided by the present disclosure may be effected without mechanical contact with, for example slip-rings of the articulated arm(s). The data communication may not be limited by the use of slip-rings and may support high bandwidth (Gigabit or greater) data rates for high speed (Gigabit or greater), synchronous data transmission effecting motion control of the arm(s) and digital signal processing of arm electronics. Electrical transmissions (some of which may be high current) may be effected within the arm through employment of slip-rings while data transmission bypasses the slip-rings. At some portions of the articulated arm, power (e.g., the electrical transmissions) may be transmitted without employment of slip rings so that power may be transferred between pressurized and unpressurized environments or between pressurized environments through the unpressurized environment. In this manner, the present disclosure may provide for placement of sensors and/or actuators within and/or on the arms and end effectors without exposing electronics and/or cabling of the sensors and/or actuators to the vacuum environment. The wireless power/data transfer between arm links and/or between arm links and end effectors provide for substantially infinite rotation of one or more joints of the articulated arm of the substrate transport apparatus 104. The wireless power/data transfer of the disclosed embodiment may provide for large/high-speed data bandwidths (e.g., about a Gigabit/see or greater) and ultra-low latency (e.g., in the nanosecond range) to effect direct driving of one or more joints of the articulated arm and/or sensing of substrates carried by the substrate transport apparatus 104.

The present disclosure may provide power and data docking (e.g., interfaces or wireless docking stations) on the arm wrist plate, on the end effector, or at any other suitable location of the arm (see FIGS. 3A and 3F). The docking stations interface with any suitable accessory devices that utilize power and/or data communication. Such accessory devices include, but are not limited to, metrology kits and wireless chargers. With the metrology kit(s) receiving power from the power dock and communicating through the data dock of the docking station, the metrology kit may receive substantially unlimited power and be provided with high speed data transmission substantially immune to external radio frequency interference (e.g., effected by short range high bandwidth data communication as described herein).

FIGS. 3D and 3E illustrate exemplary rotary joint configuration where hollow drive shafts 200M1D, 200M2D, 200M3AD, 200M3BD (see also FIG. 3A) are configured for the passage of one or more of electrical/communication cables CBL. The rotary joint configurations provide for wireless delivery of at least data communication over an air gap MAG (the term air being used herein for convenience as the gap may exist in a vacuum atmosphere as described herein with respect to the wrist axis). The rotary joint may provide for power delivery through a slip-ring 379 (such as at the shoulder and elbow joints) but the power delivery may be wireless power delivery (such as at the wrist joint and/or at one or more of the shoulder and elbow joints) similar to that of the wireless data communication over the air gap MAG. The power delivery and data communication effected by the present disclosure may provide for the integration of sensors and/or actuators/direct drive motors) into the articulated arm, as described herein, while isolating the sensors and actuators from the vacuum environment in which the articulated arm operates. Any cabling, cooling tubes, and other electronics (including at least the sensors (such as the encoders, substrate sensors, sensors of metrology kits, sensors of accessory devices, imaging/vision sensors, thermal sensors, displacement sensors, etc. described herein) and direct drive motors described herein) are embedded within the within the articulated arm structure, which may substantially eliminate contamination of the vacuum environment due to outgassing of the cabling and other electronics.

While FIG. 3D illustrates the elbow joint of the articulated arm, the shoulder joint (and the wrist joint, see FIG. 3E) may be similarly configured. Referring to FIG. 3D, a conduit 381 extends through the hollow drive shaft 200M2D and motor rotor (the motor rotor being formed by the drive shaft, or vice versa, or otherwise coupled thereto), although the conduit 381 may otherwise be formed by the hollow drive shaft 200M2D and/or motor rotor. To effect data transmission through the rotary joint, noting the conduit 381 rotates relative to the upper arm 213, a wireless transmitter 377T is fixed (i.e., stationary) to the end portion of the upper arm 213. A wireless receiver 377R (having, e.g., a disk shaped antenna or any suitably shaped antenna) is fixed to the conduit 381, so as to rotate with the conduit 381 as a unit, and is coupled to the communication cable CBL. The wireless transmitter 377T (having, e.g., a disk shaped antenna or any suitably shaped antenna) is positioned relative to the wireless receiver 377R so as to transmit data therebetween. While a transmitter and receiver 377T, 377R are illustrated, the positions of the transmitter and receiver may be reversed, there may be two transceivers (to provide two way data communication), or there may be two sets of transmitters and receivers (to provide two way data communication). The transmitter and receiver 377T, 377R may be configured for optical communication, radio frequency (e.g., WiFi, near field communication, ultra-wide band, millimeter wave, etc.) communication, inductive communication, or other short range wireless communication protocols such as those described herein (e.g., Bluetooth®, infrared, Zigbee®, etc.) that operate over very short distances such as about 20 mm or less than about 20 mm (the communication distances may be more than about 20 mm). The short-range communication effects secure data transmissions and immunity to radio frequency noise within the semiconductor manufacturing FAB or factory. A minimized air gap MAG is provided between transmitting and receiving portions of the transmitter and receiver 377T, 377R. The minimized air gap is sized to be about the smallest gap possible that provides for rotation of the receiver 377R relative to the transmitter 377T without contact therebetween.

Still referring to FIG. 3D electrical power may be transferred through the rotary joint through a slip-ring 379, although electrical power may be wirelessly transmitted over the air gap MAG as described below. For example purposes only, with respect to slip ring 379, a brush block 379B of the slip-ring 379 is fixedly (stationary) coupled to the end portion of the upper arm 213, while the rotating ring 379R of the slip-ring is fixed (e.g., relative to the conduit 381) to the conduit 381 so as to rotate as a unit with the conduit 381. Electrical power is fed to the brush block 379B with any suitable power cable CBL and from the rotating ring into the forearm 212 with any suitable power cable CBL that is routed adjacent the conduit 381 and within the drive shaft 200M2D. The power fed through the articulated arm via the cables and slip rings (and in some instances through wireless couplings) provides power to the motors 200M1-200M3B, the encoders 388, 389, 389A, and/or any other suitable electronics integrated with the articulated arm.

Referring also to FIGS. 3D and 3E, both power transmission and data communication through the rotary joint may be wireless. For exemplary purposes only, wireless power transmission and data communication will be described with respect to the wrist joint (see FIG. 3E), although the elbow joint (see FIG. 3D) and the shoulder joint may be substantially similar. For example, power and data communication is provided to the wrist, via cables, for effecting operation of at least the drive motors 200M3A, 200M3B and the respective encoders, where the cables extend through the arm to the wrist. A short-range proximity wireless communication network may be provided for transferring power and data to and/or from the end effector 211A, 211B. The short-range proximity wireless communication network includes a data and power transmitter 341T, 342T disposed within the wrist and a data and power receiver 341R, 342R disposed in the end effector 211A, 211B (power receiver 342R is illustrated at the base of the drive shaft 200M3BD for end effector 211A). The short-range proximity wireless communication network may be employed for power and/or data transmission between the frame 201 and the upper arm 213 and/or between the upper arm 213 and forearm 212. The data and power transmitter 341T is disposed within the arm. The data and power transmitter 341T is coupled to a transmitter antenna 341TA disposed within the vacuum environment (see also transmitter antenna 342TA of transmitter 342T). The transmitter antenna 341TA, 342TA is constructed of any suitable vacuum compatible material (e.g., such as stainless steel) and is affixed to the arm in any suitable manner (such as with any suitable fasteners). Any suitable seals (such as O-rings) may be provided between the transmitter antenna 341TA and the arm so as to seal any feedthroughs that couple the transmitter antenna 341TA to the data and power transmitter 341T. The transmitter antenna 341TA may circumscribe the drive shaft 200M3AD of the motor 200M3A (and hence, the coupling between the drive shaft 200M3AD and the respective end effector 211B) so that as the end effector 211B rotates, wireless communication between the power and data transmitter 341T and the end effector 211B is substantially maintained.

A data and power receiver 341R is embedded within the end effector 211B in any suitable manner (such as during manufacture of the end effector or within a sealed atmospheric chamber within the end effector 211B). A receiver antenna 341RA is disposed within the vacuum environment (see also receiver antenna 342RA at the base of the drive shaft 200M3BD). The receiver antenna 341RA, 342RA is constructed of any suitable vacuum compatible material (e.g., such as stainless steel) and is affixed to the end effector 211B in any suitable manner (such as with any suitable fasteners). Any suitable seals (such as O-rings) may be provided between the receiver antenna 341RA and the end effector 211B so as to seal any feedthroughs that couple the receiver antenna 341RA to the data and power receiver 341R. The receiver antenna 341RA may circumscribe the drive shaft 200M3AD of the motor 200M3A (and hence, the coupling between the drive shaft 200M3AD and the respective end effector 211B) so as to provide a pass through for drive shaft 200M3BD of motor 200M3B and so that as the end effector 211B rotates wireless communication between the power and data transmitter 341T and the end effector 211B is substantially maintained through wireless communication between the two ring shaped antenna 341TA, 341RA. The antenna 341TA, 341RA may have any suitable shapes. As an example, the antenna 341TA, 341RA may be constructed of a thin foil so as to be conformal to/with the surface to which they are affixed. The transmitter 341T and receiver 341R may provide two-way data communication. In a manner similar to that described herein, the antenna 341TA, 341RA are separated by the minimized gap MAG. Power and data may be transmitted to (and from) the end effector 211A in a manner substantially similar to that described with respect to end effector 2511B.

As can be seen in FIG. 3D, the rotary joints provide for substantially unlimited rotation of the forearm 212 relative to the upper arm 213. Further, because the cables CBL in the upper arm 213 at the elbow joint only interface with components that are stationary relative to the upper arm 213 (e.g., the transmitter 377T, the brush block 379B of the slip-ring 379) the cables CBL do not flex or move with articulation of the forearm 212 relative to the upper arm 213, which may increase reliability and useful life of the cables CBL. Similarly, because the cables CBL in the forearm 212 at the elbow joint only interface with components that are stationary relative to the forearm 212 (e.g., the receiver 377R, the rotating ring 379R of the slip-ring 379) the cables CBL do not flex or move with articulation of the forearm 212 relative to the upper arm 213, which may increase reliability and useful life of the cables CBL. Where substantially unlimited rotation of an arm joint is not required or otherwise desired, the one or more of the electrical slip ring and data transmitter/receiver may be removed such that the power and data cable(s) extend through the conduit 381 to the seal 385B (with the conduit 381 being stationarily fixed to the upper arm 213) where the cable(s) form a clock spring in the forearm 212 that winds and unwinds (in a manner similar to that of a spiral clock spring) as the forearm 212 rotates relative to the upper arm 213.

Referring to FIGS. 3A and 3F, the present disclosure may effect positioning wireless power and data transmission docks 345A-345C (also referred to as wireless docking stations) at any suitable location(s) of the articulated arm and/or end effectors 211A, 211B. These wireless docking stations may provide power and high-speed data transfer to (and/or from) any suitable accessory items carried by the articulated arm. The accessory items are configured to effect automatic maintenance and or diagnostics of the substrate processing apparatus (or any portions thereof). These accessory items include, but are not limited to, metrology kits 340A, 340B. The metrology kits 340A, 340B may include any suitable sensors 340S including, but not limited to, cameras, accelerometers, thermometers, tactile sensors (e.g., pressure sensing pads, transducers, etc.), magnetometers, gyroscopes, contaminant sensors, humidity sensors, gas sensors, chemical sensors, pressure sensors, audio sensors, etc. The metrology kits 340A, 340B may include a processor 340C. The metrology kits 340A, 340B may include a power supply 340P (e.g., battery, capacitor, etc.). The metrology kit 340A may be any suitable instrumented substrate that has a shape and size similar to that of a production substrate S, but configured with one or more sensors (such as those noted above) to effect metrology of the substrate processing apparatus.

Power and high-speed data transmission is provided to the processor (which may distribute the power to sensor(s) 340S and power supply 340P of the accessory item, and communicate with the sensors(s) 340S) by a mating wireless dock 340D that is configured to wirelessly mate with a respective one of the wireless docking stations 345A-345C. Substantially unlimited power and high-speed data transmission may be provided to the metrology kit 340A, 340B for powering the sensors 340S and/or charging the power supply 340P and for providing sensor feedback to the controller 110 (or any other suitable controller or operator station of the substrate processing apparatus 100A-100G).

While the wireless docking stations 345, 345A-345C are illustrated as being disposed on the end effector 211A, 211B and at the wrist joint 340B, the wireless docking station(s) may be disposed at any suitable location of the articulated arm that may present a metrology kit to a desired portion of the substrate processing apparatus. For example, wireless docking stations may be disposed at the shoulder joint, the elbow joint, the wrist joint, on the upper arm 213, on the forearm 212, and/or on the end effector 211A, 211B (or any other suitable location of the substrate transport apparatus 104). The docking stations 345, 345A-345C may have any suitable configuration (and the mating wireless dock 340D has any suitable mating configuration) for transferring power and data to and/or from the metrology kit 340A, 340B. The docking stations 345, 345A-345C communicate with the mating wireless dock 340D over any suitable short-range transmission (such as those described herein) including, but not limited to, one or more of millimeter wave (ultra wide band) transmission, capacitive transmission, and inductive transmission. The metrology kit 340A, 340B is configured so that when picked up by the substrate transport apparatus 104, the mating wireless dock 340D is aligned with a respective docking station 345, 345A-345C so as to establish a wireless power/data link between the respective docking station 345, 345A-345C and the mating wireless dock 340D.

The wireless power and data communication between the substrate transport apparatus 104 and the metrology kit 340A, 340B may effect implementation of the metrology kit 340A, 340B substantially without limitations on power and/or data bandwidth. In this respect, the metrology kits 340A, 340B may include faster, more powerful processors, increased numbers of sensors, etc., which may increase performance and functionality of the metrology kits compared to conventional battery-only powered metrology kits. The performance and functionality (e.g., substantially unlimited inspection/maintenance durations) of the metrology kits, compared to convention battery-only powered metrology kits, may be increased through employment of the high-speed data transfer (e.g., at least Gigabit Ethernet or EtherCat, etc.) provided by the present disclosure. Exemplary sensors (and/or accessory devices) 340S that may be provided include, but are not limited to, one or more of thermal sensors 1410 (for sensing a temperature of a substrate), and imaging/detection sensors 1610 (for substrate position detection and automatic substrate centering relative to the end effector when picking and placing substrates). Other sensors include arm link thermal sensors, arm link displacement sensors, and vision sensors that may be employed to monitor a temperature and thermal expansion of a respective arm link and relative positions of adjacent arm links. Accelerometers and/or inclination sensors may be placed within the articulated arm (such as adjacent the wrist axis WX) so as to determine an arm droop.

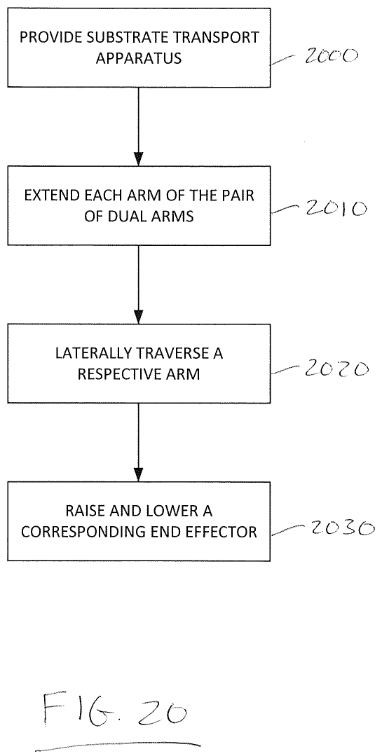

Referring to FIG. 19, the transfer arms of the robots described herein may provide for transfer of substrates to and from the substrate holding stations 1910A, 1910B, 1910C of a triple stack load lock 102 or other substrate holding location where three holding stations 1910A, 1910B, 1910C are stacked one above the other. The load lock being of and commensurate with a popular load lock configuration that has been widely adopted in the industry. As such, all of the transfer arms described herein may be oriented and configured to conform to the load lock 102 footprint and dimensions, such as those described herein with respect to the load lock 102 illustrated in FIG. 19. For exemplary purposes, the load lock 102 is illustrated as a triple stack/chamber load lock having three stationary (e.g., relative to a frame of the load lock) substrate holding stations 1910A, 1910B, 1910C. To pick or place a substrate S1-S3 from a respective substrate holding station 1910A, 1910B, 1910C a Z-direction movement distance DX1, DX2 of about 5 mm (although the movement may be more or less than about 5 mm) may be required to effect handoff of the substrate S1-S3 between supports of the substrate holding station and the end effector 1920 (a portion of which is illustrated in FIG. 19, where the end effector may be any one of those end effectors described herein). As such, to pick a substrate from the uppermost substrate holding station 1910C the end effector 1920 is moved upwards in the Z direction at least 5 mm past the top of the substrate S1 seated on the supports or 5 mm past the top of the supports of the substrate holding station 1910C. To place a substrate S3 to the lowermost substrate holding station 1910A the end effector 1920 is moved downwards in the Z direction at least 5 mm past the bottom of the substrate S3 seated on the supports or 5 mm past the top of the support of the substrate holding station 1910A. The transfer arms of the robots described herein may be provided with a Z-direction travel distance or stroke DX3 of about 175 mm (the stroke may be more or less than about 175 mm) so as to pick and place the substrates S1-S3 from the three substrate holding stations 1910A-1910C. The lowermost substrate holding station 1910A may be located a distance DX4 of about 18.5 mm (the distance may be more or less than about 18.5 mm) from a bottom of a transport opening or slot 1950 of the substrate holding station 1910A, where the bottom of the slot 1950 is disposed a distance DX5 of about 107 mm (the distance may be more or less than about 107 mm) from a reference plane RP of the substrate processing equipment. The lowermost or bottom-most transfer arm of the robots, described herein with respect to FIGS. 1A-18, is located within (does not extend below) the distance DXS when the bottom-most transfer arm is picking/placing a substrate from/to, for example, the lowermost substrate holding station 1910A of the triple stack load lock 102.

As a non-limiting example of substrate transfer to and from the triple stack load lock 102 of FIG. 19, referring to FIGS. 1A-5C, 15A-18 and 19, the substrate transport apparatus 104 includes the base 201 and the pair of dual arms (while FIGS. 15A-18 are referred to, any of the arms of the robots described herein with respect to FIGS. 1A-18 may be employed). The pair of dual arms has first dual arms 210, 210A, 1600A, 1600B and second dual arms 210C, 210D, 1600C, 1600D. The first dual arms 210, 210A, 1600A, 1600B are juxtaposed with respect to the second dual arms 210C, 210D, 1600C, 1600D. The first dual arms 210, 210A, 1600A, 1600B have a first top arm 210A, 1600B with a first top end effector, and a first bottom arm 210, 1600A with a first bottom end effector. The second dual arms 210B, 210C, 1600C, 1600D have a second top arm 210C, 1600D with a second top end effector, and a second bottom arm 210B, 1600C with a second bottom end effector.

The first top arm 210A, 1600B and the first bottom arm 210, 1600A each have a terminal joint BX about which the first top arm 210A, 1600B and first bottom arm 210, 1600A respectively rotates and extends from. The terminal joint BX being common to and joining each first top arm 210A, 1600B and first bottom arm 210, 1600A to the base 201 via the common terminal joint BX. The first top arm 210A, 1600B has at least one first top arm link and the first top end effector dependent therefrom at a distal end of the at least one first top arm link (see FIGS. 15A-18, as described herein). The first bottom arm 210 has at least one first bottom arm link and the first bottom end effector dependent therefrom at a distal end of the at least one first bottom arm link (see FIGS. 15A-18, as described herein). Each arm link of the first top arm 210A, 1600B being separate and distinct from each arm link of the first bottom arm 210, 1600A, and the first top end effector and the first bottom end effector extend overlapping each other at least in part.

The drive section 200 has at least one motor 200T, 200TA, 200TA1, 200TA2, 200TA3, 200TA4, 200TB, 200TB1, 200TB2, 200TC, 200TC1, 200TD, 200TD1, 200L1, 200L2 connected to each respective arm 210, 1600A, 210A, 1600B, of the pair of dual arms, arranged to extend each respective arm 210, 1600A, 210A, 1600B with at least one degree of freedom, independent of each other respective arm 210, 1600A, 210A, 1600B of the pair of dual arms. The drive section 200 has at least another motor 200T, 200TA, 200TA1, 200TA2, 200TA3, 200TA4, 200TB, 200TB1, 200TB2, 200TC, 200TC1, 200TD, 200TD1, 200L1, 200L2 connected to each respective arm 210, 1600A, 210A, 1600B arranged to laterally traverse the respective arm 210, 1600A, 210A, 1600B with at least another degree of freedom, so that each corresponding end effector 211, 211A, 211B, 211C, 211D of the respective arm 210, 1600A, 210A, 1600B is extended and laterally traversed along a substantially level substrate transport plane LTP relative to the corresponding end effector 211, 211A, 211B, 211C, 211D of at least another respective arm 210, 1600A, 210A, 1600B of the pair of dual arms.

The drive section 200 has another motor 200Z, that describes a motion along a direction substantially orthogonal to the substantially level substrate transport plane LTP with a predetermined stroke that raises and lowers the corresponding end effector 211, 211A-211B, 211C, 211D so that at least the first top end effector and the first bottom end effector each place and pick a substrate from each level (e.g., stacked substrate holding stations 1910A-1910C) of a triple stack load lock 102 (see FIG. 19) with the predetermined stroke of substantially 175 mm (see distance DX3). The first bottom arm and the first top arm, of the first dual arms, are arranged so that a bottom-most link of the first dual arms is located within a height from substantially 120.5 mm (the sum of distances DX4 and DX5 minus distance DX1) below the substantially level substrate transport plane LTP corresponding to a bottom-most end effector of the first dual arms.

The substrate transport apparatus 104 includes one or more of the following, individually or in any suitable combination thereof:
the second bottom arm 210B, 1600C and the second top arm 210C, 1600D, of the second dual arms 210B, 210C, 1600C, 1600D, are arranged so that a bottom-most link of the second dual arms is located within the height from substantially 120.5 mm below the substantially level substrate transport plane LTP corresponding to a bottom-most end effector of the second dual arms;
the pair of dual arms are arranged so that a bottom-most link of the pair of dual arms (see, e.g., FIGS. 15A-18) is located within the height from substantially 120.5 mm below the substantially level substrate transport plane LTP corresponding to a bottom-most end effector of the pair of dual arms;
the at least another motor 200T, 200TA, 200TA1, 200TA2, 200TA3, 200TA4, 200TB, 200TB1, 200TB2, 200TC, 200TC1, 200TD, 200TD1, 200L1, 200L2 is arranged to laterally traverse (see, e.g., FIG. 18) the respective arm 210, 210A, 1600A, 1600B, 210C, 210D, 1600C, 1600D with the at least another degree of freedom, so that each corresponding end effector 211, 211A-211D of the respective arm 210, 210A, 1600A, 1600B, 210C, 210D, 1600C, 1600D is extended and laterally traversed along the substantially level substrate transport plane LTP relative to the corresponding end effector 211, 211A-211D of each other respective arm 210, 210A, 1600A, 1600B, 210C, 210D, 1600C, 1600D of the pair of dual arms;
the at least another motor 200T, 200TA, 200TA1, 200TA2, 200TA3, 200TA4, 200TB, 200TB1, 200TB2, 200TC, 200TC1, 200TD, 200TD1, 200L1, 200L2 is disposed so as to rotate (e.g., such as about at least one or more of axes SX, SXA-SXD) the respective arm 210, 210A, 1600A, 1600B, 210C, 210D, 1600C, 1600D with the at least another degree of freedom, so that each corresponding end effector 211, 211A-211D of the respective arm 210, 210A, 1600A, 1600B, 210C, 210D, 1600C, 1600D is extended and laterally traversed along a substantially level substrate transport plane;
the at least another motor 200T, 200TA, 200TA1, 200TA2, 200TA3, 200TA4, 200TB, 200TB1, 200TB2, 200TC, 200TC1, 200TD, 200TD1, 200L1, 200L2 is disposed so as to laterally traverse (see, e.g., FIG. 18) at least one of the first top and first bottom end effector independently from each of the second top and second bottom end effector;
each of the first bottom arm 210, 1600A and first top arm 210A, 1600B are arrayed at different levels relative to a reference plane RP of the substrate transport apparatus 104, and the first bottom arm 210, 1600A and first top arm 210A, 1600B are arranged so that an overall height OAH from the reference plane RP, including the bottom-most link, to and including the uppermost link of the first dual arms 210, 210A, 1600A, 1600B is decoupled from a stack up height STK of each arm link, of the first dual arms, and the first bottom end effector and the first top end effector, each disposed in a reference stack at different elevations along a reference common axis RCA defined by at least one shoulder axis SX of the first bottom arm and the first top arm (see FIGS. 15A, 16A, 17A);
the overall height OAH defines a minimum overall height of the first dual arms 210, 210A, 1600A, 1600B that is less than the stack up height STK of the first dual arms disposed in the reference stack;
the first bottom arm 210, 1600A has a first shoulder axis corresponding to and with respect to which the first bottom arm extends, and the first top arm 210A, 1600B has another first shoulder axis (see FIGS. 16A-17C) corresponding to and with respect to which the first top arm extends, the first shoulder axis and the other first shoulder axis are separate and distinct from each other (;
the drive section 200 has a first motor 200T, 200TA, 200TA1, 200TA2, 200TA3, 200TA4, 200TB, 200TB1, 200TB2, 200TC, 200TC1, 200TD, 200TD1, 200L1, 200L2 with a first drive axis substantially coincident with the first shoulder axis, and the drive section has a second motor 200T, 200TA, 200TA1, 200TA2, 200TA3, 200TA4, 200TB, 200TB1, 200TB2, 200TC, 200TC1, 200TD, 200TD1, 200L1, 200L2 different than the first motor, the second motor has a second drive axis substantially coincident with the second shoulder axis;
the second dual arms 210C, 210D, 1600C, 1600D are arranged in a substantially mirror image arrangement of the first dual arms 210, 210A, 1600A, 1600B across an axis (e.g., a linear axis that crosses the rotational axis BX and extends between the extension axes EXT1, EXT2) dividing the transport apparatus 104 into right handed and left handed sides;
the drive section 200 is at least one of a seven motor drive section and an eight motor drive section, each motor 200T, 200TA, 200TA1, 200TA2, 200TA3, 200TA4, 200TB, 200TB1, 200TB2, 200TC, 200TC1, 200TD, 200TD1, 200L1, 200L2 of the at least one of the seven motor drive section and the eight motor drive section describing an independent degree of freedom in the level substrate transport plane;
the at least one of the seven motor drive section and the eight motor drive section has one at least one lift motor 200Z, 200Z1 different than each other motor 200T, 200TA, 200TA1, 200TA2, 200TA3, 200TA4, 200TB, 200TB1, 200TB2, 200TC, 200TC1, 200TD, 200TD1, 200L1, 200L2 of the at least one of the seven motor drive section and the eight motor drive section, that raises and lowers the level substrate transport plane and describes another independent degree of freedom different than the independent degree of freedom in the substantially level substrate transport plane LTP;
the at least one lift motor 200Z, 200Z1 has more than one different lift motors 200Z, 200Z1 arranged and operably coupled to the first dual arms 210, 210A, 1600A, 1600B and the second dual arms 210C, 210D, 1600C, 1600D so that each of the first dual arms 210, 210A, 1600A, 1600B and the second dual arms 210C, 210D, 1600C, 1600D are raised and lowered with the predetermined stroke, and so that at least one of the first dual arms 210, 210A, 1600A, 1600B and the second dual arms 210C, 210D, 1600C, 1600D is independently raised and lowered with the predetermined stroke relative to the other of the first dual arms 210, 210A, 1600A, 1600B and the second dual arms 210C, 210D, 1600C, 1600D; and

the at least one first top arm link of the first top arm 210A, 1600B comprises a first top upper arm rotatable about a respective shoulder joint and a first top forearm coupled to the first top upper arm at a respective elbow joint, where the first top forearm and the first top upper arm are unequal in length from joint center to joint center; and the at least one first bottom arm link of the first bottom arm 210, 1060A comprises a first bottom upper arm rotatable about a respective shoulder joint and a first bottom forearm coupled to the first bottom upper arm at a respective elbow joint, where the first bottom forearm and the first bottom upper arm are equal in length from joint center to joint center (see FIGS. 15A-17C).

Referring to FIGS. 1A-5C, 13A-13F, 15A-18, 19, and 20, an exemplary method will be described in accordance with the present disclosure. The method includes providing the substrate transport apparatus 104 as described herein (FIG. 20, Block 2000). For example, the substrate transport apparatus 104 includes the base 201 and the pair of dual arms (while FIGS. 13A-13F and 15A-18 are referred to, any of the dual arms robots described herein with respect to FIGS. 1A-18 may be employed). The pair of dual arms has first dual arms 210, 210A, 1600A, 1600B, 1300A and second dual arms 210C, 210D, 1600C, 1600D, 1300B. The first dual arms 210, 210A, 1600A, 1600B, 1300A are juxtaposed with respect to the second dual arms 210C, 210D, 1600C, 1600D, 1300B. The first dual arms 210, 210A, 1600A, 1600B, 1300A have a first top arm 210A, 1600B (FIGS. 15A-18), 211A (FIGS. 13A-13F) with a first top end effector, and a first bottom arm 210, 1600A (FIGS. 15A-18), 211B (FIGS. 13A-13F) with a first bottom end effector. The second dual arms 210B, 210C, 1600C, 1600D have a second top arm 210C, 1600D, 211AA with a second top end effector, and a second bottom arm 210B, 1600C, 211BB with a second bottom end effector. The first top arm 210A, 1600B, 211A and the first bottom arm 210, 1600A, 211B each have a terminal joint BX (FIGS. 15A-18), SX (FIGS. 13A-13F) about which the first top arm 210A, 1600B, 211A and first bottom arm 210, 1600A, 211B respectively rotates and extends from. The terminal joint BX, SX being common to and joining each first top arm 210A, 1600B, 211A and first bottom arm 210, 1600A, 211B to the base 201 via the common terminal joint BX, SX. The first top arm 210A, 1600B 211A has at least one first top arm link and the first top end effector dependent therefrom at a distal end of the at least one first top arm link (see FIGS. 13A-13F and 15A-18). The first bottom arm 210, 1600A, 211B has at least one first bottom arm link and the first bottom end effector dependent therefrom at a distal end of the at least one first bottom arm link (see FIGS. 13A-13F and 15A-18). The first top end effector and the first bottom end effector extend overlapping each other at least in part.

The method includes extending, with at least one motor 200T, 200TA, 200TAA, 200TA1, 200TA2, 200TA3, 200TA4, 200TB, 200TB1, 200TB2, 200TC, 200TC1, 200TD, 200TD1, 200TWA1-200TWA4, 200L1, 200L2 of the drive section 200 that is connected to each respective arm 210, 1600A, 210A, 1600B, 211A, 211B, 211AA, 211BB of the pair of dual arms, each respective arm 210, 1600A, 210A, 1600B, 211A, 211B, 211AA, 211BB with at least one degree of freedom, independent of each other respective arm 210, 1600A, 210A, 1600B, 211A, 211B, 211AA, 211BB of the pair of dual arms (FIG. 20, Block 2010). The respective arm 210, 1600A, 210A, 1600B, 211A, 211B, 211AA, 211BB is laterally traversed (FIG. 20, Block 2020), with at least another motor 200T, 200TA, 200TAA, 200TA1, 200TA2, 200TA3, 200TA4, 200TB, 200TB1, 200TB2, 200TC, 200TC1, 200TD, 200TD1, 200TWA1-200TWA4, 200L1, 200L2 of the drive section 200 that is connected to each respective arm 210, 1600A, 210A, 1600B, 211A, 211B, 211AA, 211BB, with at least another degree of freedom, so that each corresponding end effector of the respective arm 210, 1600A, 210A, 1600B, 211A, 211B, 211AA, 211BB is extended and laterally traversed along a substantially level substrate transport plane LTP relative to the corresponding end effector of at least another respective arm 210, 1600A, 210A, 1600B, 211A, 211B, 211AA, 211BB of the pair of dual arms.

The method includes raising and lowering, with another motor 200Z, 200Z1, 200Z2 of the drive section, the corresponding end effector (FIG. 20, Block 2030). The another motor 200Z, 200Z1, 200Z2 describes a motion along a direction substantially orthogonal to the substantially level substrate transport plane LTP with a predetermined stroke that raises and lowers the corresponding end effector so that at least the first top end effector and the first bottom end effector each place and pick a substrate from each level (e.g., stacked substrate holding stations 1910A-1910C) of a triple stack load lock 102 (see FIG. 19) with the predetermined stroke of substantially 175 mm. The first bottom arm and the first top arm, of the first dual arms, are arranged so that a bottom-most link of the first dual arms is located within a height from substantially 120.5 mm below the substantially level substrate transport plane LTP corresponding to a bottom-most end effector of the first dual arms.

The method includes one or more of the following, individually or in any suitable combination thereof:
each arm link of the first top arm 210A, 1600B being separate and distinct from each arm link of the first bottom arm 210, 1600A;
the second bottom arm 210B, 1600C, 211BB and the second top arm 210C, 1600D, 211AA of the second dual arms 210B, 210C, 1600C, 1600D, 1300B are arranged so that a bottom-most link of the second dual arms is located within the height from substantially 120.5 mm below the substantially level substrate transport plane LTP corresponding to a bottom-most end effector of the second dual arms;
the pair of dual arms are arranged so that a bottom-most link of the pair of dual arms (see, e.g., FIGS. 15A-18) is located within the height from substantially 120.5 mm below the substantially level substrate transport plane LTP corresponding to a bottom-most end effector of the pair of dual arms;
the at least another motor 200T, 200TA, 200TAA, 200TA1, 200TA2, 200TA3, 200TA4, 200TB, 200TB1, 200TB2, 200TC, 200TC1, 200TD, 200TD1, 200TWA1-200TWA3, 200L1, 200L2 is arranged to laterally traverse (see, e.g., FIG. 18) the respective arm 210, 210A, 1600A, 1600B, 210C, 210D, 1600C, 1600D, 211A, 211AA, 211B, 211BB with the at least another degree of freedom, so that each corresponding end effector of the respective arm 210, 210A, 1600A, 1600B, 210C, 210D, 1600C, 1600D, 211A, 211AA, 211B, 211BB is extended and laterally traversed along the substantially level substrate transport plane LTP relative to the corresponding end effector of each other respective arm 210, 210A, 1600A, 1600B, 210C, 210D, 1600C, 1600D, 211A, 211AA, 211B, 211BB of the pair of dual arms;
the at least another motor 200T, 200TA, 200TAA, 200TA1, 200TA2, 200TA3, 200TA4, 200TB, 200TB1, 200TB2, 200TC, 200TC1, 200TD, 200TD1, 200TWA1-200TWA4, 200L1, 200L2 is disposed so as to rotate (e.g., such as about at least one or more of axes SX, SXA-SXD) the respective arm 210, 210A, 1600A, 1600B, 210C, 210D, 1600C, 1600D, 211A, 211AA, 211B, 211BB with the at least another degree of freedom, so that each corresponding end effector of the respective arm 210, 210A, 1600A, 1600B, 210C, 210D, 1600C, 1600D, 211A, 211AA, 211B, 211BB is extended and laterally traversed along a substantially level substrate transport plane;
the at least another motor 200T, 200TA, 200TA1, 200TA2, 200TA3, 200TA4, 200TB, 200TB1, 200TB2, 200TC, 200TC1, 200TD, 200TD1, 200L1, 200L2 is disposed so as to laterally traverse (see, e.g., FIG. 18) at least one of the first top and first bottom end effector independently from each of the second top and second bottom end effector;
each of the first bottom arm 210, 1600A and first top arm 210A, 1600B are arrayed at different levels relative to a reference plane RP of the substrate transport apparatus 104, and the first bottom arm 210, 1600A and first top arm 210A, 1600B are arranged so that an overall height OAH from the reference plane RP, including the bottom-most link, to and including the uppermost link of the first dual arms 210, 210A, 1600A, 1600B is decoupled from a stack up height STK of each arm link, of the first dual arms, and the first bottom end effector and the first top end effector, each disposed in a reference stack at different elevations along a reference common axis RCA defined by at least one shoulder axis SX of the first bottom arm and the first top arm (see FIGS. 15A, 16A, 17A);
the overall height OAH defines a minimum overall height of the first dual arms 210, 210A, 1600A, 1600B that is less than the stack up height STK of the first dual arms disposed in the reference stack;
the first bottom arm 210, 1600A has a first shoulder axis corresponding to and with respect to which the first bottom arm extends, and the first top arm 210A, 1600B has another first shoulder axis (see FIGS. 16A-17C) corresponding to and with respect to which the first top arm extends, the first shoulder axis and the other first shoulder axis are separate and distinct from each other;
the drive section 200 has a first motor 200T, 200TA, 200TA1, 200TA2, 200TA3, 200TA4, 200TB, 200TB1, 200TB2, 200TC, 200TC1, 200TD, 200TD1, 200L1, 200L2 with a first drive axis substantially coincident with the first shoulder axis, and the drive section has a second motor 200T, 200TA, 200TA1, 200TA2, 200TA3, 200TA4, 200TB, 200TB1, 200TB2, 200TC, 200TC1, 200TD, 200TD1, 200L1, 200L2 different than the first motor, the second motor has a second drive axis substantially coincident with the second shoulder axis;
the second dual arms 210C, 210D, 1600C, 1600D are arranged in a substantially mirror image arrangement of the first dual arms 210, 210A, 1600A, 1600B across an axis (e.g., a linear axis that crosses the rotational axis BX and extends between the extension axes EXT1, EXT2) dividing the transport apparatus 104 into right handed and left handed sides;
the drive section 200 is at least one of a seven motor drive section and an eight motor drive section, each motor 200T, 200TA, 200TAA, 200TA1, 200TA2, 200TA3, 200TA4, 200TB, 200TB1, 200TB2, 200TC, 200TC1, 200TD, 200TD1, 200TWA1-200TWA4, 200L1, 200L2 of the at least one of the seven motor drive section and the eight motor drive section describing an independent degree of freedom in the level substrate transport plane;
the at least one of the seven motor drive section and the eight motor drive section has one at least one lift motor 200Z, 200Z1, 200Z2 different than each other motor 200T, 200TA, 200TAA, 200TA1, 200TA2, 200TA3, 200TA4, 200TB, 200TB1, 200TB2, 200TC, 200TC1, 200TD, 200TD1, 200TWA1-200TWA4, 200L1, 200L2 of the at least one of the seven motor drive section and the eight motor drive section, that raises and lowers the level substrate transport plane and describes another independent degree of freedom different than the independent degree of freedom in the substantially level substrate transport plane LTP;
the at least one lift motor 200Z, 200Z1, 200Z2 has more than one different lift motors 200Z, 200Z1, 200Z2 arranged and operably coupled to the first dual arms 210, 210A, 1600A, 1600B, 1300A and the second dual arms 210C, 210D, 1600C, 1600D, 1300B so that each of the first dual arms 210, 210A, 1600A, 1600B, 1300A and the second dual arms 210C, 210D, 1600C, 1600D, 1300B are raised and lowered with the predetermined stroke, and so that at least one of the first dual arms 210, 210A, 1600A, 1600B, 1300A and the second dual arms 210C, 210D, 1600C, 1600D, 1300B is independently raised and lowered with the predetermined stroke relative to the other of the first dual arms 210, 210A, 1600A, 1600B and the second dual arms 210C, 210D, 1600C, 1600D; and

the at least one first top arm link of the first top arm 210A, 1600B comprises a first top upper arm rotatable about a respective shoulder joint and a first top forearm coupled to the first top upper arm at a respective elbow joint, where the first top forearm and the first top upper arm are unequal in length from joint center to joint center; and the at least one first bottom arm link of the first bottom arm 210, 1060A comprises a first bottom upper arm rotatable about a respective shoulder joint and a first bottom forearm coupled to the first bottom upper arm at a respective elbow joint, where the first bottom forearm and the first bottom upper arm are equal in length from joint center to joint center (see FIGS. 15A-17C).

The following are provided in accordance with the present disclosure and may be employed individually, in any combination with each other, and/or in any combination with the features described above:
In accordance with the present disclosure, a brushless electrical machine includes: a frame; an electric machine stator connected to the frame and having a phase coil disposed in an atmospheric volume holding an atmospheric environment; an electric machine rotor cooperatively coupled to the electric machine stator so as to generate an output under stimulation from the electric machine stator, the electric machine rotor being disposed in a sealed environment sealed from and different than the atmospheric volume; and a seal that seals the electric machine rotor from the electric machine stator; wherein the electric machine rotor and electric machine stator are disposed in an axial gap arrangement with an axial gap between the electric machine rotor and electric machine stator disposed astride the electric machine stator, and the seal is arranged in the axial gap so as to seal each electric machine stator from each electric machine rotor stimulated by the electric machine stator across the seal.

The brushless electrical machine may include one or more of the following, individually or in any suitable combination thereof:
the axial gap arrangement is configured so that the electric machine stator stimulates the electric machine rotor across the axial gap;
the sealed environment and the atmospheric environment, in the sealed volume, are sealed respectively from each other by the seal;
the seal axially intervenes between each electric machine rotor element and each electric machine stator stimulating the electric machine rotor;
the seal has at least one seal disc portion spanning radially separating the electric machine stator from electric machine rotor throughout the axial gap;
the seal is conformal to at least one of the electric machine stator and electric machine rotor; and
the electric machine stator has stator rings that are arrayed axially, and the electric machine rotor has rotor rings that are arrayed axially.

In accordance with the present disclosure, a method includes: providing brushless electrical machine with: a frame, an electric machine stator connected to the frame and having a phase coil, and an electric machine rotor cooperatively coupled to the electric machine stator so as to generate an output under stimulation from the electric machine stator; and sealing, with a seal, the electric machine rotor from the electric machine stator so that the phase coil is disposed in an atmospheric volume holding an atmospheric environment and the electric machine rotor is disposed in a sealed environment sealed from and different than the atmospheric volume; wherein the electric machine rotor and electric machine stator are disposed in an axial gap arrangement with an axial gap between the electric machine rotor and electric machine stator disposed astride the electric machine stator, and the seal is arranged in the axial gap so as to seal each electric machine stator from each electric machine rotor stimulated by the electric machine stator across the seal.

The method may include one or more of the following, individually or in any suitable combination thereof:
the electric machine stator stimulates the electric machine rotor across the axial gap;
the sealed environment and the atmospheric environment, in the sealed volume, are sealed respectively from each other by the seal;
the seal axially intervenes between each electric machine rotor element and each electric machine stator stimulating the electric machine rotor;
the seal has at least one seal disc portion spanning radially separating the electric machine stator from electric machine rotor throughout the axial gap;
the seal is conformal to at least one of the electric machine stator and electric machine rotor; and
the electric machine stator has stator rings that are arrayed axially, and the electric machine rotor has rotor rings that are arrayed axially.

In accordance with the present disclosure, a substrate transport apparatus includes: a base; an arm with a terminal joint, about which the arm rotates and extends, and having more than one arm links and an end effector dependent therefrom, each arm link being joined in series with the end effector at a distal end of the arm; and a distributed drive section, with more than one degrees of freedom operably connected to the arm to effect motion of the end effector commensurate to the more than one degrees of freedom; wherein an arm link, of the more than one arm links, is a direct drive link dependent and directly driven from a direct drive motor, of the distributed drive section, disposed on the arm at a link joint distal to the terminal joint; and wherein the end effector, or at least another arm link of the more than one arm links, is at least one of directly driven by another direct drive motor of the distributed drive section, on the arm, and slaved to the direct drive link.

The substrate transport apparatus may include one or more of the following, individually or in any suitable combination thereof:
each direct drive motor, on the arm, has a sealed rotor sealed from an atmospheric environment of the stator of the direct drive motor;
the direct drive link has an integral motor rotor of the direct drive motor directly driving the link;
the direct drive motor, at the distal joint, and the direct drive link driven by the direct drive motor are coupled to each other with a transmission-less coupling;
the arm is selectably configurable between a hybrid configuration wherein the end effector, or at least the other arm link of the more than one arm links, is slaved to the direct drive link, and an all motor configuration wherein the end effector, or at least the other arm link of the more than one arm links is directly driven by the other direct drive motor so that in the all motor configuration, each arm link and the end effector are directly driven by a respective direct drive motor;
the base comprises an unarticulated link having an axis of rotation at a proximal end, where the terminal joint is disposed at a distal end of the unarticulated link;
the base comprises more than one serially coupled articulated link, where a proximate end of the serially coupled articulated links being disposed at an axis of rotation of the base, and the terminal joint is disposed at a distal end of the serially coupled articulated links;
more than one arm is coupled to the base at a respective terminal joint;
the arm is a SCARA arm;
the SCARA arm includes: a common upper arm link having a first and second ends where the terminal joint is disposed between the first and second ends; at least one forearm link disposed at the first end of the common upper arm link and at least another forearm joint disposed at the second end of the common upper arm link; and at least one end effector coupled to each of the at least one forearm and the at least another forearm link;
the base comprises a turret having side-by-side transfer arm supports, where each transfer arm support supports a respective arm at a respective terminal joint disposed at the transfer arm support;
each respective arm is a SCARA arm;
the end effector is directly driven by the other direct drive motor of the distributed drive section, where the end effector is at least one of: a single ended end effector; a dual end effector having side-by-side substrate holding locations in a common plane; a dual end effector having substrate holding locations disposed at opposite ends of the dual end effector in a common plane; an end effector having three substrate holding locations arranged in a common plane; and an end effector having four substrate holding locations arranged in a common plane;
the end effector is slaved to the direct drive link, where the end effector is at least one of: a single ended end effector; a dual end effector having side-by-side substrate holding locations in a common plane; and a dual end effector having substrate holding locations disposed at opposite ends of the dual end effector in a common plane; and
the distributed drive section provides the arm with a vertical stroke so as to move the end effector one or more of: a vertical distance of at least about 175 mm; a vertical distance of at least about 5 mm above an uppermost substrate held at an uppermost substrate holding station of a load lock configured to hold substrates in a stationary stack of substrates relative to a frame of the load lock; and a vertical distance of at least about 5 mm below a lowermost substrate held at a lowermost substrate holding station of the load lock configured to hold the substrates in the stationary stack of substrates relative to the frame of the load lock.

In accordance with the present disclosure, a method includes: providing a substrate transport apparatus with: a base, an arm with a terminal joint, about which the arm rotates and extends, and having more than one arm links and an end effector dependent therefrom, each arm link being joined in series with the end effector at a distal end of the arm, and a distributed drive section, with more than one degrees of freedom operably connected to the arm; effecting motion of the end effector, with the distributed drive section, commensurate to the more than one degrees of freedom; wherein an arm link, of the more than one arm links, is a direct drive link dependent and directly driven from a direct drive motor, of the distributed drive section, disposed on the arm at a link joint distal to the terminal joint; and wherein the end effector, or at least another arm link of the more than one arm links, is at least one of directly driven by another direct drive motor of the distributed drive section, on the arm, and slaved to the direct drive link.

The method may include one or more of the following, individually or in any suitable combination thereof:
each direct drive motor, on the arm, has a sealed rotor sealed from an atmospheric environment of the stator of the direct drive motor;
the direct drive link is directly driven by an integral motor rotor of the direct drive motor directly driving the link;
the direct drive motor, at the distal joint, and the direct drive link driven by the direct drive motor are coupled to each other with a transmission-less coupling;
selectably configuring the arm between a hybrid configuration wherein the end effector, or at least the other arm link of the more than one arm links, is slaved to the direct drive link, and an all motor configuration wherein the end effector, or at least the other arm link of the more than one arm links is directly driven by the other direct drive motor so that in the all motor configuration, each arm link and the end effector are directly driven by a respective direct drive motor;
the base comprises an unarticulated link having an axis of rotation at a proximal end, where the terminal joint is disposed at a distal end of the unarticulated link;
the base comprises more than one serially coupled articulated link, where a proximate end of the serially coupled articulated links being disposed at an axis of rotation of the base, and the terminal joint is disposed at a distal end of the serially coupled articulated links;
more than one arm is coupled to the base at a respective terminal joint;
the arm is a SCARA arm;
the SCARA arm includes: a common upper arm link having a first and second ends where the terminal joint is disposed between the first and second ends; at least one forearm link disposed at the first end of the common upper arm link and at least another forearm joint disposed at the second end of the common upper arm link; and at least one end effector coupled to each of the at least one forearm and the at least another forearm link;
the base comprises a turret having side-by-side transfer arm supports, where each transfer arm support supports a respective arm at a respective terminal joint disposed at the transfer arm support;
each respective arm is a SCARA arm;
the end effector is directly driven by the other direct drive motor of the distributed drive section, where the end effector is at least one of: a single ended end effector; a dual end effector having side-by-side substrate holding locations in a common plane; a dual end effector having substrate holding locations disposed at opposite ends of the dual end effector in a common plane; an end effector having three substrate holding locations arranged in a common plane; and an end effector having four substrate holding locations arranged in a common plane;
the end effector is slaved to the direct drive link, where the end effector is at least one of: a single ended end effector; a dual end effector having side-by-side substrate holding locations in a common plane; and a dual end effector having substrate holding locations disposed at opposite ends of the dual end effector in a common plane; and
the distributed drive section provides the arm with a vertical stroke so as to move the end effector one or more of: a vertical distance of at least about 175 mm; a vertical distance of at least about 5 mm above an uppermost substrate held at an uppermost substrate holding station of a load lock configured to hold substrates in a stationary stack of substrates relative to a frame of the load lock; and a vertical distance of at least about 5 mm below a lowermost substrate held at a lowermost substrate holding station of the load lock configured to hold the substrates in the stationary stack of substrates relative to the frame of the load lock.

In accordance with the present disclosure, a substrate transport apparatus includes: a base; at least two juxtaposed arms, each arm with a terminal joint about which the arm rotates and extends, the terminal joint being common to and joining each arm to the base via the common terminal joint, each arm respectively having at least one arm link and an end effector dependent therefrom, each arm link being joined in series with the end effector at a distal end of the arm; and a distributed drive section operably connected to each arm, wherein the distributed drive section has more than one separate motors, each defining an independent drive axis, operably connected to each arm to describe at least one degrees of freedom motion of the end effector of the respective arm commensurate to the more than one independent drive axis connected to the respective arm; wherein the end effector, or an arm link of the at least one arm link, of each respective arm of the at least two juxtaposed arms, is dependent and directly driven from a direct drive motor, of the distributed drive section, disposed on the respective arm at a link joint distal to the terminal joint.

The substrate transport apparatus may include one or more of the following, individually or in any suitable combination thereof:
the at least one degrees of freedom motion of the end effector, or the arm link, is decoupled from the at least one degrees of freedom motion of each other end effector, or each other arm link, of other respective arms of the at least two juxtaposed arms;
the substrate transport apparatus further comprises a Z drive motor disposed at the link joint distal to the terminal joint of at least one arm, so as to decouple Z motion of the end effector of the respective arm from each other arm of the at least two juxtaposed arms;
the substrate transport apparatus further comprises a Z drive at the terminal joint effecting differential Z motion between each arm of the at least two juxtaposed arms;
each respective arm, has two end effectors, and stacked drive motors at the link joint distal to the terminal joint so as to independently drive each end effector of the respective arm from each other end effector;
each direct drive motor, on the arm, has a sealed rotor sealed from an atmospheric environment of a stator of the direct drive motor; and
the distributed drive section provides each arm with a vertical stroke so as to move the end effector one or more of: a vertical distance of at least about 175 mm; a vertical distance of at least about 5 mm above an uppermost substrate held at an uppermost substrate holding station of a load lock configured to hold substrates in a stationary stack of substrates relative to a frame of the load lock; and a vertical distance of at least about 5 mm below a lowermost substrate held at a lowermost substrate holding station of the load lock configured to hold the substrates in the stationary stack of substrates relative to the frame of the load lock.

In accordance with the present disclosure, a substrate transport apparatus includes: a base; a common rotary joint; at least two juxtaposed arms, each arm with a respective terminal joint about which each respective arm rotates and extends, the terminal joint of each respective arm joining the respective arm to the base via the common rotary joint, each arm respectively having more than one arm link and an end effector dependent therefrom, each arm link being joined in series with the end effector at a distal end of the arm; and a distributed drive section operably connected to each arm, wherein the distributed drive section has more than one separate motors, each defining an independent drive axis, operably connected to each arm to describe at least one degrees of freedom motion of the end effector of the respective arm commensurate to the more than one independent drive axis connected to the respective arm; wherein an arm link of the more than one arm link, of each respective arm of the at least two arms, is a direct drive link dependent and directly driven from a direct drive motor, of the distributed drive section, disposed on the respective arm at a link joint distal to the terminal joint.

The substrate transport apparatus may include one or more of the following, individually or in any suitable combination thereof:
the end effector, or at least another arm link of the more than one arm links, is at least one of: directly driven by another direct drive motor of the distributed drive section, on the arm; and
slaved to the direct drive link;
the at least two juxtaposed arms includes stacked arms, where stacks of arms are juxtaposed relative to each other;
at least one of the at least two juxtaposed arms has equal length arm links;
at least one of the at least two juxtaposed arms has unequal length arm links; and
the distributed drive section provides each arm with a vertical stroke so as to move the end effector one or more of: a vertical distance of at least about 175 mm; a vertical distance of at least about 5 mm above an uppermost substrate held at an uppermost substrate holding station of a load lock configured to hold substrates in a stationary stack of substrates relative to a frame of the load lock; and a vertical distance of at least about 5 mm below a lowermost substrate held at a lowermost substrate holding station of the load lock configured to hold the substrates in the stationary stack of substrates relative to the frame of the load lock.

In accordance with the present disclosure, a substrate processing apparatus includes: a substantially hexahedron shaped substrate transport chamber that is sealed to hold a chamber atmosphere, the chamber having two linear sides of the hexahedron extending in a lateral direction, and at least one end wall of the hexahedron substantially orthogonal to the linear sides, the at least one end wall having two end substrate transport opening, each opening of the end and side substrate transport openings being arranged for transferring a substrate there through in and out of the substrate transport chamber; at least one of the linear sides having two side substrate transport openings arrayed on a common level in the lateral direction, each of the substrate transport openings for coupling to a respective processing module, and communicating with the substrate transport chamber; dual pairs of SCARA arms connected to the frame and disposed within the sealed chamber, each SCARA arm being a multi-link arm and having an independent drive axis for extending and retracting the respective arm so that a first SCARA arm has a first independent drive axis, a second SCARA arm has a second independent drive axis, a third SCARA arm has a third independent drive axis, and a fourth SCARA arm has fourth independent drive axis, each of the first, second, third and fourth drive axis being different than each other; an outside drive section located outside the sealed chamber and connected to the dual pairs of SCARA arms for moving the dual pairs of SCARA arms about a common axis; and an inside drive section located inside the sealed chamber, the inside drive section including a sealed housing configured to hold a sealed atmosphere different than the chamber atmosphere; wherein the sealed housing has different sealed motors distributed in the sealed chamber, including: a first sealed rotary motor for a first drive axis that describes the first independent drive axis of at least the first SCARA arm, a second sealed rotary motor, sealed apart from the first sealed rotary motor, and providing a second drive axis that is different than the first drive axis, where the second drive axis describes the second independent drive axis of the at least second SCARA arm, a third sealed rotary motor, sealed apart from the first and second sealed rotary motors, and providing a third drive axis that is different than the first and second drive axis, the third drive axis describes the third independent drive axis of the third SCARA arm, and a fourth sealed rotary motor, sealed apart from the first, second and third sealed rotary motors, and providing a fourth drive axis that is different than each of the first, second and third drive axis, the fourth drive axis describes the fourth independent drive axis of the fourth SCARA arm; wherein the first, second, third and fourth sealed motors are distributed in the sealed chamber in close packed cluster arrangement (with each sealed motor offset from each other) so that an outermost span width of the close packed cluster (of sealed motors) is commensurate with an outer edge to outer edge lateral distance of the two side substrate transport openings.

It should be understood that the foregoing description is only illustrative of the present disclosure. Various alternatives and modifications can be devised by those skilled in the art without departing from the present disclosure. Accordingly, the present disclosure is intended to embrace all such alternatives, modifications and variances that fall within the scope of any claims appended hereto. Further, the mere fact that different features are recited in mutually different dependent or independent claims does not indicate that a combination of these features cannot be advantageously used, such a combination remaining within the scope of the present disclosure.

What is claimed is:

1. A brushless electrical machine comprising:
a frame;
an electric machine stator connected to the frame and having a phase coil disposed in an atmospheric volume holding an atmospheric environment;
an electric machine rotor cooperatively coupled to the electric machine stator so as to generate an output under stimulation from the electric machine stator, the electric machine rotor being disposed in a sealed environment sealed from and different than the atmospheric volume; and
a seal that seals the electric machine rotor from the electric machine stator;
wherein the electric machine rotor and electric machine stator are disposed in an axial gap arrangement with an axial gap between the electric machine rotor and electric machine stator disposed astride the electric machine stator, and the seal is arranged in the axial gap so as to seal each electric machine stator from each electric machine rotor stimulated by the electric machine stator across the seal.

2. The brushless electrical machine of claim 1, wherein the axial gap arrangement is configured so that the electric machine stator stimulates the electric machine rotor across the axial gap.

3. The brushless electrical machine of claim 1, wherein the sealed environment and the atmospheric environment, in the sealed volume, are sealed respectively from each other by the seal.

4. The brushless electrical machine of claim 1, wherein the seal axially intervenes between each electric machine rotor element and each electric machine stator stimulating the electric machine rotor.

5. The brushless electrical machine of claim 1, wherein the seal has at least one seal disc portion spanning radially separating the electric machine stator from electric machine rotor throughout the axial gap.

6. The brushless electrical machine of claim 1, wherein the seal is conformal to at least one of the electric machine stator and electric machine rotor.

7. The brushless electrical machine of claim 1, wherein the electric machine stator has stator rings that are arrayed axially, and the electric machine rotor has rotor rings that are arrayed axially.

8. A method comprising:
providing brushless electrical machine with:
a frame,
an electric machine stator connected to the frame and having a phase coil, and
an electric machine rotor cooperatively coupled to the electric machine stator so as to generate an output under stimulation from the electric machine stator; and
sealing, with a seal, the electric machine rotor from the electric machine stator so that the phase coil is disposed in an atmospheric volume holding an atmospheric environment and the electric machine rotor is disposed in a sealed environment sealed from and different than the atmospheric volume;
wherein the electric machine rotor and electric machine stator are disposed in an axial gap arrangement with an axial gap between the electric machine rotor and electric machine stator disposed astride the electric machine stator, and the seal is arranged in the axial gap so as to seal each electric machine stator from each electric machine rotor stimulated by the electric machine stator across the seal.

9. The method of claim 8, wherein the electric machine stator stimulates the electric machine rotor across the axial gap.

10. The method of claim 8, wherein the sealed environment and the atmospheric environment, in the sealed volume, are sealed respectively from each other by the seal.

11. The method of claim 8, wherein the seal axially intervenes between each electric machine rotor element and each electric machine stator stimulating the electric machine rotor.

12. The method of claim 8, wherein:
the seal has at least one seal disc portion spanning radially separating the electric machine stator from electric machine rotor throughout the axial gap; or
the seal is conformal to at least one of the electric machine stator and electric machine rotor.

13. The method of claim 8, wherein the electric machine stator has stator rings that are arrayed axially, and the electric machine rotor has rotor rings that are arrayed axially.

14. A substrate transport apparatus comprising:
a base;
an arm with a terminal joint, about which the arm rotates and extends, and having more than one arm links and an end effector dependent therefrom, each arm link being joined in series with the end effector at a distal end of the arm; and
a distributed drive section, with more than one degrees of freedom operably connected to the arm to effect motion of the end effector commensurate to the more than one degrees of freedom;
wherein an arm link, of the more than one arm links, is a direct drive link dependent and directly driven from a direct drive motor, of the distributed drive section, disposed on the arm at a link joint distal to the terminal joint; and
wherein the end effector, or at least another arm link of the more than one arm links, is at least one of directly driven by another direct drive motor of the distributed drive section, on the arm, and slaved to the direct drive link.

15. The substrate transport apparatus of claim 14, wherein each direct drive motor, on the arm, has a sealed rotor sealed from an atmospheric environment of the stator of the direct drive motor.

16. The substrate transport apparatus of claim 14, wherein the direct drive link has an integral motor rotor of the direct drive motor directly driving the link.

17. The substrate transport apparatus of claim 14, wherein the direct drive motor, at the distal joint, and the direct drive link driven by the direct drive motor are coupled to each other with a transmission-less coupling.

18. The substrate transport apparatus of claim 14, wherein the arm is selectably configurable between a hybrid configuration wherein the end effector, or at least the other arm link of the more than one arm links, is slaved to the direct drive link, and an all motor configuration wherein the end effector, or at least the other arm link of the more than one arm links is directly driven by the other direct drive motor so that in the all motor configuration, each arm link and the end effector are directly driven by a respective direct drive motor.

19. The substrate transport apparatus of claim 14, wherein:
the end effector is directly driven by the other direct drive motor of the distributed drive section, where the end effector is at least one of:
a single ended end effector;
a dual end effector having side-by-side substrate holding locations in a common plane;
a dual end effector having substrate holding locations disposed at opposite ends of the dual end effector in a common plane;
an end effector having three substrate holding locations arranged in a common plane; and
an end effector having four substrate holding locations arranged in a common plane; or
the end effector is slaved to the direct drive link, where the end effector is at least one of:
a single ended end effector;
a dual end effector having side-by-side substrate holding locations in a common plane; and
a dual end effector having substrate holding locations disposed at opposite ends of the dual end effector in a common plane.

20. The substrate transport apparatus of claim 14, wherein the distributed drive section provides the arm with a vertical stroke so as to move the end effector one or more of:
a vertical distance of at least about 175 mm;
a vertical distance of at least about 5 mm above an uppermost substrate held at an uppermost substrate holding station of a load lock configured to hold substrates in a stationary stack of substrates relative to a frame of the load lock; and
a vertical distance of at least about 5 mm below a lowermost substrate held at a lowermost substrate holding station of the load lock configured to hold the substrates in the stationary stack of substrates relative to the frame of the load lock.
